(19) United States
(12) Patent Application Publication
(10) Pub. No.: US 2023/0197668 A1
(43) Pub. Date: Jun. 22, 2023

(54) POWER SEMICONDUCTOR MODULE AND POWER CONVERSION APPARATUS

(71) Applicant: Mitsubishi Electric Corporation, Tokyo (JP)

(72) Inventors: Yoshiko TAMADA, Chiyoda-ku, Tokyo (JP); Seiji OKA, Chiyoda-ku, Tokyo (JP); Shota MORISAKI, Chiyoda-ku, Tokyo (JP); Kazuya OKADA, Chiyoda-ku, Tokyo (JP)

(73) Assignee: Mitsubishi Electric Corporation, Tokyo (JP)

(21) Appl. No.: 17/927,008

(22) PCT Filed: Jul. 8, 2020
(86) PCT No.: PCT/JP2020/026741

§ 371 Date: Nov. 22, 2022

(51) Int. Cl. H01L 23/00; H01L 25/18; H01L 23/538

(52) U.S. Cl. CPC H01L 24/73; H01L 23/5384; H01L 23/5385; H01L 23/5386; H01L 24/05; H01L 24/06; H01L 24/29; H01L 24/32; H01L 24/33; H01L 24/45; H01L 24/48; H01L 25/18; H01L 23/49811; H01L 2224/0603; H01L 2224/3303; H01L 2224/4824; H01L 2224/05552; H01L 2224/05553; H01L 2224/06051; H01L 2224/06181; H01L 2224/29109; H01L 2224/29111; H01L 2224/29139; H01L 2224/29147; H01L 2224/32227; H01L 2224/33181; H01L 2224/45124; H01L 2224/45139; H01L 2224/45144; H01L 2224/45147; H01L 2224/48091; H01L 2224/48106; H01L 2224/48108; H01L 2224/48229; H01L 2224/73215; H01L 2224/73265; H01L 2924/014

(57) ABSTRACT

A power semiconductor module includes a plurality of self-arc-extinguishing semiconductor elements, a printed wiring board, a plurality of conductive joining members, and a plurality of conductive gate wires. The printed wiring board includes an insulating substrate, a source conductive pattern, and a gate conductive pattern. The plurality of self-arc-extinguishing semiconductor elements each include a source electrode and a gate electrode. The source electrodes are joined to the source conductive pattern by means of the plurality of conductive joining members. The plurality of conductive gate wires connect the gate electrodes and the gate conductive pattern.

### TECHNICAL FIELD

The present disclosure relates to a power semiconductor module and a power conversion apparatus.

### BACKGROUND ART

WO 2014/185050 A (PTL 1) discloses a power semiconductor module including an insulating substrate, a self-arc-extinguishing semiconductor element, a printed circuit board facing the insulating substrate, a first conductive post, a second conductive post, and a capacitor serving as a circuit impedance reducing element. The self-arc-extinguishing semiconductor element includes a gate electrode, a source electrode, and a drain electrode. The printed circuit board includes a first metal layer and a second metal layer. The gate electrode is electrically connected, through the first conductive post, to the first metal layer serving as a gate wiring pattern. The source electrode is electrically connected, through the second conductive post, to the second metal layer serving as a source wiring pattern.

### CITATION LIST

### Patent Literature

PTL 1: WO 2014/185050 A

### SUMMARY OF INVENTION

### Technical Problem

In the power semiconductor module disclosed in PTL 1, both the conductive member (first conductive post) that connects the gate electrode to the gate wiring pattern and the conductive member (second conductive post) that connects the source electrode to the source wiring pattern are conductive posts. In order to increase a power capacity of the power semiconductor module, it is effective to cause the power semiconductor module to include a plurality of self-arc-extinguishing semiconductor elements and connect the plurality of self-arc-extinguishing semiconductor elements in parallel to each other. In PTL 1, when the plurality of self-arc-extinguishing semiconductor elements are connected in parallel to each other, the gate electrodes of the plurality of self-are-extinguishing semiconductor elements are electrically connected to each other over a gate line including the first conductive post and the gate wiring pattern, and the source electrodes of the plurality of self-arc-extinguishing semiconductor elements are electrically connected to each other over a source line including the second conductive post and the source wiring pattern.

The source line over which the source electrodes of the plurality of self-arc-extinguishing semiconductor elements connect to each other has parasitic inductance. When the plurality of self-arc-extinguishing semiconductor elements are operated at a high frequency, a time variation dI/dt of a main current I flowing between the source electrodes and the drain electrodes of the plurality of self-arc-extinguishing semiconductor elements increases. The time variation dI/dt of the main current I and the parasitic inductance of the source line generate a large induced electromotive force between the source electrodes of the plurality of self-arc-extinguishing semiconductor elements. This induced electromotive force may apply a surge voltage between the source electrodes and the drain electrodes of the plurality of self-arc-extinguishing semiconductor elements to destroy at least one of the plurality of self-arc-extinguishing semiconductor elements. The parasitic inductance of the source line including the second conductive post and the source wiring pattern is too high to prevent the generation of the surge voltage between the source electrodes and the drain electrodes. There is a problem that the power semiconductor module has a short lifetime.

Furthermore, a gate voltage applied to the gate electrodes of the plurality of self-arc-extinguishing semiconductor elements may oscillate. The oscillation of the gate voltage is caused by an LC resonance circuit formed by parasitic capacitance of the plurality of self-arc-extinguishing semiconductor elements and parasitic inductance of wiring connected to the plurality of self-arc-extinguishing semiconductor elements. The oscillation of the gate voltage causes the self-arc-extinguishing semiconductor element to deteriorate or be destroyed or radiation of electromagnetic noise to the outside of the power semiconductor module. As the inductance of the gate line increases, the impedance of the gate line also increases. The impedance of the gate line including the first conductive post and the gate wiring pattern is too low to reduce or prevent the oscillation of the gate voltage. It is therefore difficult to prevent the oscillation of the gate voltage applied to the self-arc-extinguishing semiconductor element.

The present disclosure has been made in view of the above-described problems, and it is therefore an object of a first aspect of the present disclosure to make a power semiconductor module longer in lifetime while increasing a power capacity and an operation frequency of the power semiconductor module, and to reduce or prevent oscillation of a gate voltage applied to a self-arc-extinguishing semiconductor element included in the power semiconductor module. An object of a second aspect of the present disclosure is to make a power conversion apparatus longer in lifetime while increasing a power capacity and an operation frequency of the power conversion apparatus, and to reduce or prevent oscillation of a gate voltage applied to a self-arc-extinguishing semiconductor element included in the power conversion apparatus.

### Solution to Problem

A semiconductor module of the present disclosure includes an insulating circuit board, a plurality of first self-arc-extinguishing semiconductor elements, a printed wiring board, a plurality of first conductive joining members, and a plurality of first conductive gate wires. The insulating circuit board includes an insulating plate including a first principal surface. The printed wiring board is disposed to face the first principal surface of the insulating plate. The printed wiring board includes an insulating substrate, a first source conductive pattern, and a first gate conductive pattern. The plurality of first self-arc-extinguishing semiconductor elements each include a first source electrode and a first gate electrode. The first source electrodes of the plurality of first self-arc-extinguishing semiconductor elements are joined to the first source conductive pattern by means of the plurality of first conductive joining members. The plurality of first conductive gate wires connect the first gate electrodes of the plurality of first self-arc-extinguishing semiconductor elements and the first gate conductive pattern.

A power conversion apparatus of the present disclosure includes a main conversion circuit to convert and output input power, and a control circuit to output, to the main conversion circuit, a control signal to control the main conversion circuit The main conversion circuit includes the semiconductor module of the present disclosure.

### Advantageous Effects of Invention

Since the power semiconductor module of the present disclosure includes the plurality of first self-arc-extinguishing semiconductor elements, the power capacity of the power semiconductor module can be increased. Further, the first source electrodes of the plurality of first self-arc-extinguishing semiconductor elements are joined to the first source conductive pattern by means of the plurality of first conductive joining members. The plurality of first conductive joining members are each lower in parasitic inductance than the first gate conductive pattern. Therefore, even when the plurality of first self-arc-extinguishing semiconductor elements are operated at a high frequency, it is possible to prevent generation of a surge voltage between the first source electrodes and the first drain electrodes of the plurality of first self-arc-extinguishing semiconductor elements. It is possible to make the power semiconductor module longer in lifetime while increasing the operation frequency of the power semiconductor module.

Furthermore, the plurality of first conductive gate wires connect the first gate electrodes of the plurality of first self-arc-extinguishing semiconductor elements and the first gate conductive pattern. Each of the plurality of first conductive gate wires is higher in parasitic inductance and parasitic impedance than each of the plurality of first conductive joining members. It is therefore possible to reduce or prevent the oscillation of the gate voltage applied to the plurality of first self-arc-extinguishing semiconductor elements.

The power conversion apparatus of the present disclosure includes the semiconductor module of the present disclosure. Therefore, with the power conversion apparatus of the present disclosure, it is possible to make the power conversion apparatus longer in lifetime while increasing the power capacity and the operation frequency of the power conversion apparatus, and to reduce or prevent the oscillation of the gate voltage applied to the self-arc-extinguishing semiconductor elements included in the power conversion apparatus.

### BRIEF DESCRIPTION OF DRAWINGS

FIG. 1 is a schematic plan view of a semiconductor module of a first embodiment.

FIG. 2 is a schematic cross-sectional view of the power semiconductor module of the first embodiment taken along a cross-sectional line II-II in FIG. 1.

FIG. 3 is a schematic cross-sectional view of the power semiconductor module of the first embodiment taken along a cross-sectional line III-III in FIG. 1.

FIG. 4 is a schematic cross-sectional view of the power semiconductor module of the first embodiment taken along a cross-sectional line IV-IV in FIG. 1.

FIG. 5 is a partially enlarged plan view schematically illustrating a printed wiring board included in the semiconductor module of the first embodiment.

FIG. 6 is a partially enlarged plan view schematically illustrating the printed wiring board included in the semiconductor module of the first embodiment.

FIG. 7 is a schematic plan view of a semiconductor module of a second embodiment.

FIG. 8 is a partially enlarged plan view of the semiconductor module according to the second embodiment, schematically illustrating a region VIII in FIG. 7.

FIG. 9 is a schematic plan view of a semiconductor module of a third embodiment.

FIG. 10 is a schematic cross-sectional view of the power semiconductor module of the third embodiment taken along a cross-sectional line X-X in FIG. 9.

FIG. 11 is a schematic cross-sectional view of the power semiconductor module of the third embodiment taken along a cross-sectional line XI-XI in FIG. 9.

FIG. 12 is a schematic cross-sectional view of the power semiconductor module of the third embodiment taken along a cross-sectional line XII-XII in FIG. 9.

FIG. 13 is a schematic cross-sectional view of the power semiconductor module of the third embodiment taken along a cross-sectional line XIII-XIII in FIG. 9.

FIG. 14 is a partially enlarged plan view schematically illustrating a printed wiring board included in the semiconductor module of the third embodiment.

FIG. 15 is a partially enlarged plan view schematically illustrating the printed wiring board included in the semiconductor module of the third embodiment.

FIG. 16 is a schematic plan view of a semiconductor module of a fourth embodiment.

FIG. 17 is a schematic cross-sectional view of the power semiconductor module of the fourth embodiment taken along a cross-sectional line XVII-XVII in FIG. 16.

FIG. 18 is a schematic cross-sectional view of the power semiconductor module of the fourth embodiment taken along a cross-sectional line XVIII-XVIII in FIG. 16.

FIG. 19 is a schematic cross-sectional view of the power semiconductor module of the fourth embodiment taken along a cross-sectional line XIX-XIX in FIG. 16.

FIG. 20 is a schematic cross-sectional view of the power semiconductor module of the fourth embodiment taken along a cross-sectional line XX-XX in FIG. 16.

FIG. 21 is a schematic cross-sectional view of the power semiconductor module of the fourth embodiment taken along a cross-sectional line XXI-XXI in FIG. 16.

FIG. 22 is a partially enlarged plan view schematically illustrating a printed wiring board included in the semiconductor module of the fourth embodiment.

FIG. 23 is a partially enlarged plan view schematically illustrating the printed wiring board included in the semiconductor module of the fourth embodiment.

FIG. 24 is a schematic plan view of a semiconductor module of a fifth embodiment,

FIG. 25 is a schematic cross-sectional view of the power semiconductor module of the fifth embodiment taken along a cross-sectional line XXV-XXV in FIG. 24.

FIG. 26 is a schematic cross-sectional view of the power semiconductor module of the fifth embodiment taken along a cross-sectional line XXVI-XXVI in FIG. 24.

FIG. 27 is a schematic cross-sectional view of the power semiconductor module of the fifth embodiment taken along a cross-sectional line XXVII-XXVII in FIG. 24.

FIG. 28 is a schematic cross-sectional view of the power semiconductor module of the fifth embodiment taken along a cross-sectional line XXVIII-XXVIII in FIG. 24.

FIG. 29 is a schematic cross-sectional view of the power semiconductor module of the fifth embodiment taken along a cross-sectional line XXIX-XXIX in FIG. 24.

FIG. 30 is a partially enlarged plan view schematically illustrating a printed wiring board included in the semiconductor module of the fifth embodiment.

FIG. 31 is a partially enlarged plan view schematically illustrating a printed wiring board included in the semiconductor module of the fifth embodiment.

FIG. 32 is a block diagram illustrating a configuration of a power conversion system according to a sixth embodiment.

### DESCRIPTION OF EMBODIMENTS

Hereinafter, embodiments of the present disclosure will be described. Note that the same components are denoted by the same reference numerals to avoid the description from being redundant.

### First Embodiment

With reference to FIGS. 1 to 6, a power semiconductor module 1 of a first embodiment will be described. Power semiconductor module 1 includes, as main components, an insulating circuit board 10, a plurality of self-arc-extinguishing semiconductor elements 20a, a printed wiring board 30, a plurality of conductive joining members 25a, a plurality of conductive gate wires 50a, a conductive block 40, an electrode terminal 42, an electrode terminal 44, a first source control terminal 46, a conductive wire 47, a first gate control terminal 48, and a conductive wire 49. Power semiconductor module 1 may further include a plurality of first freewheeling diodes 20h.

Insulating circuit board 10 includes an insulating plate 12 and a first conductive circuit pattern 13. Insulating circuit board 10 may further include a base plate 11.

Insulating plate 12 includes a first principal surface 12a. First principal surface 12a of insulating plate 12 extends in a first direction (x direction) and a second direction (y direction).

Insulating plate 12 may be formed of, but not limited to, an inorganic ceramic material such as alumina (A1₂O₃), aluminum nitride (AlN), silicon nitride (Si₃N₄), silicon dioxide (SiO₂)_{,}or boron nitride (BN). Insulating plate 12 may be formed of a resin material in which at least either fine particles or fillers are dispersed. At least either the fine particles or the filler may be formed of, for example, an inorganic ceramic material such as alumina (A1₂O₃), aluminum nitride (AIN), silicon nitride (Si₃N₄), silicon dioxide (SiO₂), boron nitride (BN), diamond (C), silicon carbide (SiC), or boron oxide (B₂O₃), or may be formed of a resin material such as a silicone resin or an acrylic resin. The resin in which at least either the fine particles or the filler are dispersed may be formed of, but not limited to, an epoxy resin, a polyimide resin, a silicone resin, or an acrylic resin.

First conductive circuit pattern 13 is provided on first principal surface 12a of insulating plate 12. First conductive circuit pattern 13 is formed of metal such as copper or aluminum.

Base plate 11 is provided on a principal surface of insulating plate 12 opposite from first principal surface 12a of insulating plate 12. Base plate 11 is formed of metal such as copper or aluminum.

Each of the plurality of self-arc-extinguishing semiconductor elements 20a is a self-arc-extinguishing semiconductor element such as an insulated-gate bipolar transistor (IGBT) or a metal-oxide-semiconductor field-effect transistor (MOSFET). The plurality of self-arc-extinguishing semiconductor elements 20a are mainly formed of silicon (Si) or a wide band gap semiconductor material such as silicon carbide (SiC), gallium nitride (GaN), or diamond. The plurality of self-arc-extinguishing semiconductor elements 20a each include a drain electrode 21a, a source electrode 22a, and a gate electrode 23a.

The plurality of self-arc-extinguishing semiconductor elements 20a are fixed to first conductive circuit pattern 13. Specifically, drain electrodes 21a of the plurality of self-arc-extinguishing semiconductor elements 20a are joined to first conductive circuit pattern 13 by means of conductive joining members 15a such as solder, a metal fine particle sintered body, or a conductive adhesive. Herein, the solder is, for example, Sn-Ag-In solder, Sn-Ag-Cu solder, or the like. Herein, the metal fine particle sintered body is, for example, a silver nanoparticle sintered body. The plurality of self-arc-extinguishing semiconductor elements 20a are fixed to printed wiring board 30. Specifically, source electrodes 22a of the plurality of self-arc-extinguishing semiconductor elements 20a are joined to a source conductive pattern 33 of printed wiring board 30 by means of conductive joining members 25a such as solder, a metal fine particle sintered body, or a conductive adhesive. The plurality of self-arc-extinguishing semiconductor elements 20a are electrically connected in parallel to each other.

The plurality of first freewheeling diodes 20h are mainly formed of silicon (Si) or a wide band gap semiconductor material such as silicon carbide (SiC), gallium nitride (GaN), or diamond. The plurality of first freewheeling diodes 20h each include a first cathode electrode 21h and a first anode electrode 22h.

The plurality of first freewheeling diodes 20h are fixed to first conductive circuit pattern 13. Specifically, first cathode electrodes 21h of the plurality of first freewheeling diodes 20h are each joined to first conductive circuit pattern 13 by means of a conductive joining member 15h such as solder, a metal fine particle sintered body, or a conductive adhesive. The plurality of first freewheeling diodes 20h are fixed to printed wiring board 30. Specifically, first anode electrodes 22h of the plurality of first freewheeling diodes 20h are each joined to source conductive pattern 33 of printed wiring board 30 by means of a conductive joining member 25h such as solder, a metal fine particle sintered body, or a conductive adhesive. The plurality of first freewheeling diodes 20h are electrically connected in parallel to the plurality of self-arc-extinguishing semiconductor elements 20a.

Printed wiring board 30 is separated from insulating circuit board 10 in a third direction (z direction) orthogonal to the first direction (x direction) and second direction (y direction), and is disposed to face first principal surface 12a of insulating plate 12. Printed wiring board 30 includes an insulating substrate 31, source conductive pattern 33, and a gate conductive pattern 36. Printed wiring board 30 may further include a conductive via 32, a conductive pad 34, a source conductive pattern 35, a conductive pad 37, and a conductive via 38.

Insulating substrate 31 is, for example, a glass epoxy substrate or a glass composite substrate. The glass epoxy substrate is formed by, for example, thermally setting a glass woven fabric impregnated with an epoxy resin. The glass composite substrate is formed by, for example, thermally setting a glass nonwoven fabric impregnated with an epoxy resin.

Insulating substrate 31 includes a second principal surface 31a and a third principal surface 31b opposite from second principal surface 31a. In a plan view of third principal surface 31b of insulating substrate 31, a longitudinal direction of insulating substrate 31 coincides with the first direction (x direction), and a lateral direction of insulating substrate 31 coincides with the second direction (y direction). The lateral direction (y direction) of insulating substrate 31 is orthogonal to the longitudinal direction (x direction) of insulating substrate 31. Second principal surface 31a and third principal surface 31b extend in the first direction (x direction) and the second direction (y direction). The longitudinal direction of second principal surface 31a and the longitudinal direction of third principal surface 31b each coincide with the first direction (x direction). The lateral direction of second principal surface 31a and the lateral direction of third principal surface 31b each coincide with the second direction (y direction). Second principal surface 31a of insulating substrate 31 faces first conductive circuit pattern 13.

In a plan view of third principal surface 31b of insulating substrate 31, insulating substrate 31 includes a first edge 31c, a second edge 31d opposite from first edge 31c, a third edge 31e, and a fourth edge 31f opposite from third edge 31e. First edge 31c of insulating substrate 31 may extend in the longitudinal direction (first direction (x direction)) of insulating substrate 31, and may be a long side of insulating substrate 31 in a plan view of third principal surface 31b of insulating substrate 31. Second edge 31d of insulating substrate 31 may extend in the longitudinal direction (first direction (x direction)) of insulating substrate 31, and may be a long side of insulating substrate 31 in a plan view of third principal surface 31b of insulating substrate 31. First edge 31c and second edge 31d are located on opposite sides of insulating substrate 31 in the lateral direction (second direction (y direction)) of insulating substrate 31.

Third edge 31e of insulating substrate 31 connects first edge 31c and second edge 31d. Third edge 31e of insulating substrate 31 may extend in the lateral direction (second direction (y direction)) of insulating substrate 31, and may be a short side of insulating substrate 31 in a plan view of third principal surface 31b of insulating substrate 31. Fourth edge 31f of insulating substrate 31 connects first edge 31c and second edge 31d. Fourth edge 31f of insulating substrate 31 may extend in the lateral direction (second direction (y direction)) of insulating substrate 31, and may be a short side of insulating substrate 31 in a plan view of third principal surface 31b of insulating substrate 31. Third edge 31 e and fourth edge 31f are located on opposite sides of insulating substrate 31 in the longitudinal direction (first direction (x direction)) of insulating substrate 31.

Source conductive pattern 33, conductive pad 34, source conductive pattern 35, gate conductive pattern 36, and conductive pad 37 are each formed of metal such as copper or aluminum. Source conductive pattern 33 and conductive pad 34 are provided on second principal surface 31a of the insulating substrate. Source conductive pattern 33 and conductive pad 34 are separated from each other and electrically insulated from each other. Source conductive pattern 35, gate conductive pattern 36, and conductive pad 37 are provided on third principal surface 31b of the insulating substrate. Source conductive pattern 35, gate conductive pattern 36, and conductive pad 37 are separated from each other and electrically insulated from each other. Printed wiring board 30 is, for example, a double-sided copper-clad multilayer plate.

Source conductive pattern 33 extends in the first direction (x direction) and the second direction (y direction). A longitudinal direction of source conductive pattern 33 coincides with the first direction (x direction), and a lateral direction of source conductive pattern 33 coincides with the second direction (y direction). Source conductive pattern 33 includes an edge 33a extending in the longitudinal direction (first direction (x direction)) of source conductive pattern 33. Edge 33a of source conductive pattern 33 may be a long side of source conductive pattern 33 in a plan view of third principal surface 31b of insulating substrate 31. Edge 33a of source conductive pattern 33 is closer to first edge 31c of insulating substrate 31 rather than second edge 31d of insulating substrate 31.

In a plan view of third principal surface 31b of insulating substrate 31, source conductive pattern 33 covers source electrodes 22a of the plurality of self-arc-extinguishing semiconductor elements 20a. In a plan view of third principal surface 31b of insulating substrate 31, source conductive pattern 33 further covers first cathode electrodes 21h of the plurality of first freewheeling diodes 20h.

Source conductive pattern 35 extends in the first direction (x direction) and the second direction (y direction). A longitudinal direction of source conductive pattern 35 coincides with the first direction (x direction), and a lateral direction of source conductive pattern 35 coincides with the second direction (y direction). In a plan view of third principal surface 31b of insulating substrate 31, source conductive pattern 35 covers source electrodes 22a of the plurality of self-arc-extinguishing semiconductor elements 20a. In a plan view of third principal surface 31b of insulating substrate 31, source conductive pattern 35 further covers first cathode electrodes 21h of the plurality of first freewheeling diodes 20h.

Conductive via 32 electrically connects source conductive pattern 33 and source conductive pattern 35. Conductive via 32 extends through insulating substrate 31. Conductive via 32 is formed of metal such as copper or aluminum.

In a plan view of third principal surface 31b of insulating substrate 31, conductive pad 34 and conductive pad 37 are disposed along third edge 31e of insulating substrate 31.

A longitudinal direction of gate conductive pattern 36 coincides with the first direction (x direction), and a lateral direction of gate conductive pattern 36 coincides with the second direction (y direction). The longitudinal direction of gate conductive pattern 36 coincides with the first direction (x direction) in which first edge 31c of the insulating substrate 31 extends. The longitudinal direction of gate conductive pattern 36 coincides with the first direction (x direction) in which edge 33a of source conductive pattern 33 extends. As illustrated in FIGS. 1, 5, and 6, gate conductive pattern 36 is disposed along first edge 31c of insulating substrate 31. Gate conductive pattern 36 is disposed along edge 33a of source conductive pattern 33. Specifically, in a plan view of third principal surface 31b of insulating substrate 31, gate conductive pattern 36 is disposed directly above edge 33a of source conductive pattern 33.

As illustrated in FIGS. 1, 5, and 6, a width wg1 of a portion 36p of gate conductive pattern 36, portion 36p corresponding to the plurality of self-arc-extinguishing semiconductor elements 20a in the longitudinal direction (first direction (x direction)) of gate conductive pattern 36 in a plan view of third principal surface 31b of insulating substrate 31, is less than a width wₛ₁ of a portion 33p of source conductive pattern 33, portion 33p corresponding to the plurality of self-arc-extinguishing semiconductor elements 20a in the longitudinal direction (first direction (x direction)) of gate conductive pattern 36 in a plan view of third principal surface 31b of insulating substrate 31. Width wg1 of portion 36p of gate conductive pattern 36 is defined as a length of portion 36p of gate conductive pattern 36 in the lateral direction (second direction (y direction)) of gate conductive pattern 36. Width wₛ₁ of portion 33p of source conductive pattern 33 is defined as a length of portion 33p of source conductive pattern 33 in the lateral direction (second direction (y direction)) of gate conductive pattern 36.

Width wg1 of portion 36p of gate conductive pattern 36 may be less than or equal to one half of width _{W51} of portion 33p of source conductive pattern 33, less than or equal to one third of width _{W51} of portion 33p of source conductive pattern 33, less than or equal to one fourth of width _{Ws} of portion 33p of source conductive pattern 33, or less than or equal to one fifth of width _{Ws1} of portion 33p of source conductive pattern 33.

In general, as the width of a conductive pattern decreases, the inductance of the conductive pattern increases. Width wg1 of portion 36p of gate conductive pattern 36 is less than width _{Ws1} of portion 33p of source conductive pattern 33. Therefore, parasitic inductance of gate conductive pattern 36 between the plurality of self-arc-extinguishing semiconductor elements 20a can be made higher than parasitic inductance of source conductive pattern 33 between the plurality of self-arc-extinguishing semiconductor elements 20a.

Width wg1 of portion 36p of gate conductive pattern 36, portion 36p corresponding to the plurality of self-arc-extinguishing semiconductor elements 20a in the longitudinal direction (first direction (x direction)) of gate conductive pattern 36 in a plan view of third principal surface 31b of insulating substrate 31, is less than a width of a portion of source conductive pattern 35, the portion corresponding to the plurality of self-arc-extinguishing semiconductor elements 20a in the longitudinal direction (first direction (x direction)) of gate conductive pattern 36 in a plan view of third principal surface 31b of insulating substrate 31. Therefore, the parasitic inductance of gate conductive pattern 36 between the plurality of self-arc-extinguishing semiconductor elements 20a can be made higher than parasitic inductance of source conductive pattern 35 between the plurality of self-arc-extinguishing semiconductor elements 20a.

The plurality of self-arc-extinguishing semiconductor elements 20a are disposed along first edge 31c of insulating substrate 31. The plurality of self-arc-extinguishing semiconductor elements 20a are disposed along edge 33a of source conductive pattern 33. The plurality of self-arc-extinguishing semiconductor elements 20a are disposed along gate conductive pattern 36. In a plan view of third principal surface 31b of insulating substrate 31, the longitudinal direction (first direction (x direction)) of gate conductive pattern 36 coincides with an array direction (first direction (x direction)) of the plurality of self-arc-extinguishing semiconductor elements 20a. As illustrated in FIGS. 1 and 5, a length L_{g1} of gate conductive pattern 36 in the longitudinal direction (first direction (x direction)) of gate conductive pattern 36 is greater than or equal to a length L_{c1} of the plurality of self-arc-extinguishing semiconductor elements 20a in the array direction (first direction (x direction)) of the plurality of self-arc-extinguishing semiconductor elements 20a. In a plan view of third principal surface 31b of insulating substrate 31, gate electrodes 23a of the plurality of self-arc-extinguishing semiconductor elements 20a are exposed from insulating substrate 31 (printed wiring board 30).

The plurality of conductive gate wires 50a connect gate electrodes 23a of the plurality of self-arc-extinguishing semiconductor elements 20a and gate conductive pattern 36. The plurality of conductive gate wires 50a are bonded to gate electrodes 23a of the plurality of self-arc-extinguishing semiconductor elements 20a and gate conductive pattern 36. Gate electrodes 23a of the plurality of self-arc-extinguishing semiconductor elements 20a are electrically connected to gate conductive pattern 36 by means of conductive gate wires 50a. The plurality of conductive gate wires 50a are formed of metal such as gold, silver, copper, or aluminum.

Electrode terminal 42 and electrode terminal 44 are formed of metal such as copper or aluminum. As illustrated in FIG. 1, in a plan view of the third principal surface 31b of insulating substrate 31, electrode terminal 42 and electrode terminal 44 are disposed adjacent to third edge 31e of insulating substrate 31.

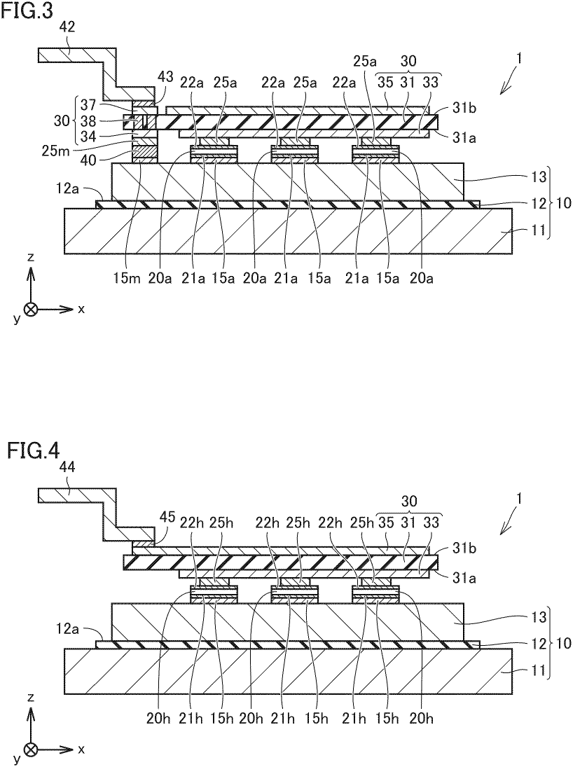

As illustrated in FIG. 3, electrode terminal 42 is joined to conductive pad 37 by means of a conductive joining member 43 such as solder. Conductive via 38 electrically connects conductive pad 34 and conductive pad 37. Conductive via 38 extends through insulating substrate 31. Conductive via 38 is formed of metal such as copper or aluminum. Conductive block 40 electrically connects conductive pad 34 and first conductive circuit pattern 13. Conductive block 40 is joined to conductive pad 34 by means of a conductive joining member 25 m such as solder. Conductive block 40 is joined to first conductive circuit pattern 13 by mean of a conductive joining member 1.5 m such as solder.

Electrode terminal 42 is electrically connected to drain electrodes 21a of the plurality of self-arc-extinguishing semiconductor elements 20a via conductive joining member 43, conductive pad 37, conductive via 38, conductive pad 34, conductive joining member 25 m, conductive block 40, conductive joining member 15 m, first conductive circuit pattern 13, and conductive joining member 15a. Electrode terminal 42 is electrically connected to drain electrodes 21a of the plurality of self-arc-extinguishing semiconductor elements 20a via first conductive circuit pattern 13 without a conductive wire. Electrode terminal 42 functions as a drain electrode terminal. Electrode terminal 42 is a path end, in power semiconductor module 1, of a first path of a first main current (main current 55) flowing between source electrodes 22a and drain electrodes 21a of the plurality of self-arc-extinguishing semiconductor elements 20a. A part of first conductive circuit pattern 13 functions as a drain conductive pattern. That is, first conductive circuit pattern 13 includes the drain conductive pattern.

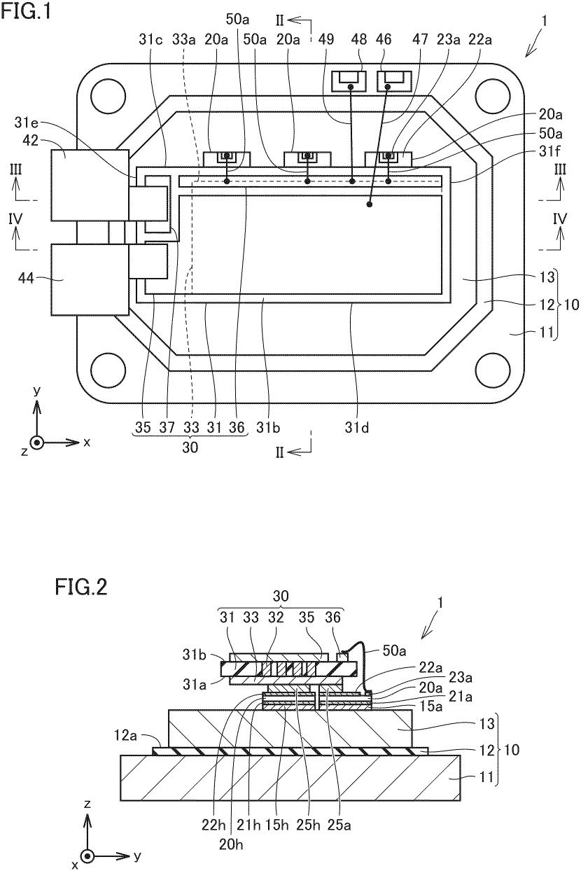

As illustrated in FIG. 4, electrode terminal 44 is joined to source conductive pattern 35 by means of a conductive joining member 45 such as solder. As illustrated in FIGS. 2 and 4, electrode terminal 44 is electrically connected to source electrodes 22a of the plurality of self-arc-extinguishing semiconductor elements 20a via conductive joining member 45, source conductive pattern 35, conductive via 32, source conductive pattern 33, and conductive joining member 25a. Electrode terminal 44 is electrically connected to source electrodes 22a of the plurality of self-arc-extinguishing semiconductor elements 20a via source conductive pattern 33 without a conductive wire. Electrode terminal 44 functions as a source electrode terminal. Electrode terminal 44 is a path end, in power semiconductor module 1, of the first path of the first main current (main current 55) flowing between source electrodes 22a and drain electrodes 21a of the plurality of self-arc-extinguishing semiconductor elements 20a.

First source control terminal 46 is provided, for example, on an insulating block (not illustrated) placed on base plate 11. First source control terminal 46 is formed of metal such as copper or aluminum. As illustrated in FIG. 1, conductive wire 47 connects source conductive pattern 35 and first source control terminal 46. Conductive wire 47 is bonded to source conductive pattern 35 and first source control terminal 46. Conductive wire 47 is formed of metal such as gold, silver, copper, or aluminum.

First gate control terminal 48 is provided, for example, on an insulating block (not illustrated) placed on base plate 11. First gate control terminal 48 is formed of metal such as copper or aluminum. As illustrated in FIG. 1, conductive wire 49 connects gate conductive pattern 36 and first gate control terminal 48. Conductive wire 49 is bonded to gate conductive pattern 36 and first gate control terminal 48. Conductive wire 49 is formed of metal such as gold, silver, copper, or aluminum.

A first source-gate voltage is applied between first source control terminal 46 and first gate control terminal 48 from the outside of power semiconductor module 1. The plurality of self-arc-extinguishing semiconductor elements 20a are switched between an ON state and an OFF state in accordance with the first source-gate voltage.

How power semiconductor module 1 of the present embodiment operates will be described.

In power semiconductor module 1, source electrodes 22a of the plurality of self-arc-extinguishing semiconductor elements 20a are joined to source conductive pattern 33 by means of the plurality of conductive joining members 25a. On the other hand, gate electrodes 23a of the plurality of self-arc-extinguishing semiconductor elements 20a are connected to gate conductive pattern 36 by means of the plurality of conductive gate wires 50a. A thickness of each of the plurality of conductive joining members 25a is less than a length of each of the plurality of conductive gate wires 50a. Each of the plurality of conductive joining members 25a is greater in cross-sectional area than each of the plurality of conductive gate wires 50a. The cross-sectional area of each of the plurality of conductive joining members 25a is defined as an area of a cross section of each of the plurality of conductive joining members 25a orthogonal to a thickness direction (third direction (z direction)) of each of the plurality of conductive joining members 25a. The cross-sectional area of each of the plurality of conductive gate wires 50a is defined as an area of a cross-section of each of the plurality of conductive gate wires 50a orthogonal to a longitudinal direction of each of the plurality of conductive gate wires 50a.

In general, as the length of a conductor increases, the parasitic inductance of the conductor increases. As the cross-sectional area of the conductor decreases, the parasitic inductance of the conductor increases. Therefore, parasitic inductance of each of the plurality of conductive gate wires 50a can be increased. Parasitic inductance of each of the plurality of conductive joining members 25a can be reduced. Each of the plurality of conductive gate wires 50a can be made higher in parasitic inductance than each of the plurality of conductive joining members 25a. A difference between the parasitic inductance of each of the plurality of conductive gate wires 50a and the parasitic inductance of each of the plurality of conductive joining members 25a can be increased.

As described above, the parasitic inductance of each of the plurality of conductive joining members 25a joined to source conductive pattern 33 can be reduced. Therefore, even when the plurality of self-arc-extinguishing semiconductor elements 20a are operated at a high frequency and a time variation dl/dt of the first main current (main current 55) flowing between source electrodes 22a and drain electrodes 21a of the plurality of self-arc-extinguishing semiconductor elements 20a increases, an induced electromotive force generated between source electrodes 22a of the plurality of self-arc-extinguishing semiconductor elements 20a can be reduced. It is possible to prevent generation of a surge voltage between source electrodes 22a and drain electrode 21a of the plurality of self-arc-extinguishing semiconductor elements 20a while increasing the operation frequency of power semiconductor module 1.

Further, the parasitic inductance of each of the plurality of conductive gate wires 50a joined to gate conductive pattern 36 can be increased. In general, as the inductance of a conductor increases, the impedance of the conductor also increases. Therefore, parasitic impedance of each of the plurality of conductive gate wires 50a can be increased. The increased parasitic impedance of each of the plurality of conductive gate wires 50a attenuates oscillation of a gate voltage. It is therefore possible to reduce or prevent the oscillation of the gate voltage applied to self-arc-extinguishing semiconductor element 20a.

Specifically, the thickness of conductive joining member 45, the thickness of conductive via 32, and the thickness of conductive joining member 25a are each less than the length of each of the plurality of conductive gate wires 50a. Conductive joining member 45, conductive via 32, and conductive joining member 25 are each greater in cross-sectional area than each of the plurality of conductive gate wires 50a. Therefore, conductive joining member 45, conductive via 32, and conductive joining member 25 are each lower in parasitic inductance than each of the plurality of conductive gate wires 50a.

Furthermore, source conductive pattern 33 is greater in cross-sectional area than gate conductive pattern 36. Source conductive pattern 35 is greater in cross-sectional area than gate conductive pattern 36. Note that the cross-sectional area of source conductive pattern 33 is defined as an area of a cross section of source conductive pattern 33 orthogonal to a direction (first direction (x direction)) in which the first main current (main current 55) flows through source conductive pattern 33. The cross-sectional area of source conductive pattern 35 is defined as an area of a cross section of source conductive pattern 35 orthogonal to a direction (first direction (x direction)) in which the first main current (main current 55) flows through source conductive pattern 35, The cross-sectional area of gate conductive pattern 36 is defined as an area of a cross section of gate conductive pattern 36 orthogonal to the longitudinal direction (first direction (x direction)) of gate conductive pattern 36 or a first array direction (first direction (x direction)) of the plurality of self-arc-extinguishing semiconductor elements 20a. Therefore, source conductive pattern 33 is lower in parasitic inductance than gate conductive pattern 36. Source conductive pattern 35 is lower in parasitic inductance than gate conductive pattern 36.

The thickness of conductive joining member 43, the thickness of conductive pad 37, the thickness of conductive via 38, the thickness of conductive pad 34, the thickness of conductive joining member 25 m, the thickness of conductive block 40, the thickness of conductive joining member 15 m, and the thickness of conductive joining member 15a are each less than the length of each of the plurality of conductive gate wires 50a. Conductive joining member 43, conductive pad 37, conductive via 38, conductive pad 34, conductive joining member 25 m, conductive block 40, conductive joining member 15 m, and conductive joining member 15a are each greater in cross-sectional area than each of the plurality of conductive gate wires 50a. Therefore, conductive joining member 43, conductive pad 37, conductive via 38, conductive pad 34, conductive joining member 25 m, conductive block 40, conductive joining member 15 m, and conductive joining member 15a are each lower in parasitic inductance than each of the plurality of conductive gate wires 50a.

Furthermore, first conductive circuit pattern 13 functioning as the drain conductive pattern is greater in cross-sectional area than gate conductive pattern 36. Note that the cross-sectional area of first conductive circuit pattern 13 is defined as an area of a cross section of first conductive circuit pattern 13 orthogonal to a direction (first direction (x direction)) in which the first main current (main current 55) flows through first conductive circuit pattern 13. Therefore, first conductive circuit pattern 13 functioning as the drain conductive pattern is lower in parasitic inductance than gate conductive pattern 36.

Therefore, a first source line extending from electrode terminal 44 to source electrodes 22a of the plurality of self-arc-extinguishing semiconductor elements 20a is lower in parasitic inductance than a first gate line extending from first gate control terminal 48 to gate electrodes 23a of the plurality of self-arc-extinguishing semiconductor elements 20a. Even when the plurality of self-arc-extinguishing semiconductor elements 20a are operated at a high frequency, it is possible to prevent generation of a surge voltage between source electrodes 22a and drain electrodes 21a of the plurality of self-arc-extinguishing semiconductor elements 20a. It is possible to make power semiconductor module 1 longer in lifetime while increasing the operation frequency of power semiconductor module 1.

A first drain line extending from electrode terminal 42 to drain electrodes 21a of the plurality of self-arc-extinguishing semiconductor elements 20a is lower in parasitic inductance than the first gate line extending from first gate control terminal 48 to gate electrodes 23 a of the plurality of self-arc-extinguishing semiconductor elements 20a. Even when the plurality of self-arc-extinguishing semiconductor elements 20a are operated at a high frequency, it is possible to prevent generation of a surge voltage between source electrodes 22a and drain electrodes 21a of the plurality of self-arc-extinguishing semiconductor elements 20a. It is possible to make power semiconductor module 1 longer in lifetime while increasing the operation frequency of power semiconductor module 1.

Further, as described above, as the inductance of a conductor increases, the impedance of the conductor also increases. The first gate line extending from first gate control terminal 48 to gate electrodes 23a of the plurality of self-arc-extinguishing semiconductor elements 20a is higher in parasitic impedance than the first source line extending from electrode terminal 44 to source electrodes 22a of the plurality of self-arc-extinguishing semiconductor elements 20a. The first gate line extending from first gate control terminal 48 to gate electrodes 23a of the plurality of self-arc-extinguishing semiconductor elements 20a is higher in parasitic impedance than the first drain line extending from electrode terminal 42 to drain electrodes 21a of the plurality of self-arc-extinguishing semiconductor elements 20a. The increased parasitic impedance of the first gate line can reduce or prevent the oscillation of the gate voltage applied to self-arc-extinguishing semiconductor elements 20a.

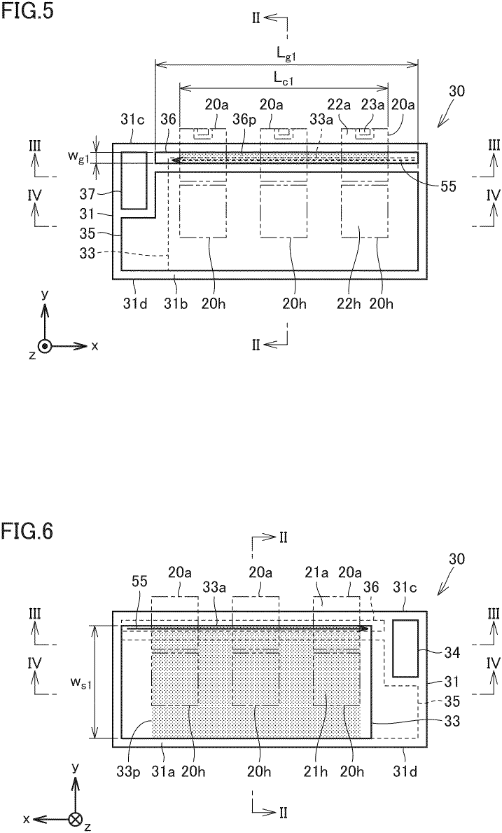

A gate-source voltage applied to each of the plurality of self-are-extiiiguishing semiconductor elements 20a (that is, a difference between a gate voltage applied to first gate control terminal 48 and a source voltage applied to first source control terminal 46) is made higher than a threshold voltage to turn on the plurality of self-arc-extinguishing semiconductor elements 20a. As illustrated in FIGS. 5 and 6, main current 55 flows through source conductive pattern 33. In general, the edge of a conductive pattern is a portion through which the most current flows in the conductive pattern. Therefore, as illustrated in FIGS. 5 and 6, main current 55 flows along edge 33a of source conductive pattern 33, edge 33a being located closest to the plurality of self-arc-extinguishing semiconductor elements 20a in source conductive pattern 33.

Main current 55 flowing through source conductive pattern 33 forms a magnetic flux around main current 55 (for example, in source conductive pattern 33). This magnetic flux and the parasitic inductance of source conductive pattern 33 generate an induced electromotive force in source conductive pattern 33. This induced electromotive force causes the source voltage to vary among the plurality of self-arc-extinguishing semiconductor elements 20a. The gate-source voltage varies among the plurality of self-arc-extinguishing semiconductor elements 20a. A drain-source current of one self-arc-extinguishing semiconductor element 20a among the plurality of self-arc-extinguishing semiconductor elements 20a may rapidly increase to destroy this one self-arc-extinguishing semiconductor element 20a.

In power semiconductor module 1 of the present embodiment, however, gate conductive pattern 36 is disposed along edge 33a of source conductive pattern 33 in a plan view of third principal surface 31b of insulating substrate 31. Therefore, main current 55 further forms a magnetic flux in gate conductive pattern 36. This magnetic flux and the parasitic inductance of gate conductive pattern 36 generate an induced electromotive force in gate conductive pattern 36. This induced electromotive force causes the gate voltage to vary among the plurality of self-arc-extinguishing semiconductor elements 20a. The variation in the gate voltage among the plurality of self-arc-extinguishing semiconductor elements 20a counteracts the variation in the gate-source voltage among the plurality of self-arc-extinguishing semiconductor elements 20a. The drain-source current of the plurality of self-arc-extinguishing semiconductor elements 20a is prevented from rapidly increasing. The plurality of self-arc-extinguishing semiconductor elements 20a are prevented from being destroyed, and it is therefore possible to make power semiconductor module 1 longer in lifetime.

An effect of power semiconductor module 1 of the present embodiment will be described.

Power semiconductor module 1 of the present embodiment includes insulating circuit board 10, a plurality of first self-arc-extinguishing semiconductor elements (the plurality of self-arc-extinguishing semiconductor elements 20a), printed wiring board 30, a plurality of first conductive joining members (the plurality of conductive joining members 25a), and a plurality of first conductive gate wires (the plurality of conductive gate wires 50a). Insulating circuit board 10 includes insulating plate 12 including first principal surface 12a and first conductive circuit pattern 13 provided on first principal surface 12a. Printed wiring board 30 is disposed to face first principal surface 12a of insulating plate 12. Printed wiring board 30 includes insulating substrate 31, a first source conductive pattern (source conductive pattern 33), and a first gate conductive pattern (gate conductive pattern 36). Insulating substrate 31 includes second principal surface 31a facing first principal surface 12a, and third principal surface 31b opposite from second principal surface 31a. In a plan view of third principal surface 31b of insulating substrate 31, insulating substrate 31 includes first edge 31.c and second edge 31d opposite from first edge 31c. The plurality of first self-arc-extinguishing semiconductor elements each includes a first source electrode (source electrode 22a), a first gate electrode (gate electrode 23a), and a first drain electrode (drain electrode 21a).

The first drain electrodes (drain electrodes 21a) of the plurality of first self-arc-extinguishing semiconductor elements (the plurality of self-arc-extinguishing semiconductor elements 20a) are joined to first conductive circuit pattern 13. The first source electrodes (source electrodes 22a) of the plurality of first self-arc-extinguishing semiconductor elements are joined to the first source conductive pattern (source conductive pattern 33) by means of the plurality of first conductive joining members (the plurality of conductive joining members 25a). The plurality of first conductive gate wires (the plurality of conductive gate wires 50a) connect the first gate electrodes (gate electrodes 23a) of the plurality of first self-arc-extinguishing semiconductor elements and the first gate conductive pattern (gate conductive pattern 36). In a plan view of third principal surface 31b of insulating substrate 31, a first longitudinal direction (first direction (x direction)) of the first gate conductive pattern coincides with a first array direction (first direction (x direction)) of the plurality of first self-arc-extinguishing semiconductor elements.

Power semiconductor module 1 of the present embodiment includes the plurality of first self-arc-extinguishing semiconductor elements (the plurality of self-arc-extinguishing semiconductor elements 20a). This allows an increase in power capacity of power semiconductor module 1. In a plan view of third principal surface 31b of insulating substrate 31, the first longitudinal direction of the first gate conductive pattern (gate conductive pattern 36) coincides with the first array direction of the plurality of first self-arc-extinguishing semiconductor elements. Therefore, even when the number of the plurality of first self-arc-extinguishing semiconductor elements included in power semiconductor module 1 is increased, a common gate voltage can be easily applied to the first gate electrodes (gate electrodes 23a) of the plurality of first self-arc-extinguishing semiconductor elements.

The first source electrodes (source electrode 22a) of the plurality of first self-arc-extinguishing semiconductor elements (the plurality of self-arc-extinguishing semiconductor elements 20a) are joined to the first source conductive pattern (source conductive pattern 33) by means of the plurality of first conductive joining members (the plurality of conductive joining members 25a). The plurality of first conductive joining members (the plurality of conductive joining members 25a) are each lower in parasitic inductance than the first gate conductive pattern (gate conductive pattern 36). Therefore, even when the plurality of first self-arc-extinguishing semiconductor elements are operated at a high frequency, it is possible to reduce the induced electromotive force generated between the first source electrodes of the plurality of first self-arc-extinguishing semiconductor elements. It is possible to prevent generation of a surge voltage between the first source electrodes and the first drain electrodes (drain electrodes 21a) of the plurality of first self-arc-extinguishing semiconductor elements. It is possible to make power semiconductor module 1 longer in lifetime while increasing the operation frequency of power semiconductor module 1.

The plurality of first conductive gate wires (the plurality of conductive gate wires 50a) connect the first gate electrodes (gate electrode 23a) of the plurality of first self-arc-extinguishing semiconductor elements (the plurality of self-arc-extinguishing semiconductor elements 20a) and the first gate conductive pattern (gate conductive pattern 36). The plurality of first conductive gate wires are each higher in parasitic inductance and parasitic impedance than each of the plurality of first conductive joining members (the plurality of conductive joining members 25a). The increased parasitic impedance of each of the plurality of first conductive gate wires attenuates the oscillation of the gate voltage. It is therefore possible to reduce or prevent the oscillation of the gate voltage applied to the plurality of first self-arc-extinguishing semiconductor elements.

In power semiconductor module 1 of the present embodiment, the first source conductive pattern (source conductive pattern 33) is provided on second principal surface 31a of insulating substrate 31. The first gate conductive pattern (gate conductive pattern 36) is provided on third principal surface 31b of insulating substrate 31. In a plan view of third principal surface 31b of insulating substrate 31, the first gate electrodes (gate electrodes 23a) are exposed from insulating substrate 31.

The first gate conductive pattern (gate conductive pattern 36) is provided on third principal surface 31b of insulating substrate 31, third principal surface 31b being remote from the first gate electrodes (gate electrodes 23a) relative to second principal surface 31a of insulating substrate 31. The length of each of the plurality of first conductive gate wires (the plurality of conductive gate wires 50a) can be increased. The parasitic inductance and the parasitic impedance of each of the plurality of first conductive gate wires can be increased. The oscillation of the gate voltage applied to the plurality of first self-arc-extinguishing semiconductor elements (the plurality of self-arc-extinguishing semiconductor elements 20a) can be reduced or prevented. Furthermore, in a plan view of third principal surface 31b of insulating substrate 31. the first gate electrodes of the plurality of first self-arc-extinguishing semiconductor elements are exposed from insulating substrate 31. Therefore, the plurality of first conductive gate wires can be easily bonded to the first gate electrodes of the plurality of first self-arc-extinguishing semiconductor elements and the first gate conductive pattern.

In power semiconductor module 1 of the present embodiment, a first length (length L_{g1}) of the first gate conductive pattern (gate conductive pattern 36) in the first longitudinal direction (first direction (x direction)) of the first gate conductive pattern (gate conductive pattern 36) is greater than or equal to a second length (length L_{c1}) of the plurality of first self-arc-extinguishing semiconductor elements (the plurality of self-arc-extinguishing semiconductor elements 20a) in the first array direction of the plurality of first self-arc-extinguishing semiconductor elements (the plurality of self-arc-extinguishing semiconductor elements 20a).

Therefore, the first length (length L_{g1}) of the first gate conductive pattern (gate conductive pattern 36) can be increased. The parasitic inductance and the parasitic impedance of the first gate conductive pattern can be increased. The oscillation of the gate voltage applied to the plurality of first self-arc-extinguishing semiconductor elements (the plurality of self-arc-extinguishing semiconductor elements 20a) can be reduced or prevented.

In power semiconductor module 1 of the present embodiment, the first gate conductive pattern (gate conductive pattern 36) is disposed along first edge 31c of insulating substrate 31 in a plan view of third principal surface 31b of insulating substrate 31. The plurality of first self-arc-extinguishing semiconductor elements (the plurality of self-arc-extinguishing semiconductor elements 20a) are disposed along first edge 31c of insulating substrate 31.

Therefore, the plurality of first conductive gate wires (the plurality of conductive gate wires 50a) can be easily bonded to the first gate electrodes (gate electrodes 23a) of the plurality of first self-arc-extinguishing semiconductor elements (the plurality of self-arc-extinguishing semiconductor elements 20a) and the first gate conductive pattern (gate conductive pattern 36).

In power semiconductor module 1 of the present embodiment, the first source conductive pattern (source conductive pattern 33) is provided on second principal surface 31a of insulating substrate 31. The first gate conductive pattern (gate conductive pattern 36) is provided on third principal surface 31b of insulating substrate 31 and is disposed along edge 33a of the first source conductive pattern in a plan view of third principal surface 31b.

The magnetic flux formed by main current 55 flowing along edge 33a of the first source conductive pattern (source conductive pattern 33) and the parasitic inductance of the first source conductive pattern causes the source voltage to vary among the plurality of self-arc-extinguishing semiconductor elements 20a, and the gate-source voltage varies among the plurality of self-arc-extinguishing semiconductor elements 20a accordingly. The magnetic flux and the parasitic inductance of the first gate conductive pattern (gate conductive pattern 36), however, causes the gate voltage to vary among the plurality of self-arc-extinguishing semiconductor elements 20a. The variation in the gate voltage among the plurality of self-arc-extinguishing semiconductor elements 20a counteracts the variation in the gate-source voltage among the plurality of self-arc-extinguishing semiconductor elements 20a. The drain-source current of the plurality of self-arc-extinguishing semiconductor elements 20a is prevented from rapidly increasing. The plurality of self-arc-extinguishing semiconductor elements 20a are prevented from being destroyed, and it is therefore possible to make power semiconductor module 1 longer in lifetime.

In power semiconductor module 1 of the present embodiment, a first width (width w_{g1}) of a first gate conductive pattern portion (portion 36p) of the first gate conductive pattern (gate conductive pattern 36), the first gate conductive pattern portion corresponding to the plurality of first self-arc-extinguishing semiconductor elements (the plurality of self-arc-extinguishing semiconductor elements 20a) in the first longitudinal direction (first direction (x direction)) of the first gate conductive pattern (gate conductive pattern 36) in a plan view of third principal surface 31b of insulating substrate 31, is less than a second width (width wₛ₁) of a first source conductive pattern portion (portion 33p) of the first source conductive pattern (source conductive pattern 33), the first source conductive pattern portion corresponding to the plurality of first self-arc-extinguishing semiconductor elements in the first longitudinal direction of the first gate conductive pattern (gate conductive pattern 36) in a plan view of third principal surface 31b of insulating substrate 31. The first width of the first gate conductive pattern portion coincides with a length of the first gate conductive pattern portion in a first lateral direction of the first gate conductive pattern orthogonal to the first longitudinal direction of the first gate conductive pattern. The second width (width wₛ₁) of the first source conductive pattern portion coincides with a length of the first source conductive pattern portion in the first lateral direction of the first gate conductive pattern.

Therefore, the parasitic inductance of the first source conductive pattern (source conductive pattern 33) can be reduced. Even when the plurality of first self-arc-extinguishing semiconductor elements (the plurality of self-arc-extinguishing semiconductor elements 20a) are operated at a high frequency, the induced electromotive force generated between the first source electrodes (source electrodes 22a) of the plurality of first self-arc-extinguishing semiconductor elements can be reduced. It is possible to prevent generation of a surge voltage between the first source electrodes and the first drain electrodes (drain electrodes 21a) of the plurality of first self-arc-extinguishing semiconductor elements. It is possible to make power semiconductor module 1 longer in lifetime while increasing the operation frequency of power semiconductor module 1.

Further, the parasitic inductance and the parasitic impedance of the first gate conductive pattern (gate conductive pattern 36) can be increased. The increased parasitic impedance of the first gate conductive pattern attenuates the oscillation of the gate voltage. Therefore, the oscillation of the gate voltage applied to the plurality of first self-arc-extinguishing semiconductor elements (the plurality of self-arc-extinguishing semiconductor elements 20a) can be reduced or prevented.

Power semiconductor module 1 of the present embodiment further includes the plurality of first freewheeling diodes 20h. The plurality of first freewheeling diodes 20h each include first anode electrode 22h and first cathode electrode 21h. First cathode electrodes 21h of the plurality of first freewheeling diodes 20h are joined to first conductive circuit pattern 13. First anode electrodes 22h of the plurality of first freewheeling diodes 20h are joined to the first source conductive pattern (source conductive pattern 33). In a plan view of third principal surface 31b of insulating substrate 31, the first source conductive pattern covers the first source electrodes (source electrodes 22a) of the plurality of first self-arc-extinguishing semiconductor elements (the plurality of self-arc-extinguishing semiconductor elements 20a) and first cathode electrodes 21h of first freewheeling diodes 20h.

Therefore, the width of the first source conductive pattern (source conductive pattern 33) can be further increased. The parasitic inductance of the first source conductive pattern can be reduced. Even when the plurality of first self-arc-extinguishing semiconductor elements (the plurality of self-arc-extinguishing semiconductor elements 20a) are operated at a high frequency, the induced electromotive force generated between the first source electrodes (source electrodes 22a) of the plurality of first self-arc-extinguishing semiconductor elements can be reduced. It is possible to prevent generation of a surge voltage between the first source electrodes and the first drain electrodes (drain electrodes 21a) of the plurality of first self-arc-extinguishing semiconductor elements. It is possible to make power semiconductor module 1 longer in lifetime while increasing the operation frequency of power semiconductor module 1.

Power semiconductor module 1 of the present embodiment further includes a first electrode terminal (electrode terminal 44) and a second electrode terminal (electrode terminal 42). The first electrode terminal is a first path end, in power semiconductor module 1, of the first path of the first main current (main current 55) flowing between the first source electrodes (source electrodes 22a) and the first drain electrodes (drain electrodes 21a) of the plurality of first self-arc-extinguishing semiconductor elements (the plurality of self-arc-extinguishing semiconductor elements 20a). The second electrode terminal is a second pathend, in power semiconductor module 1, of the first path of the first main current (main current 55). The first electrode terminal is electrically connected to the first source electrodes of the plurality of first self-arc-extinguishing semiconductor elements via the first source conductive pattern (source conductive pattern 33) without a conductive wire. The second electrode terminal is electrically connected to the first drain electrodes of the plurality of first self-arc-extinguishing semiconductor elements via first conductive circuit pattern 13 without a conductive wire.

Therefore, the parasitic inductance of the first source line extending from the first electrode terminal (electrode terminal 44) to the first source electrodes (source electrodes 22a) of the plurality of first self-arc-extinguishing semiconductor elements (the plurality of self-arc-extinguishing semiconductor elements 20a) can be reduced. The parasitic inductance of the first drain line extending from the second electrode terminal (electrode terminal 42) to the first drain electrodes (drain electrodes 21a) of the plurality of first self-arc-extinguishing semiconductor elements can be reduced. It is possible to prevent generation of a surge voltage between the first source electrodes and the first drain electrodes of the plurality of first self-arc-extinguishing semiconductor elements. It is possible to make power semiconductor module 1 longer in lifetime while increasing the operation frequency of power semiconductor module 1.

### Second Embodiment

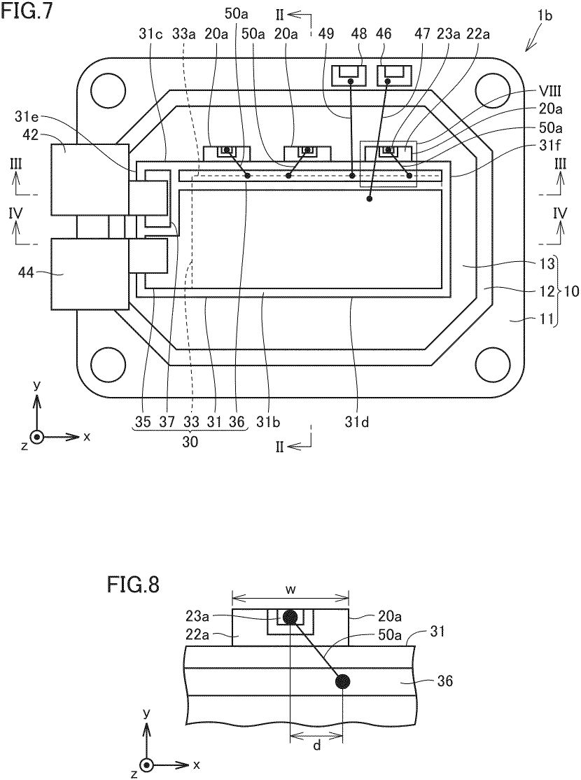

With reference to FIGS. 7 and 8, a power semiconductor module 1b of a second embodiment will be described. Power semiconductor module 1b of the present embodiment is similar in configuration to power semiconductor module 1 of the first embodiment, but is different mainly in the following points.

In power semiconductor module 1b, at least one of the plurality of conductive gate wires 50a extends in a direction oblique to the first longitudinal direction (first direction (x direction)) of gate conductive pattern 36 in a plan view of third principal surface 31b of insulating substrate 31. Specifically, in a plan view of third principal surface 31b of insulating substrate 31, all of the plurality of conductive gate wires 50a extend in a direction oblique to the first longitudinal direction (first direction (x direction)) of gate conductive pattern 36.

At least one of the plurality of conductive gate wires 50a has a first end bonded to the first gate electrode (gate electrode 23a) of at least one of the plurality of self-arc-extinguishing semiconductor elements 20a and a second end bonded to gate conductive pattern 36. Specifically, an interval d between the first end and the second end of at least one of the plurality of conductive gate wires 50a in the first longitudinal direction (first direction (x direction)) of gate conductive pattern 36 is less than or equal to a width w of at least one of the plurality of self-arc-extinguishing semiconductor elements 20a in the first longitudinal direction of gate conductive pattern 36.

More specifically, each of the plurality of conductive gate wires 50a has the first end bonded to gate electrode 23a of a corresponding one of the plurality of self-arc-extinguishing semiconductor elements 20a and the second end bonded to gate conductive pattern 36. Interval d between the first end and the second end of each of the plurality of conductive gate wires 50a in the first longitudinal direction (first direction (x direction)) of gate conductive pattern 36 is less than or equal to width w of each of the plurality of self-arc-extinguishing semiconductor elements 20a in the first longitudinal direction of gate conductive pattern 36.

Power semiconductor module 1b of the present embodiment has the following effects in addition to the effects of power semiconductor module 1 of the first embodiment.

In power semiconductor module 1b of the present embodiment, at least one of the plurality of first conductive gate wires (the plurality of conductive gate wires 50a) extends in a direction oblique to the first longitudinal direction (first direction (x direction)) of the first gate conductive pattern (gate conductive pattern 36) in a plan view of third principal surface 31b of insulating substrate 31.

Therefore, at least one of the plurality of first conductive gate wires (the plurality of conductive gate wires 50 a) can be made longer. The parasitic inductance and the parasitic impedance of at least one of the plurality of first conductive gate wires can be increased. The oscillation of the gate voltage applied to the plurality of first self-arc-extinguishing semiconductor elements (the plurality of self-arc-extinguishing semiconductor elements 20a) can be reduced or prevented.

In power semiconductor module 1b of the present embodiment, at least one of the plurality of first conductive gate wires (the plurality of conductive gate wires 50a) has the first end bonded to the first gate electrode (gate electrode 23a) of at least one of the plurality of first self-arc-extinguishing semiconductor elements (the plurality of self-arc-extinguishing semiconductor elements 20a) and the second end bonded to the first gate conductive pattern (gate conductive pattern 36). Interval d between the first end and the second end of at least one of the plurality of conductive gate wires 50a in the first longitudinal direction (first direction (x direction)) of the first gate conductive pattern is less than or equal to width w of at least one of the plurality of first self-arc-extinguishing semiconductor elements in the first longitudinal direction of the first gate conductive pattern.

Therefore, even when a thermal cycle is applied to power semiconductor module 1b, the plurality of first conductive gate wires (the plurality of conductive gate wires 50a) are less prone to disconnect. This can make power semiconductor module 1b longer in lifetime.

### Third Embodiment

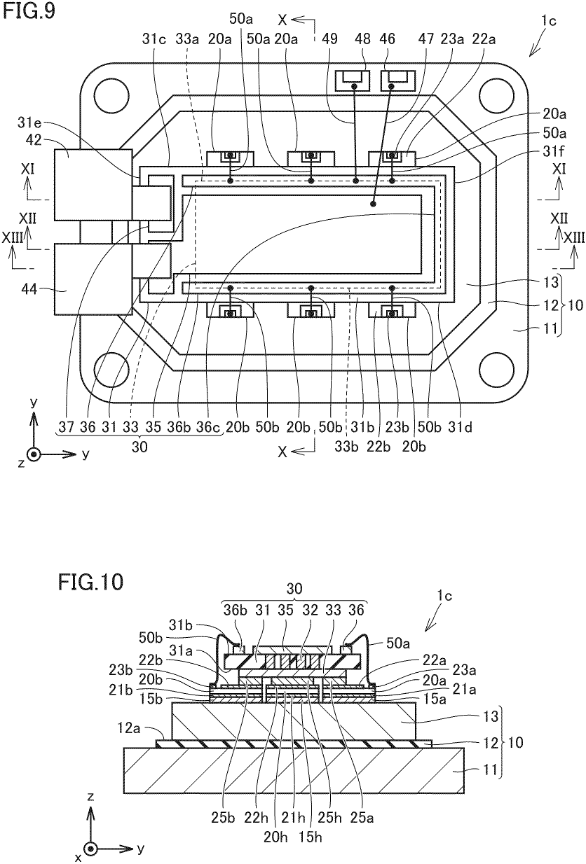

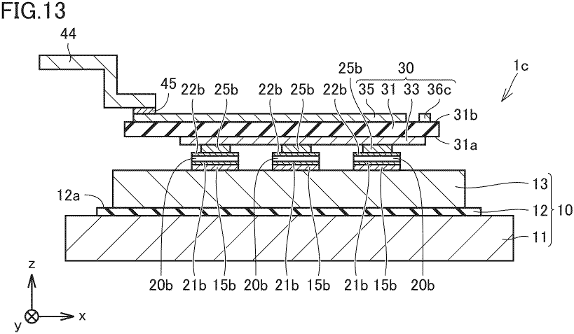

With reference to FIGS. 9 to 15, a power semiconductor module 1c of a third embodiment will be described. Power semiconductor module 1c of the present embodiment is similar in configuration to power semiconductor module 1 of the first embodiment, but is different mainly in the following points.

Power semiconductor module 1c further includes a plurality of self-arc-extinguishing semiconductor elements 20b, a plurality of conductive joining members 25b, a plurality of conductive joining members 15b, and a plurality of conductive gate wires 50b.

Each of the plurality of self-arc-extinguishing semiconductor elements 20b is a self-arc-extinguishing semiconductor element such as an insulated-gate bipolar transistor (IGBT) or a metal-oxide-semiconductor field-effect transistor (MOSFET). The plurality of self-arc-extinguishing semiconductor elements 20b are mainly formed of silicon (Si) or a wide band gap semiconductor material such as silicon carbide (SiC), gallium nitride (GaN), or diamond. The plurality of self-arc-extinguishing semiconductor elements 20b each include a source electrode 22b, a gate electrode 23b, and a drain electrode 21b.

The plurality of self-arc-extinguishing semiconductor elements 20b are fixed to first conductive circuit pattern 13. Specifically, drain electrodes 21b of the plurality of self-arc-extinguishing semiconductor elements 20b are joined to first conductive circuit pattern 13 by means of conductive joining members 15b such as solder, a metal fine particle sintered body, or a conductive adhesive. The plurality of self-arc-extinguishing semiconductor elements 20b are fixed to printed wiring board 30. Specifically, source electrodes 22b of the plurality of self-arc-extinguishing semiconductor elements 20b are joined to source conductive pattern 33 of printed wiring board 30 by means of conductive joining members 25b such as solder, a metal fine particle sintered body, or a conductive adhesive. The plurality of self-arc-extinguishing semiconductor elements 20b are electrically connected in parallel to each other. The plurality of self-arc-extinguishing semiconductor elements 20a and the plurality of self-arc-extinguishing semiconductor elements 20b and a are electrically connected in parallel to each other. The plurality of self-arc-extinguishing semiconductor elements 20b are electrically connected in parallel to the plurality of self-arc-extinguishing semiconductor elements 20a. The plurality of first freewheeling diodes 20h are electrically connected in parallel to the plurality of self-arc-extinguishing semiconductor elements 20b.

Printed wiring board 30 further includes a gate conductive pattern 36b. Gate conductive pattern 36b is provided on third principal surface 31b of insulating substrate 31. Gate conductive pattern 36b is separated from source conductive pattern 35 and conductive pad 37 and is electrically insulated from source conductive pattern 35 and conductive pad 37.

A longitudinal direction of gate conductive pattern 36b coincides with, the first direction (x direction), and a lateral direction of gate conductive pattern 36b coincides with the second direction (y direction). The longitudinal direction of gate conductive pattern 36b coincides with the first direction (x direction) in which second edge 31d of insulating substrate 31 extends. The longitudinal direction of gate conductive pattern 36b coincides with the first direction (x direction) in which edge 33b of source conductive pattern 33 extends. Edge 33b of source conductive pattern 33 is an edge of source conductive pattern 33 opposite from edge 33a of source conductive pattern 33. Edge 33b of source conductive pattern 33 is opposite from edge 33a of source conductive pattern 33 in the lateral direction (second direction (y direction)) of source conductive pattern 33.

As illustrated in FIGS. 9, 14, and 15, gate conductive pattern 36b is disposed along second edge 31d of insulating substrate 31. Gate conductive pattern 36b is disposed along edge 33b of source conductive pattern 33. Specifically, in a plan view of third principal surface 31b of insulating substrate 31, gate conductive pattern 36b is disposed directly above edge 33b of source conductive pattern 33.

As illustrated in FIGS. 9, 14, and 15, a width w_{g2} of a portion 36q of gate conductive pattern 36b, portion 36q corresponding to the plurality of self-arc-extinguishing semiconductor elements 20b in the longitudinal direction (first direction (x direction)) of gate conductive pattern 36b in a plan view of third principal surface 31b of insulating substrate 31, is less than a width wₛ₂ of a portion 33q of source conductive pattern 33, portion 33q corresponding to the plurality of self-arc-extinguishing semiconductor elements 20b in the longitudinal direction (first direction (x direction)) of gate conductive pattern 36b in a plan view of third principal surface 31b of insulating substrate 31. Width w_{g2} of portion 36q of gate conductive pattern 36b is defined as a length of portion 36q of gate conductive pattern 36b in the lateral direction (second direction (y direction)) of gate conductive pattern 36b. Width wₛ₂ of portion 33q of source conductive pattern 33 is defined as a length of portion 33q of source conductive pattern 33 in the lateral direction (second direction (y direction)) of gate conductive pattern 36b.

Width w_{g2} of portion 36q of gate conductive pattern 36b may be less than or equal to one half of width wₛ₂ of portion 33q of source conductive pattern 33, less than or equal to one third of width wₛ₂ of portion 33q of source conductive pattern 33, less than or equal to one fourth of width wₛ₂ of portion 33q of source conductive pattern 33, or less than or equal to one fifth of width wₛ₂ of portion 33q of source conductive pattern 33.

Since width w_{g2} of portion 36q of gate conductive pattern 36b is less than width wₛ₂ of portion 33q of source conductive pattern 33, the parasitic inductance of gate conductive pattern 36b between the plurality of self-arc-extinguishing semiconductor elements 20b can be made higher than the parasitic inductance of source conductive pattern 33 between the plurality of self-arc-extinguishing semiconductor elements 20b.

Width w_{g2} of portion 36q of gate conductive pattern 36b, portion 36q corresponding to the plurality of self-arc-extinguishing semiconductor elements 20b in the longitudinal direction (first direction (x direction)) of gate conductive pattern 36b in a plan view of third principal surface 31b of insulating substrate 31, is less than a width of a portion of source conductive pattern 35, the portion corresponding to the plurality of self-arc-extinguishing semiconductor elements 20b in the longitudinal direction (first direction (x direction)) of gate conductive pattern 36b in a plan view of third principal surface 31b of insulating substrate 31. Therefore, the parasitic inductance of gate conductive pattern 36b between the plurality of self-arc-extinguishing semiconductor elements 20b can be made higher than the parasitic inductance of source conductive pattern 35 between the plurality of self-arc-extinguishing semiconductor elements 20b.

Gate conductive pattern 36b is electrically connected to gate conductive pattern 36. Specifically, printed wiring board 30 may further include a gate conductive pattern 36c that connects gate conductive pattern 36 and gate conductive pattern 36b. Gate conductive pattern 36c is provided on third principal surface 31b of insulating substrate 31. A longitudinal direction of gate conductive pattern 36c coincides with the second direction (y direction), and a lateral direction of gate conductive pattern 36c coincides with the first direction (x direction). The longitudinal direction of gate conductive pattern 36c coincides with the second direction (y direction) in which fourth edge 31f of insulating substrate 31 extends. As illustrated in FIG. 9, gate conductive pattern 36c is disposed along fourth edge 31f of insulating substrate 31.

Gate conductive pattern 36c is disposed along an edge of source conductive pattern 33. Specifically, in a plan view of third principal surface 31b of insulating substrate 31, gate conductive pattern 36c is disposed directly above the edge of source conductive pattern 33. In a plan view of third principal surface 31b of insulating substrate 31, gate conductive pattern 36, gate conductive pattern 36b, and gate conductive pattern 36c face three sides of source conductive pattern 35. Gate conductive patterns 36b, 36c are formed of metal such as copper or aluminum.

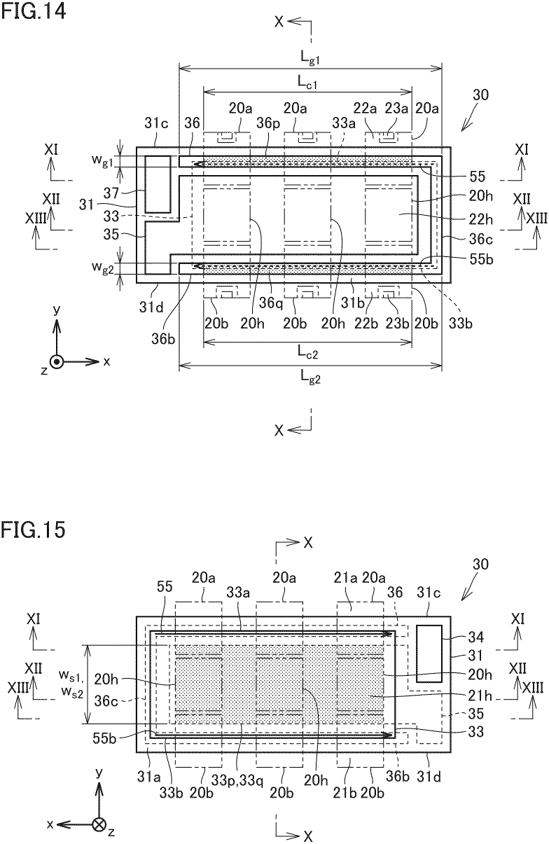

The plurality of self-arc-extinguishing semiconductor elements 20b are disposed along second edge 31d of insulating substrate 31. The plurality of self-arc-extinguishing semiconductor elements 20b are disposed along edge 33b of source conductive pattern 33. The plurality of self-arc-extinguishing semiconductor elements 20b are disposed along gate conductive pattern 36b. In a plan view of third principal surface 31b of insulating substrate 31, the longitudinal direction (first direction (x direction)) of gate conductive pattern 36b coincides with an array direction (first direction (x direction)) of the plurality of self-arc-extinguishing semiconductor elements 20b. As illustrated in FIGS. 1 and 14, a length L_{g2} of gate conductive pattern 36b in the longitudinal direction (first direction (x direction)) of gate conductive pattern 36b is greater than or equal to a length L_{c2} of the plurality of self-arc-extinguishing semiconductor elements 20b in the array direction (first direction (x direction)) of the plurality of self-arc-extinguishing semiconductor elements 20b. In a plan view of third principal surface 31b of insulating substrate 31, gate electrodes 23b of the plurality of self-arc-extinguishing semiconductor elements 20b are exposed from insulating substrate 31 (printed wiring board 30).

The plurality of conductive gate wires 50b connect gate electrodes 23b of the plurality of self-arc-extinguishing semiconductor elements 20b and gate conductive pattern 36b. The plurality of conductive gate wires 50b are bonded to gate electrodes 23b of the plurality of self-arc-extinguishing semiconductor elements 20b and gate conductive pattern 36b. Gate electrodes 23b of the plurality of self-arc-extinguishing semiconductor elements 20b are electrically connected to gate conductive pattern 36b by means of conductive gate wires 50b. The plurality of conductive gate wires 50b are formed of metal such as gold, silver, copper, or aluminum.

As illustrated in FIG. 11, electrode terminal 42 is electrically connected to drain electrodes 21a, 21b of the plurality of self-arc-extinguishing semiconductor elements 20a, 20b via conductive joining member 43, conductive pad 37, conductive via 38, conductive pad 34, conductive joining member 25 m, conductive block 40, conductive joining member 15 m, first conductive circuit pattern 13, and conductive joining members 15a, 15b. Electrode terminal 42 is electrically connected to drain electrodes 21a, 21b of the plurality of self-arc-extinguishing semiconductor elements 20a, 20b via first conductive circuit pattern 13 without a conductive wire. Electrode terminal 42 functions as a drain electrode terminal. Electrode terminal 42 is a path end, in power semiconductor module 1c, of a first path of a first main current (main currents 55, 55b) flowing between source electrodes 22a, 22b and drain electrodes 21a, 21b of the plurality of self-arc-extinguishing semiconductor elements 20a, 20b. A part of first conductive circuit pattern 13 functions as a drain conductive pattern. That is, first conductive circuit pattern 13 includes the drain conductive pattern.

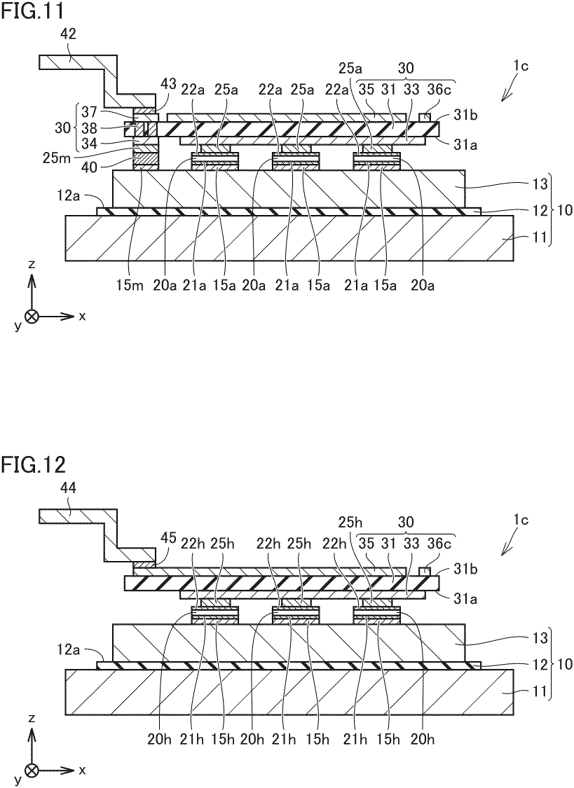

As illustrated in FIG. 12, electrode terminal 44 is joined to source conductive pattern 35 by means of conductive joining member 45 such as solder. As illustrated in FIGS. 10 and 12, electrode terminal 44 is electrically connected to source electrodes 22a, 22b of the plurality of self-arc-extinguishing semiconductor elements 20a, 20b via conductive joining member 45, source conductive pattern 35, conductive via 32, source conductive pattern 33, and conductive joining members 25a, 25b. Electrode terminal 44 is electrically connected to source electrodes 22a, 22b of the plurality of self-arc-extinguishing semiconductor elements 20a, 20b via source conductive pattern 33 without a conductive wire. Electrode terminal 44 functions as a source electrode terminal. Electrode terminal 44 is a path end, in power semiconductor module 1c, of the first path of the first main current (main currents 55, 55b) flowing between source electrodes 22a, 22b and drain electrodes 21a, 21b of the plurality of self-arc-extinguishing semiconductor elements 20a, 20b.

The first source-gate voltage is applied between first source control terminal 46 and first gate control terminal 48 from the outside of power semiconductor module 1c. The plurality of self-arc-extinguishing semiconductor elements 20a, 20b are switched between the ON state and the OFF state in accordance with the first source-gate voltage.

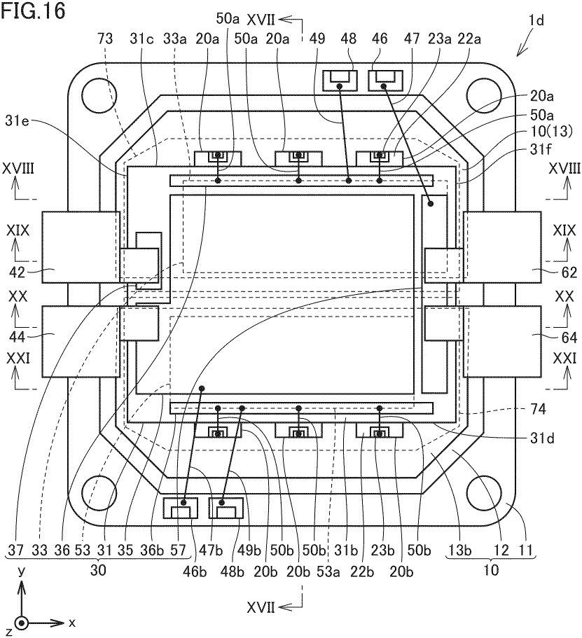

The gate-source voltage applied to each of the plurality of self-arc-extinguishing semiconductor elements 20b is made higher than the threshold voltage to turn on the plurality of self-arc-extinguishing semiconductor elements 20b. As illustrated in FIGS. 14 and 15, main current 55b flows through source conductive pattern 33. In general, the edge of a conductive pattern is a portion through which the most current flows in the conductive pattern. Therefore, as illustrated in FIGS. 14 and 15, main current 55b flows along edge 33b of source conductive pattern 33, edge 33b being located closest to the plurality of self-arc-extinguishing semiconductor elements 20b in source conductive pattern 33.

Main current 55b flowing through source conductive pattern 33 forms a magnetic flux around main current 55b (for example, in source conductive pattern 33). This magnetic flux and the parasitic inductance of source conductive pattern 33 generate an induced electromotive force in source conductive pattern 33. This induced electromotive force causes the source voltage to vary among the plurality of self-arc-extinguishing semiconductor elements 20b. The gate-source voltage varies among the plurality of self-arc-extinguishing semiconductor elements 20b. The drain-source current of one self-arc-extinguishing semiconductor element 20b among the plurality of self-arc-extinguishing semiconductor elements 20b may rapidly increase to destroy this one self-arc-extinguishing semiconductor element 20b.

In power semiconductor module 1c of the present embodiment, however, gate conductive pattern 36b is disposed along edge 33b of source conductive pattern 33 in a plan view of third principal surface 31b of insulating substrate 31. Therefore, main current 55b further forms a magnetic flux in gate conductive pattern 36b. This magnetic flux and the parasitic inductance of gate conductive pattern 36b generate an induced electromotive force in gate conductive pattern 36b. This induced electromotive force causes the gate voltage to vary among the plurality of self-arc-extinguishing semiconductor elements 20b. The variation in the gate voltage among the plurality of self-arc-extinguishing semiconductor elements 20b counteracts the variation in the gate-source voltage among the plurality of self-arc-extinguishing semiconductor elements 20b. The drain-source current of the plurality of self-arc-extinguishing semiconductor elements 20b is prevented from rapidly increasing. The plurality of self-arc-extinguishing semiconductor elements 20b are prevented from being destroyed, and it is therefore possible to make power semiconductor module 1c longer in lifetime.

Power semiconductor module 1c of the present embodiment has the following effects in addition to the effects of power semiconductor module 1 of the first embodiment.

Power semiconductor module 1c of the present embodiment further includes a plurality of second self-arc-extinguishing semiconductor elements (the plurality of self-arc-extinguishing semiconductor elements 20b), a plurality of second conductive joining members (the plurality of conductive joining members 25b), and a plurality of second conductive gate wires (the plurality of conductive gate wires 50b). Printed wiring board 30 further includes a second gate conductive pattern (gate conductive pattern 36b) electrically connected to the first gate conductive pattern (gate conductive pattern 36). The plurality of second self-arc-extinguishing semiconductor elements each includes a second source electrode (source electrode 22b), a second gate electrode (gate electrode 23b), and a second drain electrode (drain electrode 21b).

The second drain electrodes (drain electrodes 21b) of the plurality of second self-arc-extinguishing semiconductor elements (the plurality of self-arc-extinguishing semiconductor elements 20b) are joined to first conductive circuit pattern 13. The second source electrodes (source electrodes 22b) of the plurality of second self-arc-extinguishing semiconductor elements are joined to the first source conductive pattern (source conductive pattern 33) by means of the plurality of second conductive joining members (the plurality of conductive joining members 25b). The plurality of second conductive gate wires (the plurality of conductive gate wires 50b) connect the second gate electrodes (gate electrodes 23b) of the plurality of second self-arc-extinguishing semiconductor elements and the second gate conductive pattern (gate conductive pattern 36b). In a plan view of the third principal surface of the insulating substrate, a second longitudinal direction (first direction (x direction)) of the second gate conductive pattern coincides with a second array direction (first direction (x direction)) of the plurality of second self-arc-extinguishing semiconductor elements.

Power semiconductor module 1c of the present embodiment includes the plurality of second self-arc-extinguishing semiconductor elements (the plurality of self-arc-extinguishing semiconductor elements 20b). This allows an increase in power capacity of power semiconductor module 1c. In a plan view of third principal surface 31b of insulating substrate 31, the first longitudinal direction of the second gate conductive pattern (gate conductive pattern 36b) coincides with the second array direction of the plurality of second self-arc-extinguishing semiconductor elements. Therefore, even when the number of the plurality of second self-arc-extinguishing semiconductor elements included in power semiconductor module 1c is increased, a common gate voltage can be easily applied to the second gate electrodes (gate electrodes 23b) of the plurality of second self-arc-extinguishing semiconductor elements.

The second source electrodes (source electrode 22b) of the plurality of second self-arc-extinguishing semiconductor elements (the plurality of self-arc-extinguishing semiconductor elements 20b) are joined to the first source conductive pattern (source conductive pattern 33) by means of the plurality of second conductive joining members (the plurality of conductive joining members 25b). The plurality of second conductive joining members (the plurality of conductive joining members 25b) are each lower in parasitic inductance than each of the plurality of second conductive gate wires (gate conductive pattern 36b). Therefore, even when the plurality of second self-arc-extinguishing semiconductor elements are operated at a high frequency, it is possible to reduce the induced electromotive force generated between the second source electrodes of the plurality of second self-arc-extinguishing semiconductor elements. It is possible to prevent generation of a surge voltage between the second source electrodes and the second drain electrodes (drain electrodes 21a) of the plurality of second self-arc-extinguishing semiconductor elements. It is possible to make power semiconductor module 1c longer in lifetime while increasing the operation frequency of power semiconductor module 1c.

The plurality of second conductive gate wires (the plurality of conductive gate wires 50b) connect the second gate electrodes (gate electrode 23b) of the plurality of second self-arc-extinguishing semiconductor elements (the plurality of self-arc-extinguishing semiconductor elements 20b) and the second gate conductive pattern (gate conductive pattern 36b). The plurality of second conductive gate wires are each higher in parasitic inductance than each of the plurality of second conductive joining members (the plurality of conductive joining members 25b). The increased parasitic impedance of each of the plurality of second conductive gate wires attenuates the oscillation of the gate voltage. It is therefore possible to reduce or prevent the oscillation of the gate voltage applied to the plurality of second self-arc-extinguishing semiconductor elements.

The first gate conductive pattern (gate conductive pattern 36) and the second gate conductive pattern (gate conductive pattern 36b) are electrically connected to each other. Therefore, a length of the entire gate conductive pattern including the first gate conductive pattern (gate conductive pattern 36) and the second gate conductive pattern (gate conductive pattern 36b) increases. The parasitic inductance and the parasitic impedance of the entire gate conductive pattern increase. The increased parasitic impedance of the entire gate conductive pattern attenuates the oscillation of the gate voltage. It is therefore possible to reduce or prevent the oscillation of the gate voltage.

In power semiconductor module 1c of the present embodiment, the second gate conductive pattern (gate conductive pattern 36b) is provided on third principal surface 31b of insulating substrate 31. In a plan view of third principal surface 31b of insulating substrate 31, the second gate electrodes (gate electrodes 23b) are exposed from insulating substrate 31.

The second gate conductive pattern (gate conductive pattern 36b) is provided on third principal surface 31b of insulating substrate 31, third principal surface 31b being remote from the second gate electrodes (gate electrodes 23b) relative to second principal surface 31 a of insulating substrate 31. The length of each of the plurality of second conductive gate wires (the plurality of conductive gate wires 50b) can be increased. The parasitic inductance and the parasitic impedance of each of the plurality of second conductive gate wires can be increased. The oscillation of the gate voltage applied to the plurality of second self-arc-extinguishing semiconductor elements (the plurality of self-arc-extinguishing semiconductor elements 20b) can be reduced or prevented. Furthermore, in a plan view of third principal surface 31b of insulating substrate 31, since the second gate electrodes of the plurality of second self-arc-extinguishing semiconductor elements are exposed from insulating substrate 31, the plurality of second conductive gate wires can be easily bonded to the second gate electrodes of the plurality of second self-arc-extinguishing semiconductor elements and the second gate conductive pattern.

In power semiconductor module 1c of the present embodiment, a third length (length L_{g2}) of the second gate conductive pattern (gate conductive pattern 36b) in the second longitudinal direction (first direction (x direction)) of the second gate conductive pattern (gate conductive pattern 36b) is greater than or equal to a fourth length (length L_{c2}) of the plurality of second self-arc-extinguishing semiconductor elements (the plurality of self-arc-extinguishing semiconductor elements 20b) in the second array direction (first direction (x direction)) of the plurality of second self-arc-extinguishing semiconductor elements.

Therefore, the third length (length L_{g2}) of the second gate conductive pattern (gate conductive pattern 36b) can be increased. The parasitic inductance and the parasitic impedance of the second gate conductive pattern can be increased. The oscillation of the gate voltage applied to the plurality of second self-arc-extinguishing semiconductor elements (the plurality of self-arc-extinguishing semiconductor elements 20b) can be reduced or prevented.

In power semiconductor module 1c of the present embodiment, the second gate conductive pattern (gate conductive pattern 36b) is disposed along second edge 31d of insulating substrate 31 in a plan view of third principal surface 31b of insulating substrate 31. The plurality of second self-arc-extinguishing semiconductor elements (the plurality of self-arc-extinguishing semiconductor elements 20b) are disposed along second edge 31d of insulating substrate 31.

Therefore, the plurality of second conductive gate wires (the plurality of conductive gate wires 50b) can be easily bonded to the second gate electrodes (gate electrodes 23b) of the plurality of second self-arc-extinguishing semiconductor elements (the plurality of self-arc-extinguishing semiconductor elements 20b) and the second gate conductive pattern (gate conductive pattern 36b).

In power semiconductor module 1c of the present embodiment, a third width (width w_{g2}) of a second gate conductive pattern portion (portion 36q) of the second gate conductive pattern (gate conductive pattern 36b), the second gate conductive pattern portion corresponding to the plurality of second self-arc-extinguishing semiconductor elements (the plurality of self-arc-extinguishing semiconductor elements 20b) in the second longitudinal direction (first direction (x direction)) of the second gate conductive pattern in a plan view of third principal surface 31b of insulating substrate 31, is less than a fourth width (width wₛ₂) of a second source conductive pattern portion (portion 33q) of the first source conductive pattern (source conductive pattern 33), the second source conductive pattern portion corresponding to the plurality of second self-arc-extinguishing semiconductor elements in the second longitudinal direction of the second gate conductive pattern in a plan view of third principal surface 31b of insulating substrate 31. The third width of the second gate conductive pattern portion coincides with a length of the second gate conductive pattern portion in a second lateral direction (second direction (y direction)) of the second gate conductive pattern orthogonal to the second longitudinal direction of the second gate conductive pattern. The fourth width of the second source conductive pattern portion coincides with a length of the second source conductive pattern portion in the second lateral direction of the second gate conductive pattern.

Therefore, the parasitic inductance of the first source conductive pattern (source conductive pattern 33) can be reduced. Even when the plurality of second self-arc-extinguishing semiconductor elements (the plurality of self-arc-extinguishing semiconductor elements 20b) are operated at a high frequency, the induced electromotive force generated between the second source electrodes (source electrodes 22b) of the plurality of second self-arc-extinguishing semiconductor elements can be reduced. It is possible to prevent generation of a surge voltage between the second source electrodes and the second drain electrodes (drain electrodes 21b) of the plurality of second self-arc-extinguishing semiconductor elements. It is possible to make power semiconductor module 1c longer in lifetime while increasing the operation frequency of power semiconductor module 1c.

Further, the parasitic inductance and the parasitic impedance of the second gate conductive pattern (gate conductive pattern 36b) can be increased. The increased parasitic impedance of the second gate conductive pattern attenuates the oscillation of the gate voltage. Therefore, the oscillation of the gate voltage applied to the plurality of second self-arc-extinguishing semiconductor elements (the plurality of self-arc-extinguishing semiconductor elements 20b) can be reduced or prevented.

In power semiconductor module 1c of the present embodiment, printed wiring board 30 further includes a third gate conductive pattern (gate conductive pattern 36c) that connects the first gate conductive pattern (gate conductive pattern 36) and the second gate conductive pattern (gate conductive pattern 36b).

Therefore, a length of the entire gate conductive pattern including the first gate conductive pattern (gate conductive pattern 36), the second gate conductive pattern (gate conductive pattern 36b), and the third gate conductive pattern (gate conductive pattern 36c) increases. The parasitic inductance and the parasitic impedance of the entire gate conductive pattern increase. The increased parasitic impedance of the entire gate conductive pattern attenuates the oscillation of the gate voltage. It is therefore possible to reduce or prevent the oscillation of the gate voltage.

### Fourth Embodiment

With reference to FIGS. 16 to 23, a power semiconductor module 1d of a fourth embodiment will be described. Power semiconductor module 1d of the present embodiment is similar in configuration to power semiconductor module 1 of the first embodiment, but is different mainly in the following points.

Power semiconductor module 1d further includes a plurality of self-arc-extinguishing semiconductor elements 20b, a plurality of conductive joining members 25b, a plurality of conductive joining members 15b, a plurality of conductive gate wires 50b, an electrode terminal 62, an electrode terminal 64, a second first source control terminal 46b, a conductive wire 47b, a second first gate control terminal 48b, a conductive wire 49b, and a conductive block 70. Power semiconductor module 1d may further include a plurality of second freewheeling diodes 20i.

Insulating circuit board 10 further includes a second conductive circuit pattern 13b. Second conductive circuit pattern 13b is provided on first principal surface 12a of insulating plate 12. Second conductive circuit pattern 13b is separated from first conductive circuit pattern 13 and electrically insulated from first conductive circuit pattern 13. In a plan view of third principal surface 31b of insulating substrate 31, second conductive circuit pattern 13b is separated from first conductive circuit pattern 13 in the second direction (y direction) orthogonal to the longitudinal direction (first direction (x direction)) of gate conductive pattern 36 or the longitudinal direction (first direction (x direction)) of insulating substrate 31. Second conductive circuit pattern 13b is formed of metal such as copper or aluminum.

The plurality of self-arc-extinguishing semiconductor elements 20b of the present embodiment are similar to the plurality of self-arc-extinguishing semiconductor elements 20b of the third embodiment, but are fixed to second conductive circuit pattern 13b and a source conductive pattern 53 of printed wiring board 30 as illustrated in FIG. 21. Specifically, drain electrodes 21b of the plurality of self-arc-extinguishing semiconductor elements 20b are joined to second conductive circuit pattern 13b by means of conductive joining members 15b such as solder, a metal fine particle sintered body, or a conductive adhesive. Specifically, source electrodes 22b of the plurality of self-arc-extinguishing semiconductor elements 20b are joined to source conductive pattern 53 of printed wiring board 30 by means of conductive joining members 25b such as solder, a metal fine particle sintered body, or a conductive adhesive. The plurality of self-arc-extinguishing semiconductor elements 20b are electrically connected in parallel to each other. The plurality of self-arc-extinguishing semiconductor elements 20b are not electrically connected in parallel to the plurality of self-arc-extinguishing semiconductor elements 20a, and are electrically separated from the plurality of self-arc-extinguishing semiconductor elements 20a.

The plurality of second freewheeling diodes 20i are mainly formed of silicon (Si) or a wide band gap semiconductor material such as silicon carbide (SiC), gallium nitride (GaN), or diamond. The plurality of second freewheeling diodes 201 each include a second cathode electrode 21i and a second anode electrode 22i.

As illustrated in FIG. 20, the plurality of second freewheeling diodes 20i are fixed to second conductive circuit pattern 13b. Specifically, second cathode electrodes 21i of the plurality of second freewheeling diodes 20i are each joined to second conductive circuit pattern 13b by means of a conductive joining member 15i such as solder, a metal fine particle sintered body, or a conductive adhesive. The plurality of second freewheeling diodes 20i are fixed to printed wiring board 30. Specifically, second anode electrodes 22i of the plurality of second freewheeling diodes 20i are each joined to source conductive pattern 53 of printed wiring board 30 by means of a conductive joining member 25i such as solder, a metal fine particle sintered body, or a conductive adhesive. The plurality of second freewheeling diodes 20i are electrically connected in parallel to the plurality of self-arc-extinguishing semiconductor elements 20b.

Power semiconductor module 1d is a 2-in-1 module including two arms (an upper arm 73 and a lower arm 74). As illustrated in FIG. 17, upper arm 73 includes the plurality of self-arc-extinguishing semiconductor elements 20a and the plurality of first freewheeling diodes 20h joined to first conductive circuit pattern 13 and source conductive pattern 33. Lower arm 74 includes the plurality of self-arc-extinguishing semiconductor elements 20b and the plurality of second freewheeling diodes 20i joined to second conductive circuit pattern 13b and source conductive pattern 53.

Printed wiring board 30 further includes source conductive pattern 53, conductive pads 57, 67, gate conductive pattern 36b, and conductive vias 58, 66, 68. Source conductive pattern 53, conductive pad 67, gate conductive pattern 36b, and conductive pad 57 are formed of metal such as copper or aluminum. Source conductive pattern 53 and conductive pad 67 are provided on second principal surface 31a of insulating substrate 31. Source conductive pattern 33, conductive pad 34, source conductive pattern 53, and conductive pad 67 are separated from each other and electrically insulated from each other. Gate conductive pattern 36b and conductive pad 57 are provided on third principal surface 31b of insulating substrate 31. Source conductive pattern 35, gate conductive pattern 36, gate conductive pattern 36b, conductive pad 37, and conductive pad 57 are separated from each other and electrically insulated from each other.

Source conductive pattern 53 extends in the first direction (x direction) and the second direction (y direction). A longitudinal direction of source conductive pattern 53 coincides with the first direction (x direction), and the lateral direction of source conductive pattern 33 coincides with the second direction (y direction). Source conductive pattern 53 includes an edge 53a extending in the longitudinal direction (first direction (x direction)) of source conductive pattern 53. Edge 53a of source conductive pattern 53 may be a long side of source conductive pattern 53 in a plan view of third principal surface 31b of insulating substrate 31. Edge 53a of source conductive pattern 53 is closer to second edge 31d of insulating substrate 31 rather than first edge 31c of insulating substrate 31.

In a plan view of third principal surface 31b of insulating substrate 31, source conductive pattern 53 is separated from source conductive pattern 33 in the second direction (y direction) orthogonal to the longitudinal direction (first direction (x direction)) of gate conductive pattern 36, the longitudinal direction (first direction (x direction)) of gate conductive pattern 36b, or the longitudinal direction (first direction (x direction)) of insulating substrate 31. In a plan view of third principal surface 31b of insulating substrate 31, source conductive pattern 53 covers source electrodes 22b of the plurality of self-arc-extinguishing semiconductor elements 20b. In a plan view of third principal surface 31b of insulating substrate 31, source conductive pattern 53 further covers second cathode electrodes 21i of the plurality of second freewheeling diodes 20i.

In a plan view of third principal surface 31b of insulating substrate 31, source conductive pattern 35 is disposed directly above source conductive pattern 33 and source conductive pattern 53. In a plan view of third principal surface 31b of insulating substrate 31, source conductive pattern 35 covers source electrodes 22a, 22b of the plurality of self-arc-extinguishing semiconductor elements 20a, 20b. In a plan view of third principal surface 31b of insulating substrate 31, source conductive pattern 35 further covers first cathode electrodes 21h of the plurality of first freewheeling diodes 20h and second cathode electrodes 21i of the plurality of second freewheeling diodes 20i.

Conductive via 32 electrically connects source conductive pattern 53 and source conductive pattern 35. Conductive via 32 extends through insulating substrate 31. Conductive via 32 is formed of metal such as copper or aluminum.

In a plan view of third principal surface 31b of insulating substrate 31, conductive pad 57 and conductive pad 67 are disposed along fourth edge 31f of insulating substrate 31.

Gate conductive pattern 36b of the present embodiment is similar to gate conductive pattern 36b of the third embodiment, but is different in the following points. Gate conductive pattern 36b is not electrically connected to gate conductive pattern 36b. The longitudinal direction of gate conductive pattern 36b coincides with the first direction (x direction) in which edge 53a of source conductive pattern 53 extends. Gate conductive pattern 36b is disposed along edge 53a of source conductive pattern 53. Specifically, in a plan view of third principal surface 31b of insulating substrate 31, gate conductive pattern 36b is disposed directly above edge 53a of source conductive pattern 53.

As illustrated in FIGS. 16, 22, and 23, a width w_{g2} of a portion 36q of gate conductive pattern 36b, portion 36q corresponding to the plurality of self-arc-extinguishing semiconductor elements 20b in the longitudinal direction (first direction (x direction)) of gate conductive pattern 36b in a plan view of third principal surface 31b of insulating substrate 31, is less than a width wₛ₂ of a portion 53p of source conductive pattern 53, portion 53p corresponding to the plurality of self-arc-extinguishing semiconductor elements 20b in the longitudinal direction (first direction (x direction)) of gate conductive pattern 36b in a plan view of third principal surface 31b of insulating substrate 31. Width w_{g2} of portion 36q of gate conductive pattern 36b is defined as a length of portion 36q of gate conductive pattern 36b in the lateral direction (second direction (y direction)) of gate conductive pattern 36b. Width wₛ₂ of portion 53p of source conductive pattern 53 is defined as a length of portion 53p of source conductive pattern 53 in the lateral direction (second direction (y direction)) of gate conductive pattern 36b.

Width w_{g2} of portion 36q of gate conductive pattern 36b may be less than or equal to one half of width wₛ₂ of portion 53p of source conductive pattern 53, less than or equal to one third of width wₛ₂ of portion 53p of source conductive pattern 53, less than or equal to one fourth of width wₛ₂ of portion 53p of source conductive pattern 53, or less than or equal to one fifth of width wₛ₂ of portion 53p of source conductive pattern 53.

Since width w_{g2} of portion 36q of gate conductive pattern 36b is less than width wₛ₂ of portion 53p of source conductive pattern 53, the parasitic inductance of gate conductive pattern 36b between the plurality of self-arc-extinguishing semiconductor elements 20b can be made higher than the parasitic inductance of source conductive pattern 53 between the plurality of self-arc-extinguishing semiconductor elements 20b.

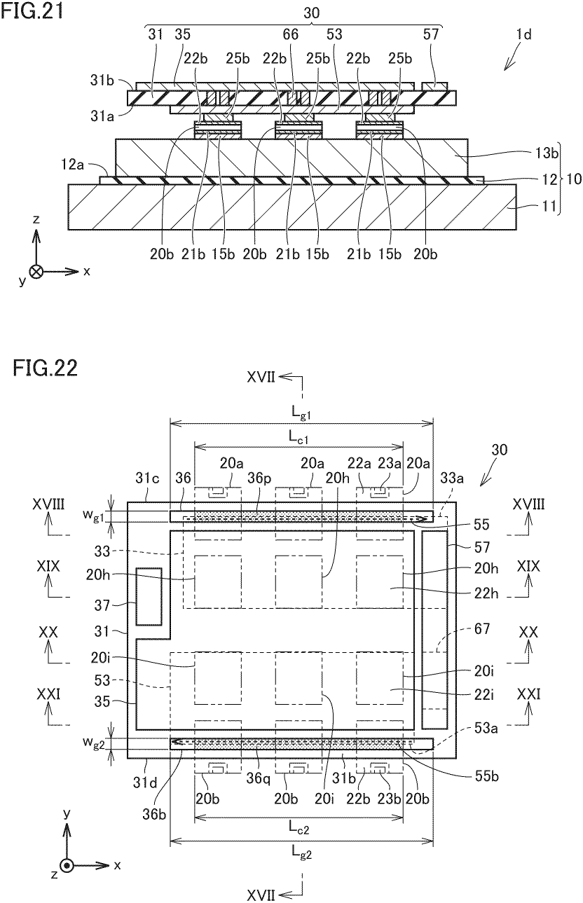

The plurality of self-arc-extinguishing semiconductor elements 20b are disposed along second edge 31d of insulating substrate 31. The plurality of self-arc-extinguishing semiconductor elements 20b are disposed along edge 53a of source conductive pattern 53. The plurality of self-arc-extinguishing semiconductor elements 20b are disposed along gate conductive pattern 36b. In a plan view of third principal surface 31b of insulating substrate 31, the longitudinal direction (first direction (x direction)) of gate conductive pattern 36b coincides with an array direction (first direction (x direction)) of the plurality of self-arc-extinguishing semiconductor elements 20b. As illustrated in FIGS. 16 and 22, a length L_{g2} of gate conductive pattern 36b in the longitudinal direction (first direction (x direction)) of gate conductive pattern 36b is greater than or equal to a length L_{c2} of the plurality of self-arc-extinguishing semiconductor elements 20b in the array direction (first direction (x direction)) of the plurality of self-arc-extinguishing semiconductor elements 20b. In a plan view of third principal surface 31b of insulating substrate 31, gate electrodes 23b of the plurality of self-arc-extinguishing semiconductor elements 20b are exposed from insulating substrate 31 (printed wiring board 30).

The plurality of conductive gate wires 50b of the present embodiment are similar to the plurality of conductive gate wires 50b of the third embodiment.

Electrode terminal 62 and electrode terminal 64 are formed of metal such as copper or aluminum. As illustrated in FIG. 16, in a plan view of the third principal surface 31b of insulating substrate 31, electrode terminal 42 and electrode terminal 44 are disposed adjacent to third edge 31 e of insulating substrate 31. In a plan view of third principal surface 31b of insulating substrate 31, electrode terminal 62 and electrode terminal 64 are disposed adjacent to fourth edge 31f of insulating substrate 31.

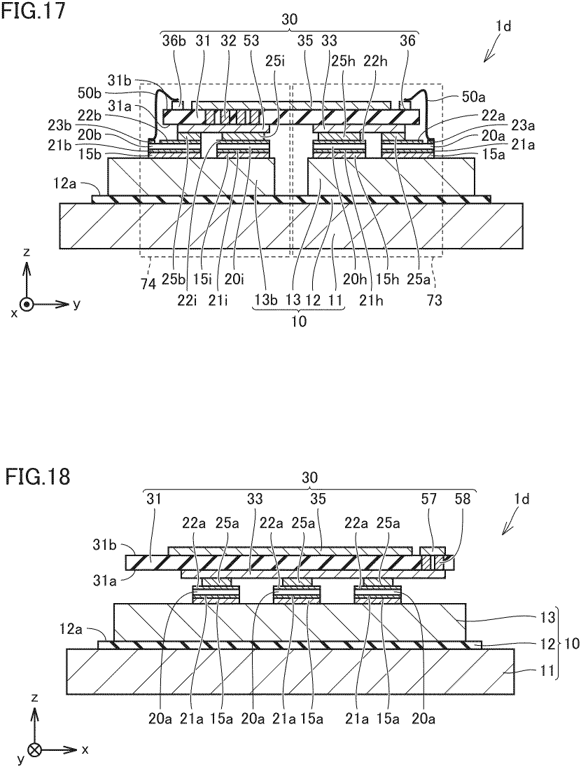

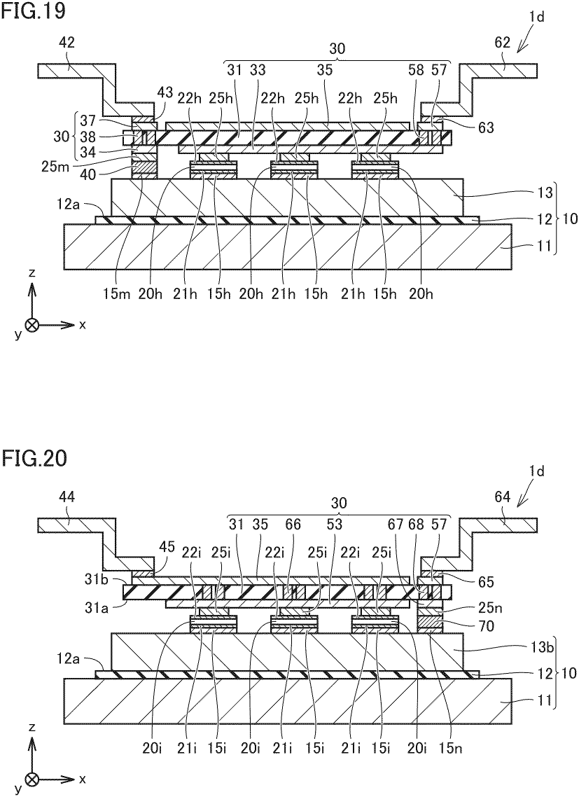

As illustrated in FIGS. 18 and 19, as with electrode terminal 42 of the first embodiment, electrode terminal 42 of the present embodiment is electrically connected to drain electrodes 21a of the plurality of self-arc-extinguishing semiconductor elements 20a via conductive joining member 43, conductive pad 37, conductive via 38, conductive pad 34, conductive joining member 25 m, conductive block 40, conductive joining member 15 m, first conductive circuit pattern 13, and conductive joining member 15a. Electrode terminal 42 is electrically connected to drain electrodes 21a of the plurality of self-arc-extinguishing semiconductor elements 20a via first conductive circuit pattern 13 without a conductive wire. Electrode terminal 42 functions as a drain electrode terminal of upper arm 73. Electrode terminal 42 is a path end, in power semiconductor module 1d, of a first path of a first main current (main current 55) flowing through upper arm 73 (that is, flowing between source electrodes 22a and drain electrodes 21a of the plurality of self-arc-extinguishing semiconductor elements 20a). A part of first conductive circuit pattern 13 functions as a first drain conductive pattern. That is, first conductive circuit pattern 13 includes the first drain conductive pattern.

As illustrated in FIG. 19, electrode terminal 62 is joined to conductive pad 57 by means of a conductive joining member 63 such as solder. Conductive via 58 electrically connects conductive pad 57 and source conductive pattern 33. Conductive via 58 extends through insulating substrate 31. Conductive via 58 is formed of metal such as copper or aluminum.

As illustrated in FIGS. 18 and 19, electrode terminal 62 is electrically connected to source electrodes 22a of the plurality of self-arc-extinguishing semiconductor elements 20a via conductive joining member 63, conductive pad 57, conductive via 58, source conductive pattern 33, and conductive joining member 25a. Electrode terminal 62 is electrically connected to source electrodes 22a of the plurality of self-arc-extinguishing semiconductor elements 20a via source conductive pattern 33 without a conductive wire. Electrode terminal 62 functions as a source electrode terminal of upper arm 73. Electrode terminal 62 is a path end, in power semiconductor module 1d, of the first path of the first main current (main current 55) flowing through upper arm 73 (that is, flowing between source electrodes 22a and drain electrodes 21a of the plurality of self-arc-extinguishing semiconductor elements 20a).

As illustrated in FIG. 20, electrode terminal 64 is joined to conductive pad 57 by means of a conductive joining member 65 such as solder. Conductive via 68 electrically connects conductive pad 57 and conductive pad 67. Conductive via 68 extends through insulating substrate 31. Conductive via 68 is formed of metal such as copper or aluminum. Conductive block 70 electrically connects conductive pad 67 and second conductive circuit pattern 13b. Conductive block 70 is joined to conductive pad 67 by means of a conductive joining member 25n such as solder. Conductive block 70 is joined to second conductive circuit pattern 13b by means of a conductive joining member 15n such as solder.

As illustrated in FIGS. 20 and 21, electrode terminal 64 is electrically connected to drain electrodes 21b of the plurality of self-arc-extinguishing semiconductor elements 20b via conductive joining member 65, conductive pad 57, conductive via 68, conductive pad 67, conductive joining member 25n, conductive block 70, conductive joining member 15n, second conductive circuit pattern 13b, and conductive joining member 15b. Electrode terminal 64 is electrically connected to drain electrodes 21b of the plurality of self-arc-extinguishing semiconductor elements 20b via second conductive circuit pattern 13b without a conductive wire. Electrode terminal 64 functions as a drain electrode terminal of lower arm 74. Electrode terminal 64 is a path end, in power semiconductor module 1d, of a second path of a second main current (main current 55b) flowing through lower arm 74 (that is, flowing between source electrodes 22b and drain electrodes 21b of the plurality of self-arc-extinguishing semiconductor elements 20b). A part of second conductive circuit pattern 13b functions as a second drain conductive pattern. That is, second conductive circuit pattern 13b includes the second drain conductive pattern.

As illustrated in FIG. 20, electrode terminal 44 is joined to source conductive pattern 35 by means of conductive joining member 45 such as solder. Conductive via 66 electrically connects source conductive pattern 35 and source conductive pattern 53. Conductive via 66 extends through insulating substrate 31. Conductive via 66 is formed of metal such as copper or aluminum.

As illustrated in FIGS. 20 and 21, electrode terminal 44 is electrically connected to source electrodes 22b of the plurality of self-arc-extinguishing semiconductor elements 20b via conductive joining member 45, source conductive pattern 35, conductive via 66, source conductive pattern 53, and conductive joining member 25b. Electrode terminal 44 is electrically connected to source electrodes 22b of the plurality of self-arc-extinguishing semiconductor elements 20b via source conductive pattern 53 without a conductive wire. Electrode terminal 44 functions as a source electrode terminal of lower arm 74. Electrode terminal 44 is a path end, in power semiconductor module 1d, of the second path of the second main current (main current 55b) flowing through lower arm 74 (that is, flowing between source electrodes 22b and drain electrodes 21b of the plurality of self-arc-extinguishing semiconductor elements 20b).

Electrode terminals 42, 44 may each function as an input terminal connected to a power supply (not illustrated) via a smoothing coil (not illustrated). For example, electrode terminal 42 may function as a positive electrode input terminal connected to a positive electrode of the power supply, and electrode terminal 44 may function as a negative electrode input terminal connected to a negative electrode of the power supply. Electrode terminals 62, 64 may each function as an output terminal connected to a load such as a motor.

As illustrated in FIG. 16, conductive wire 47 connects conductive pad 57 and first source control terminal 46. Conductive wire 47 is bonded to conductive pad 57 and first source control terminal 46. The first source-gate voltage is applied between first source control terminal 46 and first gate control terminal 48 from the outside of power semiconductor module 1d. The plurality of self-arc-extinguishing semiconductor elements 20a are switched between the ON state and the OFF state in accordance with the first source-gate voltage.

Second first source control terminal 46b is provided, for example, on an insulating block (not illustrated) placed on base plate 11. Second first source control terminal 46b is formed of metal such as copper or aluminum. As illustrated in FIG. 16, conductive wire 47b connects source conductive pattern 35 and second first source control terminal 46b. Conductive wire 47b is bonded to source conductive pattern 35 and second first source control terminal 46b. Conductive wire 47b is formed of metal such as gold, silver, copper, or aluminum.

Second first gate control terminal 48b is provided, for example, on an insulating block (not illustrated) placed on base plate 11. Second first gate control terminal 48b is formed of metal such as copper or aluminum. As illustrated in FIG. 16, conductive wire 49b connects gate conductive pattern 36b and second first gate control terminal 48b. Conductive wire 49b is bonded to gate conductive pattern 36b and second first gate control terminal 48b. Conductive wire 49b is formed of metal such as gold, silver, copper, or aluminum. A second source-gate voltage is applied between second first source control terminal 46b and second first gate control terminal 48b from the outside of power semiconductor module 1d. The plurality of self-arc-extinguishing semiconductor elements 20b are switched between the ON state and the OFF state in accordance with the second source-gate voltage.

Power semiconductor module 1d of the present embodiment has the following effects in addition to the effects of power semiconductor module 1 of the first embodiment.

In power semiconductor module 1d, source electrodes 22b of the plurality of self-arc-extinguishing semiconductor elements 20b are joined to source conductive pattern 53 by means of the plurality of conductive joining members 25b. On the other hand, gate electrodes 23b of the plurality of self-arc-extinguishing semiconductor elements 20b are connected to gate conductive pattern 36b by means of the plurality of conductive gate wires 50b. A thickness of each of the plurality of conductive joining members 25b is less than a length of each of the plurality of conductive gate wires 50b. Each of the plurality of conductive joining members 25b is greater in cross-sectional area than each of the plurality of conductive gate wires 50b. The cross-sectional area of each of the plurality of conductive joining members 25b is defined as an area of a cross section of each of the plurality of conductive joining members 25b orthogonal to the thickness direction (third direction (z direction)) of each of the plurality of conductive joining members 25b. The cross-sectional area of each of the plurality of conductive gate wires 50b is defined as an area of a cross-section of each of the plurality of conductive gate wires 50b orthogonal to a longitudinal direction of each of the plurality of conductive gate wires 50b.

In general, as the length of a conductor increases, the parasitic inductance of the conductor increases. As the cross-sectional area of the conductor decreases, the parasitic inductance of the conductor increases. Therefore, the parasitic inductance of each of the plurality of conductive gate wires 50b can be increased. The parasitic inductance of each of the plurality of conductive joining members 25b can be reduced. Each of the plurality of conductive gate wires 50b can be made higher in parasitic inductance than each of the plurality of conductive joining members 25b. A difference between the parasitic inductance of each of the plurality of conductive gate wires 50b and the parasitic inductance of each of the plurality of conductive joining members 25b can be increased.

As described above, the parasitic inductance of each of the plurality of conductive joining members 25b joined to source conductive pattern 53 can be reduced. Therefore, even when the plurality of self-arc-extinguishing semiconductor elements 20b are operated at a high frequency and a time variation dl/dt of the second main current (main current 55b) flowing between source electrodes 22b and drain electrodes 21b of the plurality of self-arc-extinguishing semiconductor elements 20b increases, the induced electromotive force generated between source electrodes 22b of the plurality of self-arc-extinguishing semiconductor elements 20b can be reduced. It is possible to prevent generation of a surge voltage between source electrodes 22b and drain electrode 21b of the plurality of self-arc-extinguishing semiconductor elements 20b while increasing the operation frequency of power semiconductor module 1d.

Further, the parasitic inductance of each of the plurality of conductive gate wires 50b joined to gate conductive pattern 36b can be increased. As described above, as the inductance of a conductor increases, the impedance of the conductor also increases. Therefore, the parasitic impedance of each of the plurality of conductive gate wires 50b can be increased. The increased parasitic impedance of each of the plurality of conductive gate wires 50b attenuates the oscillation of the gate voltage. It is therefore possible to reduce or prevent the oscillation of the gate voltage applied to the plurality of self-arc-extinguishing semiconductor elements 20b.

Specifically, the thickness of conductive joining member 45, the thickness of conductive via 66, and the thickness of conductive joining member 25b are each less than the length of each of the plurality of conductive gate wires 50b. Conductive joining member 45, conductive via 66, and conductive joining member 25b are each greater in cross-sectional area than each of the plurality of conductive gate wires 50b. Therefore, conductive joining member 45, conductive via 66, and conductive joining member 25b are each lower in parasitic inductance than each of the plurality of conductive gate wires 50b.

Furthermore, source conductive pattern 53 is greater in cross-sectional area than gate conductive pattern 36b. Source conductive pattern 35 is greater in cross-sectional area than gate conductive pattern 36b. Note that the cross-sectional area of source conductive pattern 53 is defined as an area of a cross section of source conductive pattern 53 orthogonal to a direction (first direction (x direction)) in which the second main current (main current 55b) flows through source conductive pattern 53. The cross-sectional area of source conductive pattern 35 is defined as an area of a cross section of source conductive pattern 35 orthogonal to a direction (first direction (x direction)) in which the second main current (main current 55b) flows through source conductive pattern 35. The cross-sectional area of gate conductive pattern 36b is defined as an area of a cross section of gate conductive pattern 36b orthogonal to the longitudinal direction (first direction (x direction)) of gate conductive pattern 36b or the second array direction (first direction (x direction)) of the plurality of self-arc-extinguishing semiconductor elements 20b. Therefore, source conductive pattern 53 is lower in parasitic inductance than gate conductive pattern 36b. Source conductive pattern 35 is lower in parasitic inductance than gate conductive pattern 36b.

The thickness of conductive joining member 65, the thickness of conductive pad 57, the thickness of conductive via 68, the thickness of conductive pad 67, the thickness of conductive joining member 25n, the thickness of conductive block 70, the thickness of conductive joining member 15n, and the thickness of conductive joining member 15b are each less than the length of each of the plurality of conductive gate wires 50b. Conductive joining member 65, conductive pad 57, conductive via 68, conductive pad 67, conductive joining member 25n, conductive block 70, conductive joining member 15n, and conductive joining member 15b are each greater in cross-sectional area than each of the plurality of conductive gate wires 50b. Therefore, conductive joining member 65, conductive pad 57, conductive via 68, conductive pad 67, conductive joining member 25n, conductive block 70, conductive joining member 15n, and conductive joining member 15b are each lower in parasitic inductance than each of the plurality of conductive gate wires 50b.

Furthermore, second conductive circuit pattern 13b functioning as the drain conductive pattern is greater in cross-sectional area than gate conductive pattern 36b. Note that the cross-sectional area of second conductive circuit pattern 13b is defined as an area of a cross section of second conductive circuit pattern 13b orthogonal to a direction (first direction (x direction)) in which the second main current (main current 55b) flows through second conductive circuit pattern 13b. Therefore, second conductive circuit pattern 13b functioning as the drain conductive pattern is lower in parasitic inductance than gate conductive pattern 36b.

Therefore, a second source line extending from electrode terminal 44 to source electrodes 22b of the plurality of self-arc-extinguishing semiconductor elements 20b is lower in parasitic inductance than a second gate line extending from second first gate control terminal 48b to gate electrodes 23b of the plurality of self-arc-extinguishing semiconductor elements 20b. Even when the plurality of self-arc-extinguishing semiconductor elements 20b are operated at a high frequency, it is possible to prevent generation of a surge voltage between source electrodes 22b and drain electrodes 21b of the plurality of self-arc-extinguishing semiconductor elements 20b. It is possible to make power semiconductor module 1d longer in lifetime while increasing the operation frequency of power semiconductor module 1d.

A second drain line extending from electrode terminal 64 to drain electrodes 21bof the plurality of self-arc-extinguishing semiconductor elements 20b is lower in parasitic inductance than the second gate line extending from second first gate control terminal 48b to gate electrodes 23b of the plurality of self-arc-extinguishing semiconductor elements 20b. Even when the plurality of self-arc-extinguishing semiconductor elements 20b are operated at a high frequency, it is possible to prevent generation of a surge voltage between source electrodes 22b and drain electrodes 21b of the plurality of self-arc-extinguishing semiconductor elements 20b. It is possible to make power semiconductor module 1d longer in lifetime while increasing the operation frequency of power semiconductor module 1d.

As described above, as the impedance of a conductor increases, the inductance of the conductor also increases. The second gate line extending from second first gate control terminal 48b to gate electrodes 23b of the plurality of self-arc-extinguishing semiconductor elements 20b is higher in parasitic impedance than the second source line extending from electrode terminal 44 to source electrodes 22b of the plurality of self-arc-extinguishing semiconductor elements 20b. The second gate line extending from second first gate control terminal 48b to gate electrodes 23b of the plurality of self-arc-extinguishing semiconductor elements 20b is higher in parasitic impedance than the second drain line extending from electrode terminal 64 to drain electrodes 21b of the plurality of self-arc-extinguishing semiconductor elements 20b. The increased parasitic impedance of the second gate line can reduce or prevent the oscillation of the gate voltage applied to self-arc-extinguishing semiconductor elements 20b.

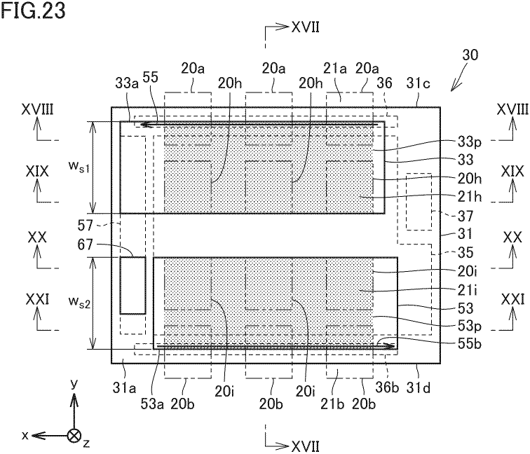

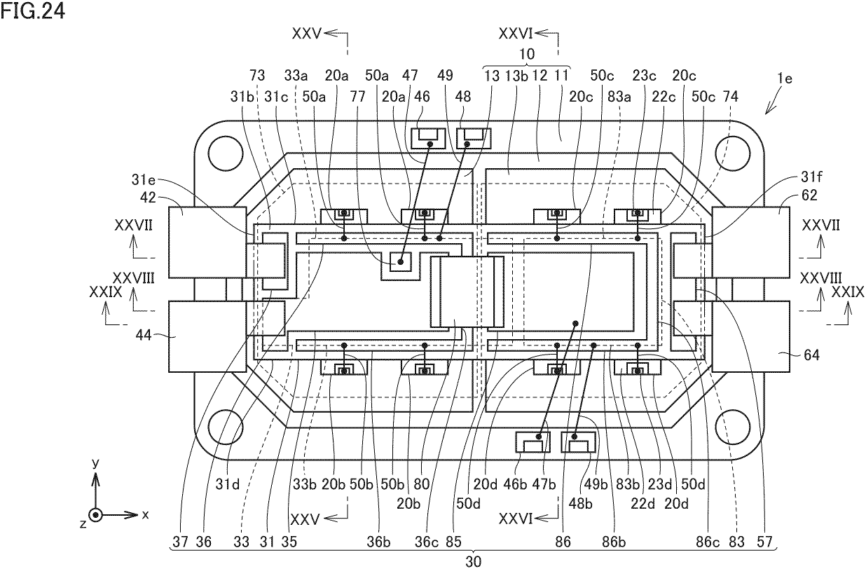

The gate-source voltage applied to each of the plurality of self-arc-extinguishing semiconductor elements 20b is made higher than the threshold voltage to turn on the plurality of self-arc-extinguishing semiconductor elements 20b. As illustrated in FIGS. 22 and 23, main current 55b flows through source conductive pattern 53. In general, the edge of a conductive pattern is a portion through which the most current flows in the conductive pattern. Therefore, as illustrated in FIGS. 22 and 23, main current 55b flows along edge 53a of source conductive pattern 53, edge 53a being located closest to the plurality of self-arc-extinguishing semiconductor elements 20b in source conductive pattern 53.

Main current 55b flowing through source conductive pattern 53 forms a magnetic flux around main current 55b (for example, in source conductive pattern 53). This magnetic flux and the parasitic inductance of source conductive pattern 53 generate an induced electromotive force in source conductive pattern 53. This induced electromotive force causes the source voltage to vary among the plurality of self-arc-extinguishing semiconductor elements 20b. The gate-source voltage varies among the plurality of self-arc-extinguishing semiconductor elements 20b. The drain-source current of one self-arc-extinguishing semiconductor element 20b among the plurality of self-arc-extinguishing semiconductor elements 20b may rapidly increase to destroy this one self-arc-extinguishing semiconductor element 20b.

In power semiconductor module 1d of the present embodiment, however, gate conductive pattern 36b is disposed along edge 53a of source conductive pattern 53 in a plan view of third principal surface 31b of insulating substrate 31. Therefore, main current 55b further forms a magnetic flux in gate conductive pattern 36b. This magnetic flux and the parasitic inductance of gate conductive pattern 36b generate an induced electromotive force in gate conductive pattern 36b. This induced electromotive force causes the gate voltage to vary among the plurality of self-arc-extinguishing semiconductor elements 20b. The variation in the gate voltage among the plurality of self-arc-extinguishing semiconductor elements 20b counteracts the variation in the gate-source voltage among the plurality of self-arc-extinguishing semiconductor elements 20b. The drain-source current of the plurality of self-arc-extinguishing semiconductor elements 20b is prevented from rapidly increasing. The plurality of self-arc-extinguishing semiconductor elements 20b are prevented from being destroyed, and it is therefore possible to make power semiconductor module 1d longer in lifetime.

Power semiconductor module 1d of the present embodiment has the following effects in addition to the effects of power semiconductor module 1 of the first embodiment.

Power semiconductor module 1d of the present embodiment further includes a plurality of second self-arc-extinguishing semiconductor elements (the plurality of self-arc-extinguishing semiconductor elements 20b), a plurality of second conductive joining members (the plurality of conductive joining members 25b), and a plurality of second conductive gate wires (the plurality of conductive gate wires 50b). Insulating circuit board 10 further includes second conductive circuit pattern 13b provided on first principal surface 12a of insulating plate 12 and electrically insulated from first conductive circuit pattern 13. Printed wiring board 30 further includes a second source conductive pattern (source conductive pattern 53) electrically insulated from a first source conductive pattern (source conductive pattern 33), and a second gate conductive pattern (gate conductive pattern 36b) electrically insulated from a first gate conductive pattern (gate conductive pattern 36). The plurality of second self-arc-extinguishing semiconductor elements each includes a second source electrode (source electrode 22b), a second gate electrode (gate electrode 23b), and a second drain electrode (drain electrode 21b).

The second drain electrodes (drain electrodes 21b) of the plurality of second self-arc-extinguishing semiconductor elements (the plurality of self-arc-extinguishing semiconductor elements 20b) are joined to second conductive circuit pattern 13b. The second source electrodes (source electrodes 22b) of the plurality of second self-arc-extinguishing semiconductor elements are joined to the second source conductive pattern (source conductive pattern 53) by means of the plurality of second conductive joining members (the plurality of conductive joining members 25b). The plurality of second conductive gate wires (the plurality of conductive gate wires 50b) connect the second gate electrodes (gate electrodes 23b) of the plurality of second self-arc-extinguishing semiconductor elements and the second gate conductive pattern (gate conductive pattern 36b). In a plan view of third principal surface 31b of insulating substrate 31, a second longitudinal direction (first direction (x direction)) of the second gate conductive pattern coincides with the second array direction (first direction (x direction)) of the plurality of second self-arc-extinguishing semiconductor elements.

Therefore, as with power semiconductor module 1 of the first embodiment, power semiconductor module 1d of the present embodiment can be made longer in lifetime while increasing the operation frequency of power semiconductor module 1d, and can reduce or prevent the oscillation of the gate voltage. Further, power semiconductor module 1d can be a 2-in-l module including upper arm 73 including the first self-arc-extinguishing semiconductor elements (the plurality of self-arc-extinguishing semiconductor elements 20a) and lower arm 74 including the second self-arc-extinguishing semiconductor elements (the plurality of self-arc-extinguishing semiconductor elements 20b).

In power semiconductor module 1d of the present embodiment, the second gate conductive pattern (gate conductive pattern 36b) is provided on third principal surface 31b of insulating substrate 31. In a plan view of third principal surface 31b of insulating substrate 31, the second gate electrodes (gate electrodes 23b) are exposed from insulating substrate 31.

With power semiconductor module 1d, as with power semiconductor module 1c of the third embodiment, it is possible to increase the parasitic inductance and the parasitic impedance of each of the plurality of second conductive gate wires (the plurality of conductive gate wires 50b), and reduce or prevent the oscillation of the gate voltage. Further, with power semiconductor module 1d, as with power semiconductor module 1c of the third embodiment, the plurality of second conductive gate wires can be easily bonded to the second gate electrodes (gate electrodes 23b) of the plurality of second self-arc-extinguishing semiconductor elements (the plurality of self-arc-extinguishing semiconductor elements 20b) and the second gate conductive pattern (gate conductive pattern 36b).

In power semiconductor module 1d of the present embodiment, a third length (length L_{g2}) of the second gate conductive pattern (gate conductive pattern 36b) in the second longitudinal direction (first direction (x direction)) of the second gate conductive pattern (gate conductive pattern 36b) is greater than or equal to a fourth length (length L_{c2}) of the plurality of second self-arc-extinguishing semiconductor elements (the plurality of self-arc-extinguishing semiconductor elements 20b) in the second array direction (first direction (x direction)) of the plurality of second self-arc-extinguishing semiconductor elements (the plurality of self-arc-extinguishing semiconductor elements 20b).

Therefore, the third length (length L_{g2}) of the second gate conductive pattern (gate conductive pattern 36b) can be increased. The parasitic inductance and the parasitic impedance of the second gate conductive pattern can be increased. The oscillation of the gate voltage applied to the plurality of second self-arc-extinguishing semiconductor elements (the plurality of self-arc-extinguishing semiconductor elements 20b) can be reduced or prevented.

In power semiconductor module 1d of the present embodiment, the second gate conductive pattern (gate conductive pattern 36b) is disposed along second edge 31d of insulating substrate 31 in a plan view of third principal surface 31b of insulating substrate 31. The plurality of second self-arc-extinguishing semiconductor elements (the plurality of self-arc-extinguishing semiconductor elements 20b) are disposed along second edge 31d of insulating substrate 31.

Therefore, the plurality of second conductive gate wires (the plurality of conductive gate wires 50b) can be easily bonded to the second gate electrodes (gate electrodes 23b) of the plurality of second self-arc-extinguishing semiconductor elements (the plurality of self-arc-extinguishing semiconductor elements 20b) and the second gate conductive pattern (gate conductive pattern 36b).

In power semiconductor module 1d of the present embodiment, a third width (width w_{g2}) of a second gate conductive pattern portion (portion 36q) of the second gate conductive pattern (gate conductive pattern 36b), the second gate conductive pattern portion corresponding to the plurality of second self-arc-extinguishing semiconductor elements (the plurality of self-arc-extinguishing semiconductor elements 20b) in the second longitudinal direction (first direction (x direction)) of the second gate conductive pattern in a plan view of third principal surface 31b of insulating substrate 31, is less than a fourth width (width wₛ₂) of a second source conductive pattern portion (portion 53p) of the second source conductive pattern (source conductive pattern 53), the second source conductive pattern portion corresponding to the plurality of second self-arc-extinguishing semiconductor elements in the second longitudinal direction of the second gate conductive pattern in a plan view of third principal surface 31b of insulating substrate 31. The third width (width w_{g2}) of the second gate conductive pattern portion coincides with a length of the second gate conductive pattern portion in a second lateral direction (second direction (y direction)) of the second gate conductive pattern orthogonal to the second longitudinal direction of the second gate conductive pattern. The fourth width (width wₛ₂) of the second source conductive pattern portion coincides with a length of the second source conductive pattern portion in the second lateral direction of the second gate conductive pattern.

Therefore, the parasitic inductance of the second source conductive pattern (source conductive pattern 53) can be reduced. Even when the plurality of second self-arc-extinguishing semiconductor elements (the plurality of self-arc-extinguishing semiconductor elements 20b) are operated at a high frequency, the induced electromotive force generated between the second source electrodes (source electrodes 22b) of the plurality of second self-arc-extinguishing semiconductor elements can be reduced. It is possible to prevent generation of a surge voltage between the second source electrodes and the second drain electrodes (drain electrodes 21b) of the plurality of second self-arc-extinguishing semiconductor elements. It is possible to make power semiconductor module 1d longer in lifetime while increasing the operation frequency of power semiconductor module 1d.

Further, the parasitic inductance and the parasitic impedance of the second gate conductive pattern (gate conductive pattern 36b) can be increased. The increased parasitic impedance of the second gate conductive pattern attenuates the oscillation of the gate voltage. It is therefore possible to reduce or prevent the oscillation of the gate voltage applied to the plurality of second self-arc-extinguishing semiconductor elements (the plurality of self-arc-extinguishing semiconductor elements 20b).

Power semiconductor module 1d of the present embodiment further includes the plurality of second freewheeling diodes 20i. The plurality of second freewheeling diodes 20i each include second cathode electrode 21i and second anode electrode 22i. Second cathode electrodes 21i of the plurality of second freewheeling diodes 20i are joined to second conductive circuit pattern 13b. Second anode electrodes 22i of the plurality of second freewheeling diodes 20i are joined to the second source conductive pattern (source conductive pattern 53). In a plan view of third principal surface 31b of insulating substrate 31, the second source conductive pattern (source conductive pattern 53) covers the second source electrodes (source electrodes 22b) of the plurality of second self-arc-extinguishing semiconductor elements (the plurality of self-arc-extinguishing semiconductor elements 20b) and second cathode electrodes 21i of second freewheeling diodes 20i.

Therefore, the width of the second source conductive pattern (source conductive pattern 53) can be further increased. The parasitic inductance of the second source conductive pattern can be reduced. Even when the plurality of second self-arc-extinguishing semiconductor elements (the plurality of self-arc-extinguishing semiconductor elements 20b) are operated at a high frequency, the induced electromotive force generated between the second source electrodes (source electrodes 22b) of the plurality of second self-arc-extinguishing semiconductor elements can be reduced. It is possible to prevent generation of a surge voltage between the second source electrodes and the second drain electrodes (drain electrodes 21b) of the plurality of second self-arc-extinguishing semiconductor elements. It is possible to make power semiconductor module 1d longer in lifetime while increasing the operation frequency of power semiconductor module 1d.

Power semiconductor module 1d of the present embodiment further includes a first electrode terminal (electrode terminal 62) and a second electrode terminal (electrode terminal 42). The first electrode terminal is a first path end, in power semiconductor module 1d, of the first path of the first main current (main current 55) flowing between the first source electrodes (source electrodes 22a) and the first drain electrodes (drain electrodes 21a) of the plurality of first self-arc-extinguishing semiconductor elements (the plurality of self-arc-extinguishing semiconductor elements 20a). The second electrode terminal is a second path end, in power semiconductor module 1d, of the first path of the first main current (main current 55). The first electrode terminal is electrically connected to the first source electrodes of the plurality of first self-arc-extinguishing semiconductor elements via the first source conductive pattern (source conductive pattern 33) without a conductive wire. The second electrode terminal is electrically connected to the first drain electrodes (drain electrodes 21a) of the plurality of first self-arc-extinguishing semiconductor elements via first conductive circuit pattern 13 without a conductive wire.

Therefore, parasitic inductance of a first source line extending from the first electrode terminal (electrode terminal 62) to the first source electrodes (source electrodes 22a) of the plurality of first self-arc-extinguishing semiconductor elements (the plurality of self-arc-extinguishing semiconductor elements 20a) can be reduced. Parasitic inductance of a first drain line extending from the second electrode terminal (electrode terminal 42) to the first drain electrodes (drain electrodes 21a) of the plurality of first self-arc-extinguishing semiconductor elements can be reduced. It is therefore possible to prevent generation of a surge voltage between the first source electrodes and the first drain electrodes of the plurality of first self-arc-extinguishing semiconductor elements. It is possible to make power semiconductor module 1d longer in lifetime while increasing the operation frequency of power semiconductor module 1d.

Power semiconductor module 1d of the present embodiment further includes a third electrode terminal (electrode terminal 44) and a fourth electrode terminal (electrode terminal 64). The third electrode terminal is a third path end, in power semiconductor module 1d, of the second path of the second main current (main current 55b) flowing between the second source electrodes (source electrodes 22b) and the second drain electrodes (drain electrodes 21b) of the plurality of second self-arc-extinguishing semiconductor elements (the plurality of self-arc-extinguishing semiconductor elements 20b). The fourth electrode terminal is a fourth path end, in power semiconductor module 1d, of the second path of the second main current (main current 55b). The third electrode terminal is electrically connected to the second source electrodes of the plurality of first self-arc-extinguishing semiconductor elements via the second source conductive pattern (source conductive pattern 53) without a conductive wire. The fourth electrode terminal is electrically connected to the second drain electrodes of the plurality of first self-arc-extinguishing semiconductor elements via second conductive circuit pattern 13b without a conductive wire.

Therefore, the parasitic inductance of the second source line extending from the third electrode terminal (electrode terminal 44) to the second source electrodes (source electrodes 22b) of the plurality of second self-arc-extinguishing semiconductor elements (the plurality of self-arc-extinguishing semiconductor elements 20b) can be reduced. The parasitic inductance of the second drain line extending from the fourth electrode terminal (electrode terminal 64) to the second drain electrodes (drain electrodes 21b) of the plurality of second self-arc-extinguishing semiconductor elements can be reduced. It is therefore possible to prevent generation of a surge voltage between the second source electrodes and the second drain electrodes of the plurality of second self-arc-extinguishing semiconductor elements. It is possible to make power semiconductor module 1d longer in lifetime while increasing the operation frequency of power semiconductor module 1d.

### Fifth Embodiment

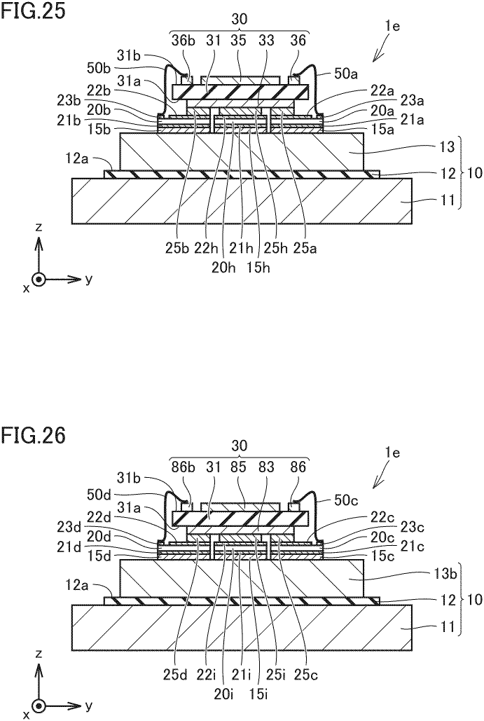

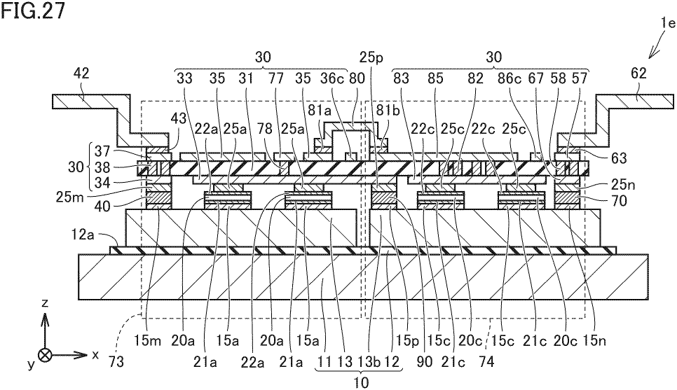

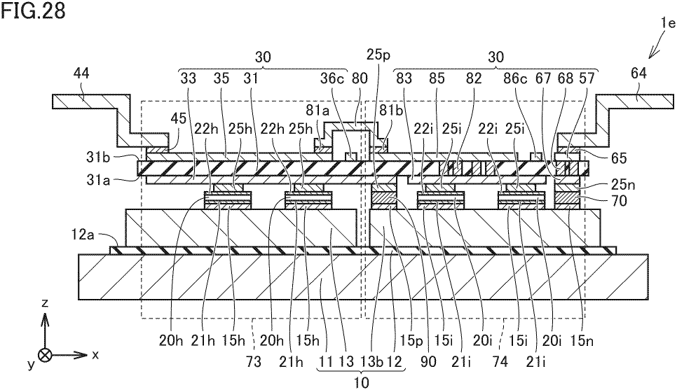

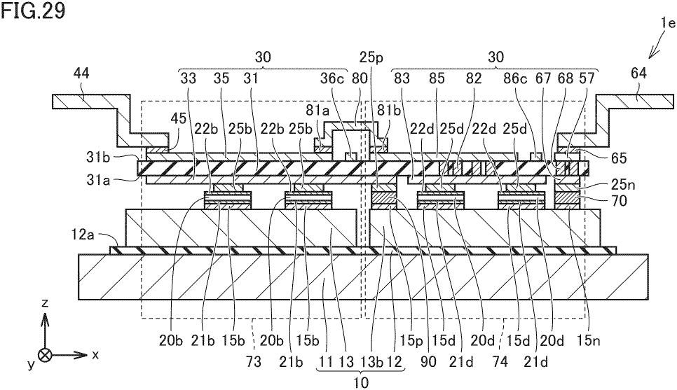

With reference to FIGS. 24 to 31, a power semiconductor module 1e according to a fifth embodiment will be described. Power semiconductor module 1e of the present embodiment is similar in configuration to power semiconductor module 1c of the third embodiment, but is different mainly in the following points.

Power semiconductor module 1e further includes a plurality of self-arc-extinguishing semiconductor elements 20c, a plurality of self-arc-extinguishing semiconductor elements 20d, a plurality of conductive joining members 25c, a plurality of conductive joining members 25d, a plurality of conductive gate wires 50c, a plurality of conductive gate wires 50d, an electrode terminal 62, an electrode terminal 64, a second first source control terminal 46b, a second first gate control terminal 48b, conductive wires 47b, 49b, conductive blocks 70, 90, and a conductive bridge 80. Power semiconductor module 1e may further include a plurality of second freewheeling diodes 20i.

A second conductive circuit pattern 13b is the same as second conductive circuit pattern 13b of the fourth embodiment. In the present embodiment, however, in a plan view of third principal surface 31b of insulating substrate 31, second conductive circuit pattern 13b is separated from first conductive circuit pattern 13 in the longitudinal direction (first direction (x direction)) of gate conductive pattern 36, the longitudinal direction (first direction (x direction)) of gate conductive pattern 36b, or the longitudinal direction (first direction (x direction)) of insulating substrate 31.

Each of the plurality of self-arc-extinguishing semiconductor elements 20c, 20d is a self-arc-extinguishing semiconductor element such as an insulated-gate bipolar transistor (IGBT) or a metal-oxide-semiconductor field-effect transistor (MOSFET). The plurality of self-arc-extinguishing semiconductor elements 20c, 20d are mainly formed of silicon (Si) or a wide band gap semiconductor material such as silicon carbide (SiC), gallium nitride (GaN), or diamond. The plurality of self-arc-extinguishing semiconductor elements 20c each include a source electrode 22c, a gate electrode 23c, and a drain electrode 21c. The plurality of self-arc-extinguishing semiconductor elements 20d each include a source electrode 22d, a gate electrode 23d, and a drain electrode 21d.

The plurality of self-arc-extinguishing semiconductor elements 20c, 20d are fixed to second conductive circuit pattern 13b. Specifically, drain electrodes 21c of the plurality of self-arc-extinguishing semiconductor elements 20c are each joined to second conductive circuit pattern 13b by means of a conductive joining member 15c such as solder, a metal fine particle sintered body, or a conductive adhesive. Drain electrodes 21d of the plurality of self-arc-extinguishing semiconductor elements 20d are each joined to second conductive circuit pattern 13b by means of a conductive joining member 15d such as solder, a metal fine particle sintered body, or a conductive adhesive.

The plurality of self-arc-extinguishing semiconductor elements 20c, 20d are fixed to printed wiring board 30. Specifically, source electrodes 22c of the plurality of self-arc-extinguishing semiconductor elements 20c are joined to a source conductive pattern 83 of printed wiring board 30 by means of conductive joining members 25c such as solder, a metal fine particle sintered body, or a conductive adhesive. Source electrodes 22d of the plurality of self-arc-extinguishing semiconductor elements 20d are joined to source conductive patterns 83 of printed wiring board 30 by means of conductive joining members 25d such as solder, a metal fine particle sintered body, or a conductive adhesive. The plurality of self-arc-extinguishing semiconductor elements 20c are electrically connected in parallel to each other. The plurality of self-arc-extinguishing semiconductor elements 20d are electrically connected in parallel to each other. The plurality of self-arc-extinguishing semiconductor elements 20c and the plurality of self-arc-extinguishing semiconductor elements 20d are electrically connected in parallel to each other.

The plurality of second freewheeling diodes 20i of the present embodiment are the same as the plurality of second freewheeling diodes 20i of the fourth embodiment. The plurality of second freewheeling diodes 20i are fixed to second conductive circuit pattern 13b. Specifically, second cathode electrodes 21i of the plurality of second freewheeling diodes 20i are each joined to second conductive circuit pattern 13b by means of a conductive joining member 15i such as solder, a metal fine particle sintered body, or a conductive adhesive. The plurality of second freewheeling diodes 20i are fixed to printed wiring board 30. Specifically, second anode electrodes 22i of the plurality of second freewheeling diodes 20i are each joined to source conductive pattern 83 of printed wiring board 30 by means of a conductive joining member 25i such as solder, a metal fine particle sintered body, or a conductive adhesive. The plurality of second freewheeling diodes 20i are electrically connected in parallel to the plurality of self-arc-extinguishing semiconductor elements 20c, 20d.

Power semiconductor module 1e is a 2-in-1 module including two arms (an upper arm 73 and a lower arm 74). As illustrated in FIGS. 27 to 29, upper arm 73 includes a plurality of self-arc-extinguishing semiconductor elements 20a, 20b and a plurality of first freewheeling diodes 20h joined to first conductive circuit pattern 13 and source conductive pattern 33. Lower arm 74 includes the plurality of self-arc-extinguishing semiconductor elements 20c, 20d and the plurality of second freewheeling diodes 20i joined to second conductive circuit pattern 13b and source conductive pattern 83.

Printed wiring board 30 further includes source conductive pattern 83, a conductive pad 67, a source conductive pattern 85, a gate conductive pattern 86, a gate conductive pattern 86b, a conductive pad 57, a conductive pad 77, a conductive via 68, a conductive via 78, and a conductive via 82. Printed wiring board 30 may further include a gate conductive pattern 86c. Source conductive pattern 83, conductive pad 67, source conductive pattern 85, gate conductive pattern 86, gate conductive pattern 86b, conductive pad 57, and conductive pad 77 are each formed of metal such as copper or aluminum.

Source conductive pattern 83 and conductive pad 67 are provided on second principal surface 31a of insulating substrate 31. Source conductive pattern 83 and conductive pad 67 are closer to fourth edge 31f of insulating substrate 31 than source conductive pattern 33 and a conductive pad 34. Conductive pad 67 is closer to fourth edge 31f of insulating substrate 31 than source conductive pattern 83. Source conductive pattern 83 and conductive pad 67 are separated from source conductive pattern 33 and conductive pad 34 in the longitudinal direction (first direction (x direction)) of insulating substrate 31, the longitudinal direction (first direction (x direction)) of gate conductive pattern 36, or a longitudinal direction (first direction (x direction)) of gate conductive pattern 86.

Source conductive pattern 83 and conductive pad 67 are separated from each other and electrically insulated from each other. Conductive pad 67 is disposed along fourth edge 31f of insulating substrate 31. As described later, conductive pad 67 is electrically connected to source conductive pattern 33.

Source conductive pattern 85, gate conductive pattern 86, gate conductive pattern 86b, gate conductive pattern 86c, conductive pad 57, and conductive pad 77 are provided on third principal surface 31b of insulating substrate 31. Source conductive pattern 35, conductive pad 37, gate conductive pattern 36, gate conductive pattern 36b, gate conductive pattern 36c, and conductive pad 77 are closer to third edge 31e of insulating substrate 31 than source conductive pattern 85, gate conductive pattern 86, gate conductive pattern 86b, gate conductive pattern 86c, and conductive pad 57. Source conductive pattern 85, gate conductive pattern 86, gate conductive pattern 86b, gate conductive pattern 86c, and conductive pad 57 are closer to fourth edge 31f of insulating substrate 31 than source conductive pattern 35, conductive pad 37, gate conductive pattern 36, gate conductive pattern 36b, gate conductive pattern 36c, and conductive pad 77.

Source conductive pattern 35, conductive pad 37, gate conductive pattern 36, gate conductive pattern 36b, gate conductive pattern 36c, and conductive pad 77 are separated from source conductive pattern 85, gate conductive pattern 86, gate conductive pattern 86b, gate conductive pattern 86c, and conductive pad 57 in the longitudinal direction (first direction (x direction)) of insulating substrate 31, the longitudinal direction (first direction (x direction)) of gate conductive pattern 36, or the longitudinal direction (first direction (x direction)) of the gate conductive pattern 86.

Source conductive pattern 35, conductive pad 37, gate conductive pattern 36, gate conductive pattern 36b, gate conductive pattern 36c, and conductive pad 77 are separated from each other and electrically insulated from each other. Conductive pad 37 is disposed along third edge 31e of insulating substrate 31. Conductive pad 77 is disposed in a recess provided in source conductive pattern 35. Source conductive pattern 85, gate conductive pattern 86, gate conductive pattern 86b, gate conductive pattern 86c, and conductive pad 57 are separated from each other and electrically insulated from each other. Conductive pad 57 is disposed along fourth edge 31f of insulating substrate 31.

Source conductive pattern 85 is electrically connected to source conductive pattern 35 via conductive bridge 80. Specifically, conductive bridge 80 is joined to source conductive pattern 35 by means of a conductive joining member 81a such as solder. Conductive bridge 80 is joined to source conductive pattern 85 by means of a conductive joining member 81b such as solder. Conductive bridge 80 extends above gate conductive pattern 36c and is electrically insulated from gate conductive pattern 36c.

Conductive via 78 electrically connects conductive pad 77 and source conductive pattern 33. Conductive via 78 extends through insulating substrate 31. Conductive via 78 is formed of metal such as copper or aluminum.

Source conductive pattern 83 extends in the first direction (x direction) and the second direction (y direction). A longitudinal direction of source conductive pattern 83 coincides with the first direction (x direction), and a lateral direction of source conductive pattern 83 coincides with the second direction (y direction). Source conductive pattern 83 includes an edge 83a extending in the longitudinal direction (first direction (x direction)) of source conductive pattern 83. Edge 83a of source conductive pattern 83 may be a long side of source conductive pattern 83 in a plan view of third principal surface 31b of insulating substrate 31. Edge 83a of source conductive pattern 83 is closer to first edge 31c of insulating substrate 31 rather than second edge 31d of insulating substrate 31.

In a plan view of third principal surface 31b of insulating substrate 31, source conductive pattern 83 covers source electrodes 22c, 22d of the plurality of self-arc-extinguishing semiconductor elements 20c, 20d. In a plan view of third principal surface 31b of insulating substrate 31, source conductive pattern 83 further covers second cathode electrodes 21i of the plurality of second freewheeling diodes 20i.

Source conductive pattern 85 extends in the first direction (x direction) and the second direction (y direction). A longitudinal direction of source conductive pattern 85 coincides with the first direction (x direction), and a lateral direction of source conductive pattern 85 coincides with the second direction (y direction). In a plan view of third principal surface 31b of insulating substrate 31, source conductive pattern 85 covers source electrodes 22c, 22d of the plurality of self-arc-extinguishing semiconductor elements 20c, 20d. In a plan view of third principal surface 31b of insulating substrate 31, source conductive pattern 85 further covers second cathode electrodes 21i of the plurality of second freewheeling diodes 20i.

Conductive via 82 electrically connects source conductive pattern 83 and source conductive pattern 85. Conductive via 82 extends through insulating substrate 31. Conductive via 82 is formed of metal such as copper or aluminum.

The longitudinal direction of gate conductive pattern 86 coincides with the first direction (x direction), and a lateral direction of gate conductive pattern 86 coincides with the second direction (y direction). The longitudinal direction of gate conductive pattern 86 coincides with the first direction (x direction) in which first edge 31c of the insulating substrate 31 extends. The longitudinal direction of gate conductive pattern 86 coincides with the first direction (x direction) in which edge 83a of source conductive pattern 83 extends. As illustrated in FIGS. 24, 30, and 31, gate conductive pattern 86 is disposed along first edge 31c of insulating substrate 31. In a plan view of third principal surface 31b of insulating substrate 31, gate conductive pattern 86 is disposed along edge 83a of source conductive pattern 83. Specifically, in a plan view of third principal surface 31b of insulating substrate 31, gate conductive pattern 86 is disposed directly above edge 83a of source conductive pattern 83.

A width w_{g3} of a portion 86p of gate conductive pattern 86, portion 86p corresponding to the plurality of self-arc-extinguishing semiconductor elements 20c in the longitudinal direction (first direction (x direction)) of gate conductive pattern 86 in a plan view of third principal surface 31b of insulating substrate 31, is less than a width wₛ₃ of a portion 83p of source conductive pattern 83, portion 83p corresponding to the plurality of self-arc-extinguishing semiconductor elements 20c in the longitudinal direction (first direction (x direction)) of gate conductive pattern 86 in a plan view of third principal surface 31b of insulating substrate 31. Width w_{g3} of portion 86p of gate conductive pattern 86 is defined as a length of portion 86p of gate conductive pattern 86 in the lateral direction (second direction (y direction)) of gate conductive pattern 86. Width wₛ₃ of portion 83p of source conductive pattern 83 is defined as a length of portion 83p of source conductive pattern 83 in the lateral direction (second direction (y direction)) of gate conductive pattern 86.

Width w_{g3} of portion 86p of gate conductive pattern 86 may be less than or equal to one half of width wₛ₃ of portion 83p of source conductive pattern 83, less than or equal to one third of width wₛ₃ of portion 83p of source conductive pattern 83, less than or equal to one fourth of width wₛ₃ of portion 83p of source conductive pattern 83, or less than or equal to one fifth of width wₛ₃ of portion 83p of source conductive pattern 83.

Since width w_{g3} of portion 86p of gate conductive pattern 86 is less than width wₛ₃ of portion 83p of source conductive pattern 83, the parasitic inductance of gate conductive pattern 86 between the plurality of self-arc-extinguishing semiconductor elements 20c can be made higher than the parasitic inductance of source conductive pattern 83 between the plurality of self-arc-extinguishing semiconductor elements 20c.

Width w_{g3} of portion 86p of gate conductive pattern 86, portion 86p corresponding to the plurality of self-arc-extinguishing semiconductor elements 20c in the longitudinal direction (first direction (x direction)) of gate conductive pattern 86 in a plan view of third principal surface 31b of insulating substrate 31, is less than a width of a portion of source conductive pattern 85, the portion corresponding to the plurality of self-arc-extinguishing semiconductor elements 20a in the longitudinal direction (first direction (x direction)) of gate conductive pattern 86 in a plan view of third principal surface 31b of insulating substrate 31. Therefore, the parasitic inductance of gate conductive pattern 86 between the plurality of self-arc-extinguishing semiconductor elements 20c can be made higher than the parasitic inductance of source conductive pattern 85 between the plurality of self-arc-extinguishing semiconductor elements 20c,

A longitudinal direction of gate conductive pattern 86b coincides with the first direction (x direction), and a lateral direction of gate conductive pattern 86b coincides with the second direction (y direction). The longitudinal direction of gate conductive pattern 86b coincides with the first direction (x direction) in which second edge 31d of insulating substrate 31 extends. The longitudinal direction of gate conductive pattern 86b coincides with the first direction (x direction) in which an edge 83b of source conductive pattern 83 extends. Edge 83b of source conductive pattern 83 is an edge of source conductive pattern 83 opposite from edge 83a of source conductive pattern 83. Edge 83b of source conductive pattern 83 is opposite from edge 83a of source conductive pattern 83 in the lateral direction (second direction (y direction)) of source conductive pattern 83.

As illustrated in FIGS. 24, 30, and 31, gate conductive pattern 86b is disposed along second edge 31d of insulating substrate 31. In a plan view of third principal surface 31b of insulating substrate 31, gate conductive pattern 86b is disposed along edge 83b of source conductive pattern 83. Specifically, in a plan view of third principal surface 31b of insulating substrate 31, gate conductive pattern 86b is disposed directly above edge 83b of source conductive pattern 83.

A width w_{g4} of a portion 86q of gate conductive pattern 86b, portion 86q corresponding to the plurality of self-arc-extinguishing semiconductor elements 20d in the longitudinal direction (first direction (x direction)) of gate conductive pattern 86b in a plan view of third principal surface 31b of insulating substrate 31, is less than a width wₛ₄ of a portion 83q of source conductive pattern 83, the portion 83q corresponding to the plurality of self-arc-extinguishing semiconductor elements 20d in the longitudinal direction (first direction (x direction)) of gate conductive pattern 86b in a plan view of third principal surface 31b of insulating substrate 31. Width w_{g4} of portion 86q of gate conductive pattern 86b is defined as a length of portion 86q of gate conductive pattern 86b in the lateral direction (second direction (y direction)) of gate conductive pattern 86b. Width wₛ₄ of portion 83q of source conductive pattern 83 is defined as a length of portion 83q of source conductive pattern 83 in the lateral direction (second direction (y direction)) of gate conductive pattern 86b.

Width w_{g4} of portion 86q of gate conductive pattern 86b may be less than or equal to one half of width wₛ₄ of portion 83q of source conductive pattern 83, less than or equal to one third of width wₛ₄ of portion 83q of source conductive pattern 83, less than or equal to one fourth of width wₛ₄ of portion 83q of source conductive pattern 83, or less than or equal to one fifth of width wₛ₄ of portion 83q of source conductive pattern 83.

Since width w_{g4} of portion 86q of gate conductive pattern 86b is less than width wₛ₄ of portion 83q of source conductive pattern 83, the parasitic inductance of gate conductive pattern 86b between the plurality of self-arc-extinguishing semiconductor elements 20d can be made higher than the parasitic inductance of source conductive pattern 83 between the plurality of self-arc-extinguishing semiconductor elements 20d.

Width w_{g4} of portion 86q of gate conductive pattern 86b, portion 86q corresponding to the plurality of self-arc-extinguishing semiconductor elements 20d in the longitudinal direction (first direction (x direction)) of gate conductive pattern 86b in a plan view of third principal surface 31b of insulating substrate 31, is less than a width of a portion of source conductive pattern 85, the portion corresponding to the plurality of self-arc-extinguishing semiconductor elements 20d in the longitudinal direction (first direction (x direction)) of gate conductive pattern 86b in a plan view of third principal surface 31b of insulating substrate 31. Therefore, the parasitic inductance of gate conductive pattern 86b between the plurality of self-arc-extinguishing semiconductor elements 20d can be made higher than parasitic inductance of source conductive pattern 85 between the plurality of self-arc-extinguishing semiconductor elements 20d.

The plurality of self-arc-extinguishing semiconductor elements 20c are disposed along first edge 31c of insulating substrate 31. The plurality of self-arc-extinguishing semiconductor elements 20c are disposed along edge 83a of source conductive pattern 83. The plurality of self-arc-extinguishing semiconductor elements 20c are disposed along gate conductive pattern 86. In a plan view of third principal surface 31b of insulating substrate 31, the longitudinal direction (first direction (x direction)) of gate conductive pattern 86 coincides with an array direction (first direction (x direction)) of the plurality of self-arc-extinguishing semiconductor elements 20c.

The plurality of self-arc-extinguishing semiconductor elements 20c are separated from the plurality of self-arc-extinguishing semiconductor elements 20a in the longitudinal direction (first direction (x direction)) of insulating substrate 31, the longitudinal direction (first direction (x direction)) of gate conductive pattern 36, or the longitudinal direction (first direction (x direction)) of gate conductive pattern 86. The plurality of self-arc-extinguishing semiconductor elements 20c are closer to fourth edge 31f of insulating substrate 31 than the plurality of self-arc-extinguishing semiconductor elements 20a. The plurality of self-arc-extinguishing semiconductor elements 20a are closer to third edge 31e of insulating substrate 31 than the plurality of self-arc-extinguishing semiconductor elements 20c.

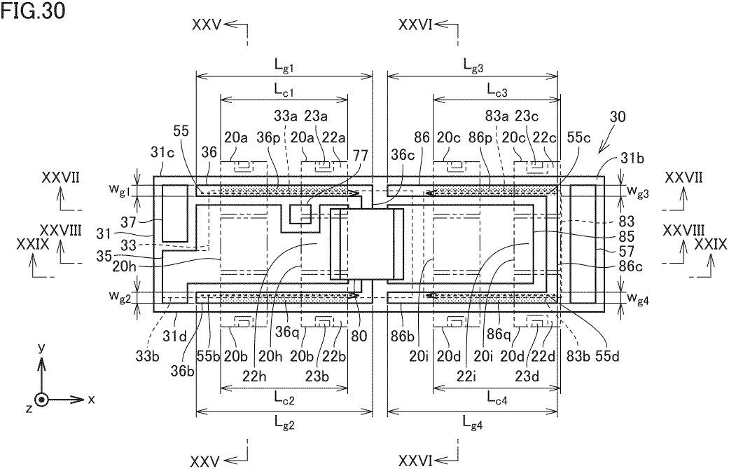

As illustrated in FIGS. 24 and 30, a length L_{g3} of gate conductive pattern 86 in the longitudinal direction (first direction (x direction)) of gate conductive pattern 86 is greater than or equal to a length L_{c3} of the plurality of self-arc-extinguishing semiconductor elements 20c in the array direction (first direction (x direction)) of the plurality of self-arc-extinguishing semiconductor elements 20c. In a plan view of third principal surface 31b of insulating substrate 31, gate electrodes 23c of the plurality of self-arc-extinguishing semiconductor elements 20c are exposed from insulating substrate 31 (printed wiring board 30).

The plurality of self-arc-extinguishing semiconductor elements 20d are disposed along second edge 31d of insulating substrate 31. The plurality of self-arc-extinguishing semiconductor elements 20d are disposed along edge 83b of source conductive pattern 83. The plurality of self-arc-extinguishing semiconductor elements 20d are disposed along gate conductive pattern 86b. In a plan view of third principal surface 31b of insulating substrate 31, the longitudinal direction (first direction (x direction)) of gate conductive pattern 86b coincides with an array direction (first direction (x direction)) of the plurality of self-arc-extinguishing semiconductor elements 20d.

The plurality of self-arc-extinguishing semiconductor elements 20d are separated from the plurality of self-arc-extinguishing semiconductor elements 20b in the longitudinal direction (first direction (x direction)) of insulating substrate 31, the longitudinal direction (first direction (x direction)) of gate conductive pattern 36b, or the longitudinal direction (first direction (x direction)) of gate conductive pattern 86b. The plurality of self-arc-extinguishing semiconductor elements 20d are closer to fourth edge 31f of insulating substrate 31 than the plurality of self-arc-extinguishing semiconductor elements 20b. The plurality of self-arc-extinguishing semiconductor elements 20b are closer to third edge 31e of insulating substrate 31 than the plurality of self-arc-extinguishing semiconductor elements 20d.

As illustrated in FIGS. 24 and 30, a length L_{g4} of gate conductive pattern 86b in the longitudinal direction (first direction (x direction)) of gate conductive pattern 86b is greater than or equal to a length L_{c4} of the plurality of self-arc-extinguishing semiconductor elements 20d in the array direction (first direction (x direction)) of the plurality of self-arc-extinguishing semiconductor elements 20d. In a plan view of third principal surface 31b of insulating substrate 31, gate electrodes 23d of the plurality of self-arc-extinguishing semiconductor elements 20d are exposed from insulating substrate 31 (printed wiring board 30).

The plurality of conductive gate wires 50c connect gate electrodes 23c of the plurality of self-arc-extinguishing semiconductor elements 20c and gate conductive pattern 86. The plurality of conductive gate wires 50c are bonded to gate electrodes 23c of the plurality of self-arc-extinguishing semiconductor elements 20c and gate conductive pattern 86. Gate electrodes 23c of the plurality of self-arc-extinguishing semiconductor elements 20c are electrically connected to gate conductive pattern 86 by means of conductive gate wires 50c. The plurality of conductive gate wires 50c are formed of metal such as gold, silver, copper, or aluminum.

The plurality of conductive gate wires 50d connect gate electrodes 23d of the plurality of self-arc-extinguishing semiconductor elements 20d and gate conductive pattern 86b. The plurality of conductive gate wires 50d are bonded to gate electrodes 23d of the plurality of self-arc-extinguishing semiconductor elements 20d and gate conductive pattern 86b. Gate electrodes 23d of the plurality of self-arc-extinguishing semiconductor elements 20d are electrically connected to gate conductive pattern 86b by means of conductive gate wires 50d. The plurality of conductive gate wires 50d are formed of metal such as gold, silver, copper, or aluminum.

Electrode terminal 62 and electrode terminal 64 are formed of metal such as copper or aluminum. As illustrated in FIG. 24, in a plan view of the third principal surface 31b of insulating substrate 31, electrode terminal 42 and electrode terminal 44 are disposed adjacent to third edge 31e of insulating substrate 31. In a plan view of third principal surface 31b of insulating substrate 31, electrode terminal 62 and electrode terminal 64 are disposed adjacent to fourth edge 31f of insulating substrate 31.

As illustrated in FIG. 27, as with electrode terminal 42 of the third embodiment, electrode terminal 42 of the present embodiment is electrically connected to drain electrodes 21a, 21b of the plurality of self-arc-extinguishing semiconductor elements 20a, 20b via conductive joining member 43, conductive pad 37, conductive via 38, conductive pad 34, conductive joining member 25 m, conductive block 40, conductive joining member 15 m, first conductive circuit pattern 13, and conductive joining members 15a, 15b. Electrode terminal 42 is electrically connected to drain electrodes 21a, 21b of the plurality of self-arc-extinguishing semiconductor elements 20a, 20b via first conductive circuit pattern 13 without a conductive wire. Electrode terminal 42 functions as a drain electrode terminal of upper arm 73. Electrode terminal 42 is a path end, in power semiconductor module 1e, of a first path of a first main current (main currents 55, 55b) flowing through upper arm 73 (that is, flowing between source electrodes 22a, 22b and drain electrodes 21a, 21b of the plurality of self-arc-extinguishing semiconductor elements 20a, 20b). A part of first conductive circuit pattern 13 functions as a first drain conductive pattern. That is, first conductive circuit pattern 13 includes the first drain conductive pattern.

As illustrated in FIG. 27, electrode terminal 62 is joined to conductive pad 57 by means of conductive joining member 63 such as solder. Conductive via 58 electrically connects conductive pad 57 and conductive pad 67. Conductive via 58 extends through insulating substrate 31. Conductive via 58 is formed of metal such as copper or aluminum. Conductive block 70 electrically connects conductive pad 67 and second conductive circuit pattern 13b. Conductive block 70 is joined to conductive pad 67 by means of a conductive joining member 25n such as solder. Conductive block 70 is joined to second conductive circuit pattern 13b by means of a conductive joining member 15n such as solder.

Conductive block 90 electrically connects second conductive circuit pattern 13b and source conductive pattern 33. Conductive block 90 is joined to second conductive circuit pattern 13b by means of a conductive joining member 15p such as solder. Conductive block 90 is joined to source conductive pattern 33 by means of a conductive joining member 25p such as solder.

As illustrated in FIGS. 27 and 29, electrode terminal 62 is electrically connected to source electrodes 22a, 22b of the plurality of self-arc-extinguishing semiconductor elements 20a, 20b via conductive joining member 63, conductive pad 57, conductive via 58, conductive pad 67, conductive joining member 25n, conductive block 70, conductive joining member 15n, second conductive circuit pattern 13b, conductive joining member 15p, conductive block 90, conductive joining member 25p, source conductive pattern 33, and conductive joining members 25a, 25b. Electrode terminal 62 is electrically connected to source electrodes 22a, 22b of the plurality of self-arc-extinguishing semiconductor elements 20a, 20b via source conductive pattern 33 without a conductive wire. Electrode terminal 62 functions as a source electrode terminal of upper arm 73. Electrode terminal 62 is a path end, in power semiconductor module 1e, of the first path of the first main current (main currents 55, 55b) flowing through upper arm 73 (that is, flowing between source electrodes 22a, 22b and drain electrodes 21a, 21b of the plurality of self-arc-extinguishing semiconductor elements 20a, 20b).

As illustrated in FIGS. 28 and 29, electrode terminal 64 is joined to conductive pad 57 by means of conductive joining member 65 such as solder. Conductive via 68 electrically connects conductive pad 57 and conductive pad 67. Conductive via 68 extends through insulating substrate 31. Conductive via 68 is formed of metal such as copper or aluminum.

As illustrated in FIGS. 27 and 29, electrode terminal 64 is electrically connected to drain electrodes 21c, 21d of the plurality of self-arc-extinguishing semiconductor elements 20c, 20d via conductive joining member 65, conductive pad 57, conductive via 68, conductive pad 67, conductive joining member 25n, conductive block 70, conductive joining member 15n, second conductive circuit pattern 13b, and conductive joining members 15c, 15d. Electrode terminal 64 is electrically connected to drain electrodes 21c, 21d of the plurality of self-arc-extinguishing semiconductor elements 20c, 20d via second conductive circuit pattern 13b without a conductive wire. Electrode terminal 64 functions as a drain electrode terminal of lower arm 74. Electrode terminal 64 is a path end, in power semiconductor module 1e, of a second path of a second main current (main currents 55c, 55d) flowing through lower arm 74 (that is, flowing between source electrodes 22c, 22d and drain electrodes 21c, 21d of the plurality of self-arc-extinguishing semiconductor elements 20c, 20d). A part of second conductive circuit pattern 13b functions as a second drain conductive pattern. That is, second conductive circuit pattern 13b includes the second drain conductive pattern.

As illustrated in FIGS. 28 and 29, electrode terminal 44 is joined to source conductive pattern 35 by means of conductive joining member 45 such as solder. Conductive bridge 80 is joined to source conductive pattern 35 by means of conductive joining member 81a such as solder. Conductive bridge 80 is joined to source conductive pattern 85 by means of conductive joining member 81b such as solder. Source conductive pattern 85 is electrically connected to source conductive pattern 35 via conductive bridge 80. Conductive via 82 electrically connects source conductive pattern 85 and source conductive pattern 83. Conductive via 82 extends through insulating substrate 31. Conductive via 82 is formed of metal such as copper or aluminum.

As illustrated in FIGS. 27 and 29, electrode terminal 44 is electrically connected to source electrodes 22c, 22d of the plurality of self-arc-extinguishing semiconductor elements 20c, 20d via conductive joining member 45, source conductive pattern 35, conductive joining member 81a, conductive bridge 80, conductive joining member 81b, source conductive pattern 85, conductive via 82, source conductive pattern 83, and conductive joining members 25c, 25d. Electrode terminal 44 is electrically connected to source electrodes 22c, 22d of the plurality of self-arc-extinguishing semiconductor elements 20c, 20d via source conductive pattern 83 without a conductive wire. Electrode terminal 44 functions as a source electrode terminal of lower arm 74. Electrode terminal 62 is a path end, in power semiconductor module 1e, of the second path of the second main current (main currents 55c, 55d) flowing through lower arm 74 (that is, flowing between source electrodes 22c, 22d and drain electrodes 21c, 21d of the plurality of self-arc-extinguishing semiconductor elements 20c, 20d).

Electrode terminals 42, 44 may each function as an input terminal connected to a power supply (not illustrated) via a smoothing coil (not illustrated). For example, electrode terminal 42 may function as a positive electrode input terminal connected to a positive electrode of the power supply, and electrode terminal 44 may function as a negative electrode input terminal connected to a negative electrode of the power supply. Electrode terminals 62, 64 may each function as an output terminal connected to a load such as a motor.

As illustrated in FIG. 24, conductive wire 47 connects conductive pad 77 and a first source control terminal 46. Conductive wire 47 is bonded to conductive pad 77 and first source control terminal 46. The first source-gate voltage is applied between first source control terminal 46 and first gate control terminal 48 from the outside of power semiconductor module 1e. The plurality of self-arc-extinguishing semiconductor elements 20a, 20b are switched between the ON state and the OFF state in accordance with the first source-gate voltage.

Second first source control terminal 46b is provided, for example, on an insulating block (not illustrated) placed on base plate 11. Second first source control terminal 46b is formed of metal such as copper or aluminum. As illustrated in FIG. 24, conductive wire 47b connects source conductive pattern 85 and second first source control terminal 46b. Conductive wire 47b is bonded to source conductive pattern 85 and second first source control terminal 46b. Conductive wire 47b is formed of metal such as gold, silver, copper, or aluminum.

Second first gate control terminal 48b is provided, for example, on an insulating block (not illustrated) placed on base plate 11. Second first gate control terminal 48b is formed of metal such as copper or aluminum. As illustrated in FIG. 24, conductive wire 49b connects gate conductive pattern 36b and second first gate control terminal 48b. Conductive wire 49b is bonded to gate conductive pattern 36b and second first gate control terminal 48b. Conductive wire 49b is formed of metal such as gold, silver, copper, or aluminum. The second source-gate voltage is applied between second first source control terminal 46b and second first gate control terminal 48b from the outside of power semiconductor module 1e. The plurality of self-arc-extinguishing semiconductor elements 20c, 20d are switched between the ON state and the OFF state in accordance with the second source-gate voltage.

Power semiconductor module 1e of the present embodiment has the following effects in addition to the effects of power semiconductor module 1c of the third embodiment.

In power semiconductor module 1e, source electrodes 22c, 22d of the plurality of self-arc-extinguishing semiconductor elements 20c, 20d are joined to source conductive pattern 83 by means of the plurality of conductive joining members 25c, 25d. On the other hand, gate electrodes 23c, 23d of the plurality of self-arc-extinguishing semiconductor elements 20c, 20d are connected to gate conductive patterns 86, 86b by means of the plurality of conductive gate wires 50c, 50d. A thickness of each of the plurality of conductive joining members 25c, 25 d is less than a length of each of the plurality of conductive gate wires 50c, 50d. Each of the plurality of conductive joining members 25c, 25d is greater in cross-sectional area than each of the plurality of conductive gate wires 50c, 50d. The cross-sectional area of each of the plurality of conductive joining members 25c, 25d is defined as an area of a cross section of each of the plurality of conductive joining members 25c, 25d orthogonal to the thickness direction (third direction (z direction)) of each of the plurality of conductive joining members 25c, 25d. The cross-sectional area of each of the plurality of conductive gate wires 50c, 50d is defined as an area of a cross-section of each of the plurality of conductive gate wires 50c, 50d orthogonal to the longitudinal direction of each of the plurality of conductive gate wires 50c, 50d.

In general, as the length of a conductor increases, the parasitic inductance of the conductor increases. As the cross-sectional area of the conductor decreases, the parasitic inductance of the conductor increases. Therefore, the parasitic inductance of each of the plurality of conductive gate wires 50c, 50d can be increased. The parasitic inductance of each of the plurality of conductive joining members 25c, 25d can be reduced. The parasitic inductance of each of the plurality of conductive gate wires 50c, 50d can be made higher than the parasitic inductance of each of the plurality of conductive joining members 25c, 25d. A difference between the parasitic inductance of each of the plurality of conductive gate wires 50c, 50d and the parasitic inductance of each of the plurality of conductive joining members 25c, 25d can be increased.

As described above, the parasitic inductance of each of the plurality of conductive joining members 25c, 25d joined to source conductive pattern 83 can be reduced. Therefore, even when the plurality of self-arc-extinguishing semiconductor elements 20c, 20d are operated at a high frequency and a time variation dI/dt of the second main current (main currents 55c, 55d) flowing between source electrodes 22c, 22d and drain electrodes 21c, 21d of the plurality of self-arc-extinguishing semiconductor elements 20c, 20d increases, an induced electromotive force generated between source electrodes 22c, 22d of the plurality of self-arc-extinguishing semiconductor elements 20c, 20d can be reduced. It is possible to prevent generation of a surge voltage between source electrodes 22c, 22d and drain electrode 21c, 21d of the plurality of self-arc-extinguishing semiconductor elements 20c, 20d while increasing the operation frequency of power semiconductor module 1e.

Further, the parasitic inductance of each of the plurality of conductive gate wires 50c, 50d joined to gate conductive patterns 86, 86b can be increased. In general, as the inductance of a conductor increases, the impedance of the conductor also increases. Therefore, the parasitic impedance of each of the plurality of conductive gate wires 50c, 50d can be increased. The increased parasitic impedance of each of the plurality of conductive gate wires 50c, 50d attenuates the oscillation of the gate voltage. It is therefore possible to reduce or prevent the oscillation of the gate voltage applied to the plurality of self-arc-extinguishing semiconductor elements 20c, 20d.

Specifically, the thickness of the conductive joining member 45, the thickness of conductive joining member 81a, the thickness of conductive bridge 80, the thickness of conductive joining member 81b, the thickness of conductive via 82, and the thickness of conductive joining member 25c are each less than the length of each of the plurality of conductive gate wires 50c, 50d. Conductive joining member 45, conductive joining member 81a, conductive bridge 80, conductive joining member 81b, conductive via 82, and conductive joining member 25c are each greater in cross-sectional area than each of the plurality of conductive gate wires 50c, 50d. Therefore, conductive joining member 45, conductive joining member 81a, conductive bridge 80, conductive joining member 81b, conductive via 82, and conductive joining member 25c is lower in parasitic inductance than each of the plurality of conductive gate wires 50c, 50d.

Furthermore, source conductive pattern 83 is greater in cross-sectional area than gate conductive patterns 86, 86b. Source conductive pattern 85 is greater in cross-sectional area than gate conductive patterns 86, 86b. Source conductive pattern 35 is greater in cross-sectional area than gate conductive patterns 86, 86b. Therefore, source conductive pattern 83 is lower in parasitic inductance than gate conductive patterns 86, 86b. Source conductive pattern 85 is lower in parasitic inductance than gate conductive patterns 86, 86b. Source conductive pattern 35 is lower in parasitic inductance than gate conductive patterns 86, 86b.

Note that the cross-sectional area of source conductive pattern 83 is defined as an area of a cross section of source conductive pattern 83 orthogonal to a direction (first direction (x direction)) in which the second main current (main currents 55c, 55d) flows through source conductive pattern 83. The cross-sectional area of source conductive pattern 85 is defined as an area of a cross section of source conductive pattern 85 orthogonal to a direction (first direction (x direction)) in which the second main current flows through source conductive pattern 85. The cross-sectional area of source conductive pattern 35 is defined as an area of a cross section of source conductive pattern 35 orthogonal to a direction (first direction (x direction)) in which the second main current flows through source conductive pattern 35. The cross-sectional area of gate conductive patterns 86, 86b is defined as an area of a cross section of gate conductive pattern 86, 86b orthogonal to the longitudinal direction (first direction (x direction)) of gate conductive patterns 86, 86b or the second array direction (first direction (x direction)) of the plurality of self-arc-extinguishing semiconductor elements 20c, 20d.

The thickness of conductive joining member 65, the thickness of conductive pad 57, the thickness of conductive vias 58, 68, the thickness of conductive pad 67, the thickness of conductive joining member 25n, the thickness of conductive block 70, the thickness of conductive joining member 15n, and the thickness of conductive joining members 15c, 15d are each less than the length of each of the plurality of conductive gate wires 50c, 50d. Conductive joining member 65, conductive pad 57, conductive vias 58, 68, conductive pad 67, conductive joining member 25n, conductive block 70, conductive joining member 15n, and conductive joining members 15c, 15d are each greater in cross-sectional area than each of the plurality of conductive gate wires 50c, 50d. Therefore, conductive joining member 65, conductive pad 57, conductive vias 58, 68, conductive pad 67, conductive joining member 25n, conductive block 70, conductive joining member 15n, and conductive joining members 15c, 15d are each lower in parasitic inductance than each of the plurality of conductive gate wires 50c, 50d.

Furthermore, second conductive circuit pattern 13b functioning as the drain conductive pattern is greater in cross-sectional area than gate conductive patterns 86, 86b. Note that the cross-sectional area of second conductive circuit pattern 13b is defined as an area of a cross section of second conductive circuit pattern 13b orthogonal to a direction (first direction (x direction)) in which the second main current (main currents 55, 55b) flows through second conductive circuit pattern 13b. Therefore, second conductive circuit pattern 13b functioning as the drain conductive pattern is lower in parasitic inductance than gate conductive patterns 86, 86b.

Therefore, a second source line extending from electrode terminal 44 to source electrodes 22c, 22d of the plurality of self-arc-extinguishing semiconductor elements 20c, 20d is lower in parasitic inductance than a second gate line extending from second first gate control terminal 48b to gate electrodes 23c, 23d of the plurality of self-arc-extinguishing semiconductor elements 20c, 20d. Even when the plurality of self-arc-extinguishing semiconductor elements 20c, 20d are operated at a high frequency, it is possible to prevent generation of a surge voltage between source electrodes 22c, 22d and drain electrodes 21c, 21d of the plurality of self-arc-extinguishing semiconductor elements 20c, 20d. It is possible to make power semiconductor module 1e longer in lifetime while increasing the operation frequency of power semiconductor module 1e.

Therefore, a second drain line extending from electrode terminal 64 to drain electrodes 21c, 21d of the plurality of self-arc-extinguishing semiconductor elements 20c, 20d is lower in parasitic inductance than the second gate line extending from second first gate control terminal 48b to gate electrodes 23c, 23d of the plurality of self-arc-extinguishing semiconductor elements 20c, 20d. Even when the plurality of self-arc-extinguishing semiconductor elements 20c, 20d are operated at a high frequency, it is possible to prevent generation of a surge voltage between source electrodes 22c, 22d and drain electrodes 21c, 21d of the plurality of self-arc-extinguishing semiconductor elements 20c, 20d. It is possible to make power semiconductor module 1e longer in lifetime while increasing the operation frequency of power semiconductor module 1e.

As described above, as the impedance of a conductor increases, the inductance of the conductor also increases. The second gate line extending from second first gate control terminal 48b to gate electrodes 23c, 23d of the plurality of self-arc-extinguishing semiconductor elements 20c, 20d is higher in parasitic impedance than the second source line extending from electrode terminal 44 to source electrodes 22c, 22d of the plurality of self-arc-extinguishing semiconductor elements 20c, 20d. The second gate line extending from second first gate control terminal 48b to gate electrodes 23c, 23d of the plurality of self-arc-extinguishing semiconductor elements 20c, 20d is higher in parasitic impedance than the second drain line extending from electrode terminal 64 to drain electrodes 21c, 21d of the plurality of self-arc-extinguishing semiconductor elements 20c, 20d. The increased parasitic impedance of the second gate line can reduce or prevent the oscillation of the gate voltage applied to self-arc-extinguishing semiconductor elements 20c, 20d.

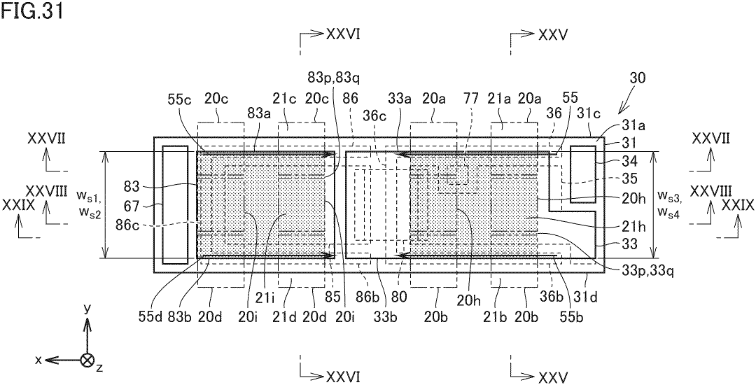

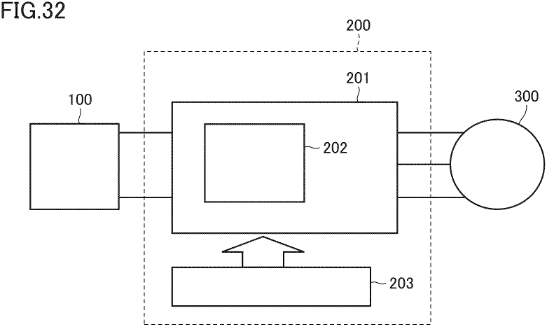

The gate-source voltage applied to each of the plurality of self-arc-extinguishing semiconductor elements 20c is made higher than the threshold voltage to turn on the plurality of self-arc-extinguishing semiconductor elements 20c. As illustrated in FIGS. 30 and 31, main current 55c flows through source conductive pattern 83. In general, the edge of a conductive pattern is a portion through which the most current flows in the conductive pattern. Therefore, as illustrated in FIGS. 30 and 31, main current 55c flows along edge 83a of source conductive pattern 83, edge 83a being located closest to the plurality of self-arc-extinguishing semiconductor elements 20c in source conductive pattern 83.

Main current 55c flowing through source conductive pattern 83 forms a magnetic flux around main current 55c (for example, in source conductive pattern 83). This magnetic flux and the parasitic inductance of source conductive pattern 83 generate an induced electromotive force in source conductive pattern 83. This induced electromotive force causes the source voltage to vary among the plurality of self-arc-extinguishing semiconductor elements 20c. The gate-source voltage varies among the plurality of self-arc-extinguishing semiconductor elements 20c. The drain-source current of one self-arc-extinguishing semiconductor element 20c among the plurality of self-arc-extinguishing semiconductor elements 20c may rapidly increase to destroy this one self-arc-extinguishing semiconductor element 20c.

In power semiconductor module 1e of the present embodiment, however, gate conductive pattern 86 is disposed along edge 83a of source conductive pattern 83 in a plan view of third principal surface 31b of insulating substrate 31. Therefore, main current 55c further forms a magnetic flux in gate conductive pattern 86. This magnetic flux and the parasitic inductance of gate conductive pattern 86 generate an induced electromotive force in gate conductive pattern 86. This induced electromotive force causes the gate voltage to vary among the plurality of self-arc-extinguishing semiconductor elements 20c. The variation in the gate voltage among the plurality of self-arc-extinguishing semiconductor elements 20c counteracts the variation in the gate-source voltage among the plurality of self-arc-extinguishing semiconductor elements 20c. The drain-source current of the plurality of self-arc-extinguishing semiconductor elements 20c is prevented from rapidly increasing. The plurality of self-arc-extinguishing semiconductor elements 20c are prevented from being destroyed, and it is therefore possible to make power semiconductor module 1e longer in lifetime.

The gate-source voltage applied to each of the plurality of self-arc-extinguishing semiconductor elements 20d is made higher than the threshold voltage to turn on the plurality of self-arc-extinguishing semiconductor elements 20d. As illustrated in FIGS. 30 and 31, main current 55d flows through source conductive pattern 83. In general, the edge of a conductive pattern is a portion through which the most current flows in the conductive pattern. Therefore, as illustrated in FIGS. 30 and 31, main current 55d flows along edge 83b of source conductive pattern 83, edge 83b being located closest to the plurality of self-arc-extinguishing semiconductor elements 20d in source conductive pattern 83.

Main current 55d flowing through source conductive pattern 83 forms a magnetic flux around main current 55d (for example, in source conductive pattern 83). This magnetic flux and the parasitic inductance of source conductive pattern 83 generate an induced electromotive force in source conductive pattern 83. This induced electromotive force causes the source voltage to vary among the plurality of self-arc-extinguishing semiconductor elements 20d. The gate-source voltage varies among the plurality of self-arc-extinguishing semiconductor elements 20d. The drain-source current of one self-arc-extinguishing semiconductor element 20d among the plurality of self-arc-extinguishing semiconductor elements 20d may rapidly increase to destroy this one self-arc-extinguishing semiconductor element 20d.

In power semiconductor module 1e of the present embodiment, however, gate conductive pattern 86b is disposed along edge 83b of source conductive pattern 83 in a plan view of third principal surface 31b of insulating substrate 31. Therefore, main current 55d further forms a magnetic flux in gate conductive pattern 86b. This magnetic flux and the parasitic inductance of gate conductive pattern 86b generate an induced electromotive force in gate conductive pattern 86b. This induced electromotive force causes the gate voltage to vary among the plurality of self-arc-extinguishing semiconductor elements 20d. The variation in the gate voltage among the plurality of self-arc-extinguishing semiconductor elements 20d counteracts the variation in the gate-source voltage among the plurality of self-arc-extinguishing semiconductor elements 20d. The drain-source current of the plurality of self-arc-extinguishing semiconductor elements 20d is prevented from rapidly increasing. The plurality of self-arc-extinguishing semiconductor elements 20d are prevented from being destroyed, and it is therefore possible to make power semiconductor module 1e longer in lifetime.

Power semiconductor module 1e of the present embodiment has the following effects in addition to the effects of power semiconductor module 1c of the third embodiment.

Power semiconductor module 1e of the present embodiment further includes a plurality of second self-arc-extinguishing semiconductor elements (the plurality of self-arc-extinguishing semiconductor elements 20c), a plurality of second conductive joining members (the plurality of conductive joining members 25c), and a plurality of second conductive gate wires (the plurality of conductive gate wires 50c). Insulating circuit board 10 further includes second conductive circuit pattern 13b provided on first principal surface 12a of insulating plate 12 and electrically insulated from first conductive circuit pattern 13. Printed wiring board 30 further includes a second source conductive pattern (source conductive pattern 83) electrically insulated from a first source conductive pattern (source conductive pattern 33), and a second gate conductive pattern (gate conductive pattern 86) electrically insulated from a first gate conductive pattern (gate conductive pattern 36). The plurality of second self-arc-extinguishing semiconductor elements each includes a second source electrode (source electrode 22c), a second gate electrode (gate electrode 23c), and a second drain electrode (drain electrode 21c).

The second drain electrodes (drain electrodes 21c) of the plurality of second self-arc-extinguishing semiconductor elements (the plurality of self-arc-extinguishing semiconductor elements 20c) are joined to second conductive circuit pattern 13b. The second source electrodes (source electrodes 22c) of the plurality of second self-arc-extinguishing semiconductor elements are joined to the second source conductive pattern (source conductive pattern 83) by means of the plurality of second conductive joining members (the plurality of conductive joining members 25c). The plurality of second conductive gate wires (the plurality of conductive gate wires 50c) connect the second gate electrodes (gate electrodes 23c) of the plurality of second self-arc-extinguishing semiconductor elements and the second gate conductive pattern (gate conductive pattern 86). In a plan view of third principal surface 31b of insulating substrate 31, a second longitudinal direction (first direction (x direction)) of the second gate conductive pattern (gate conductive pattern 86) coincides with a second array direction (first direction (x direction)) of the plurality of second self-arc-extinguishing semiconductor elements (the plurality of self-are-extinguishing semiconductor elements 20c).

Therefore, as with power semiconductor module 1c of the third embodiment, power semiconductor module 1e of the present embodiment can be made longer in lifetime while increasing the operation frequency of power semiconductor module 1e, and can reduce or prevent the oscillation of the gate voltage. Further, power semiconductor module 1e can be a 2-in-1 module including upper arm 73 including the first self-arc-extinguishing semiconductor elements (the plurality of self-arc-extinguishing semiconductor elements 20a) and lower arm 74 including the second self-arc-extinguishing semiconductor elements (the plurality of self-arc-extinguishing semiconductor elements 20c).

In power semiconductor module 1e of the present embodiment, the second gate conductive pattern (gate conductive pattern 86) is provided on third principal surface 31b of insulating substrate 31. In a plan view of third principal surface 31b of insulating substrate 31, the second gate electrodes (gate electrodes 23c) are exposed from insulating substrate 31.

With power semiconductor module 1e, as with power semiconductor module 1c of the third embodiment, it is possible to increase the parasitic inductance and the parasitic impedance of each of the plurality of second conductive gate wires (the plurality of conductive gate wires 50c), and to reduce or prevent the oscillation of the gate voltage. Further, with power semiconductor module 1e, as with power semiconductor module 1c of the third embodiment, the plurality of second conductive gate wires can be easily bonded to the second gate electrodes (gate electrodes 23c) of the plurality of second self-arc-extinguishing semiconductor elements (the plurality of self-arc-extinguishing semiconductor elements 20c) and the second gate conductive pattern (gate conductive pattern 86).

In power semiconductor module 1e of the present embodiment, a third length (length L_{g3}) of the second gate conductive pattern (gate conductive pattern 86) in the second longitudinal direction (first direction (x direction)) of the second gate conductive pattern (gate conductive pattern 86) is greater than or equal to a fourth length (length L_{c3}) of the plurality of second self-arc-extinguishing semiconductor elements (the plurality of self-arc-extinguishing semiconductor elements 20c) in the second array direction (first direction (x direction)) of the plurality of second self-arc-extinguishing semiconductor elements (the plurality of self-arc-extinguishing semiconductor elements 20c).

Therefore, the third length (length L_{g3}) of the second gate conductive pattern (gate conductive pattern 86) can be increased. The parasitic inductance and the parasitic impedance of the second gate conductive pattern can be increased. The oscillation of the gate voltage applied to the plurality of second self-arc-extinguishing semiconductor elements (the plurality of self-arc-extinguishing semiconductor elements 20c) can be reduced or prevented.

In power semiconductor module 1e of the present embodiment, the second gate conductive pattern (gate conductive pattern 86) is disposed along first edge 31c of insulating substrate 31 in a plan view of third principal surface 31b of insulating substrate 31. The plurality of second self-arc-extinguishing semiconductor elements (the plurality of self-arc-extinguishing semiconductor elements 20c) are disposed along first edge 31c of insulating substrate 31.

Therefore, the plurality of second conductive gate wires (the plurality of conductive gate wires 50c) can be easily bonded to the second gate electrodes (gate electrodes 23 c) of the plurality of second self-arc-extinguishing semiconductor elements (the plurality of self-arc-extinguishing semiconductor elements 20c) and the second gate conductive pattern (gate conductive pattern 86).

In power semiconductor module 1e of the present embodiment, a third width (width w_{g3}) of a second gate conductive pattern portion (portion 86p) of the second gate conductive pattern (gate conductive pattern 86), the second gate conductive pattern portion corresponding to the plurality of second self-arc-extinguishing semiconductor elements (the plurality of self-arc-extinguishing semiconductor elements 20c) in the second longitudinal direction (first direction (x direction)) of the second gate conductive pattern in a plan view of the third principal surface, is less than a fourth width (width wₛ₃) of a second source conductive pattern portion (portion 83p) of the first source conductive pattern, the second source conductive pattern portion corresponding to the plurality of second self-arc-extinguishing semiconductor elements in the second longitudinal direction (first direction (x direction)) of the second gate conductive pattern in a plan view of the third principal surface. The third width of the second gate conductive pattern portion (portion 86p) coincides with a length of the second gate conductive pattern portion (86p) in a second lateral direction of the second gate conductive pattern orthogonal to the second longitudinal direction (first direction (x direction)) of the second gate conductive pattern. The fourth width of the second source conductive pattern portion (portion 83p) coincides with a length of the second source conductive pattern portion (portion 83p) in the second lateral direction of the second gate conductive pattern.

Therefore, the parasitic inductance of the second source conductive pattern (source conductive pattern 83) can be reduced. Even when the plurality of second self-arc-extinguishing semiconductor elements (the plurality of self-arc-extinguishing semiconductor elements 20c) are operated at a high frequency, the induced electromotive force generated between the second source electrodes (source electrodes 22c) of the plurality of second self-arc-extinguishing semiconductor elements can be reduced. It is possible to prevent generation of a surge voltage between the second source electrodes and the second drain electrodes (drain electrodes 21c) of the plurality of second self-arc-extinguishing semiconductor elements. It is possible to make power semiconductor module 1e longer in lifetime while increasing the operation frequency of power semiconductor module 1e.

Further, the parasitic inductance and the parasitic impedance of the second gate conductive pattern (gate conductive pattern 86) can be increased. The increased parasitic impedance of the second gate conductive pattern attenuates the oscillation of the gate voltage. It is therefore possible to reduce or prevent the oscillation of the gate voltage applied to the plurality of second self-arc-extinguishing semiconductor elements (the plurality of self-arc-extinguishing semiconductor elements 20c).

Power semiconductor module 1e of the present embodiment further includes a first electrode terminal (electrode terminal 62) and a second electrode terminal (electrode terminal 42). The first electrode terminal is a first path end, in power semiconductor module 1e, of the first path of the first main current (main currents 55, 55b) flowing between the first source electrodes (source electrodes 22a) and the first drain electrodes (drain electrodes 21a) of the plurality of first self-arc-extinguishing semiconductor elements (the plurality of self-arc-extinguishing semiconductor elements 20a). The second electrode terminal is a second path end, in power semiconductor module 1e, of the first path of the first main current. The first electrode terminal is electrically connected to the first source electrodes of the plurality of first self-arc-extinguishing semiconductor elements via the first source conductive pattern (source conductive pattern 33) without a conductive wire. The second electrode terminal is electrically connected to the first drain electrodes of the plurality of first self-arc-extinguishing semiconductor elements via first conductive circuit pattern 13 without a conductive wire.

Therefore, parasitic inductance of a first source line extending from the first electrode terminal (electrode terminal 62) to the first source electrodes (source electrodes 22a) of the plurality of first self-arc-extinguishing semiconductor elements (the plurality of self-arc-extinguishing semiconductor elements 20a) can be reduced. The parasitic inductance of the first drain line extending from the second electrode terminal (electrode terminal 42) to the first drain electrodes (drain electrodes 21a) of the plurality of first self-arc-extinguishing semiconductor elements can be reduced. It is therefore possible to prevent generation of a surge voltage between the first source electrodes and the first drain electrodes of the plurality of first self-arc-extinguishing semiconductor elements. It is possible to make power semiconductor module 1e longer in lifetime while increasing the operation frequency of power semiconductor module 1e.

Power semiconductor module 1e of the present embodiment further includes a third electrode terminal (electrode terminal 44) and a fourth electrode terminal (electrode terminal 64). The third electrode terminal is a third path end, in power semiconductor module 1e, of the second path of the second main current (main current 55c, 55d) flowing between the second source electrodes (source electrodes 22c) and the second drain electrode (drain electrodes 21c). The fourth electrode terminal is a fourth path end, in power semiconductor module 1e, of the second path of the second main current. The third electrode terminal is electrically connected to the second source electrodes via the second source conductive pattern (source conductive pattern 83) without a conductive wire. The fourth electrode terminal is electrically connected to the second drain electrodes via second conductive circuit pattern 13b without a conductive wire.

Therefore, the parasitic inductance of the second source line extending from the third electrode terminal (electrode terminal 44) to the second source electrodes (source electrodes 22c) of the plurality of second self-arc-extinguishing semiconductor elements (the plurality of self-arc-extinguishing semiconductor elements 20c) can be reduced. The parasitic inductance of the second drain line extending from the fourth electrode terminal (electrode terminal 64) to the second drain electrodes (drain electrodes 21c) of the plurality of second self-arc-extinguishing semiconductor elements can be reduced. It is therefore possible to prevent generation of a surge voltage between the second source electrodes and the second drain electrodes of the plurality of second self-arc-extinguishing semiconductor elements. It is possible to make power semiconductor module 1e longer in lifetime while increasing the operation frequency of power semiconductor module 1e.

### Sixth Embodiment

The present embodiment corresponds to a power conversion apparatus to which power semiconductor modules 1, 1b, 1c, 1d, 1e of the first to fifth embodiments described above are applied. Although the present disclosure is not limited to a specific power conversion apparatus, a case where power semiconductor modules 1, 1b, 1c, 1d, 1e of the present disclosure are applied to a three-phase inverter will be described below as a sixth embodiment.

A power conversion system illustrated in FIG. 32 includes a power supply 100, a power conversion apparatus 200, and a load 300. Power supply 100 is a DC power supply and supplies DC power to power conversion apparatus 200. Power supply 100 may be made up of, but not limited to, for example, a DC system, a solar cell, or a storage battery, or may be made up of a rectifier circuit or an AC/DC converter connected to an AC system. Further, power supply 100 may be made up of a DC/DC converter that converts DC power output from a DC system into different DC power.

Power conversion apparatus 200 is a three-phase inverter connected between power supply 100 and load 300, converts DC power supplied from power supply 100 into AC power, and supplies the AC power to load 300. As illustrated in FIG. 32, power conversion apparatus 200 includes a main conversion circuit 201 that converts DC power into AC power and outputs the AC power, and a control circuit 203 that outputs, to main conversion circuit 201, a control signal to control main conversion circuit 201 .

Load 300 is a three-phase electric motor driven by the AC power supplied from power conversion apparatus 200. Note that load 300 is not limited to a specific application, and is an electric motor mounted on various electric devices such as a hybrid vehicle, an electric vehicle, a railroad car, an elevator, and an air conditioner.

A description will be given below of details of power conversion apparatus 200. Main conversion circuit 201 includes a switching element (not illustrated) and a freewheeling diode (not illustrated). When the switching element switches a voltage supplied from power supply 100, main conversion circuit 201 converts DC power supplied from power supply 100 into AC power and supplies the AC power to load 300. Although there are various specific circuit structures applicable to main conversion circuit 201, main conversion circuit 201 of the present embodiment is a two-level three-phase full bridge circuit and may be made up of six switching elements and six freewheeling diodes each being in anti-parallel to a corresponding one of the switching elements. At least either each switching element or each freewheeling diode of main conversion circuit 201 is a switching element or a freewheeling diode included in a semiconductor device 202 corresponding to any one of power semiconductor modules 1, 1b, 1c, 1d, 1e of the first to fifth embodiments described above. Each two switching elements of the six switching elements are connected in series to constitute upper and lower arms, and each of the upper and lower arms constitutes a corresponding phase (U-phase, V-phase, W-phase) of the full bridge circuit. Then, output terminals of the upper and lower arms, that is, three output terminals of main conversion circuit 201, are connected to load 300.

Main conversion circuit 201 further includes a drive circuit (not illustrated) that drives each switching element. The drive circuit may be contained in semiconductor device 202 or may be provided outside semiconductor device 202. The drive circuit generates a drive signal to drive each switching element of main conversion circuit 201 and supplies the drive signal to a control electrode of the switching element of main conversion circuit 201. Specifically, in accordance with the control signal from control circuit 203, a drive signal to switch the switching element to the ON state or a drive signal to switch the switching element to the OFF state is output to the control electrode of each switching element. When the switching element is kept in the ON state, the drive signal is a voltage signal (ON signal) greater than or equal to a threshold voltage of the switching element, and when the switching element is kept in the OFF state, the drive signal is a voltage signal (OFF signal) less than or equal to the threshold voltage of the switching element.

Control circuit 203 controls each switching element of main conversion circuit 201 so as to supply power to load 300. Specifically, a time (ON time) during which each switching element of main conversion circuit 201 is in the ON state is calculated based on the power to be supplied to load 300. For example, main conversion circuit 201 can be controlled by PWM control under which the ON time of the switching element is modulated in a manner that depends on the voltage to be output to load 300. Then, a control command (control signal) is output to the drive circuit contained in main conversion circuit 201 so as to output the ON signal to a switching element to be in the ON state and output the OFF signal to a switching element to be in the OFF state at each time point. The drive circuit outputs the ON signal or the OFF signal as the drive signal to the control electrode of each switching element in accordance with the control signal.

In the power conversion apparatus of the present embodiment, any one of power semiconductor modules 1, 1b, 1c, 1d, 1e of the first to fifth embodiments is applied as semiconductor device 202 constituting main conversion circuit 201. Therefore, the power capacity of the power conversion apparatus can be increased, and the lifetime of the power conversion apparatus can be made longer.

For the present embodiment, an example where the present disclosure is applied to a two-level three-phase inverter has been described, but the present disclosure is not limited to such an example, and may be applied to various power conversion apparatuses. According to the present embodiment, the present disclosure is applied to a two-level power conversion apparatus, but may be applied to a three-level or multilevel power conversion apparatus, or alternatively, the present disclosure may be applied to a single-phase inverter in a case where power is supplied to a single-phase load. In a case where the power conversion apparatus supplies power to a DC load or the like, the present disclosure may be applied to a DC/DC converter or an AC/DC converter.

The power conversion apparatus to which the present disclosure is applied is not limited to a power conversion apparatus applied to a case where the above-described load is an electric motor, and may be used as a power supply device applied to, for example, an electric discharge machine, a laser beam machine, an induction heating cooker, or a non-contact power supply system. Alternatively, the power conversion apparatus may be used as a power conditioner applied to a photovoltaic system, a power storage system, or the like.

It should be understood that the first to sixth embodiments disclosed herein are illustrative in all respects and not restrictive. At least two of the first to sixth embodiments disclosed herein may be combined as long as there is no inconsistency. The scope of the present disclosure is defined by the claims rather than the above description, and the present disclosure is intended to include the claims, equivalents of the claims, and all modifications within the scope.

### REFERENCE SIGNS LIST

1, 1b, 1c., 1d, 1e: power semiconductor module, 10: insulating circuit board, 11: base plate, 12: insulating plate, 12a: first principal surface, 13: first conductive circuit pattern, 13b: second conductive circuit pattern, 15a, 15b, 15c, 15d, 15h, 15i, 15m, 15n, 15p: conductive joining member, 20a, 20b, 20c, 20d: self-arc-extinguishing semiconductor element, 20h: first freewheeling diode, 20i: second freewheeling diode, 21a, 21b, 21c, 21d: drain electrode, 21h: first cathode electrode, 21i: second cathode electrode, 22a, 22b, 22c, 22d: source electrode, 22h: first anode electrode, 22i: second anode electrode, 23a, 23b, 23c, 23d: gate electrode, 25a, 25b, 25c, 25d, 25h, 25i, 25m, 25n, 25p: conductive joining member, 30: printed wiring board, 31: insulating substrate, 31a: second principal surface, 31b: third principal surface, 31c: first edge, 31d: second edge, 31e: third edge, 31f: fourth edge, 32, 38: conductive via, 33, 35: source conductive pattern, 33a, 33b: edge, 33p, 33q: portion, 34: conductive pad, 36, 36b, 36c: gate conductive pattern, 36p, 36q: portion, 37: conductive pad, 40: conductive block, 42, 44: electrode terminal, 43, 45: conductive joining member, 46: first source control terminal, 46b: second source control terminal, 47, 47b, 49, 49b: conductive wire, 48: first gate control terminal, 48b: second gate control terminal, 50a, 50b, 50c, 50d: conductive gate wire, 53: source conductive pattern, 53a: edge, 53p: portion, 55, 55b, 55c, 55d: main current, 57: conductive pad, 58: conductive via, 62, 64: electrode terminal, 63, 65: conductive joining member, 66, 68: conductive via, 67: conductive pad, 70: conductive block, 73: upper arm, 74: lower arm, 77: conductive pad, 78: conductive via, 80: conductive bridge, 81a, 81b: conductive joining member, 82: conductive via, 83, 85: source conductive pattern, 83a, 83b: edge, 83p, 83q: portion, 86, 86b, 86c: gate conductive pattern, 86p, 86q: portion, 90: conductive block, 100: power supply, 200: power conversion apparatus, 201: main conversion circuit, 202: semiconductor device, 203: control circuit, 300: load

1. A power semiconductor module comprising:
an insulating circuit board including an insulating plate including a first principal surface and a first conductive circuit pattern provided on the first principal surface;
a plurality of first self-arc-extinguishing semiconductor elements;
a printed wiring board disposed to face the first principal surface;
a plurality of first conductive joining members; and
a plurality of first conductive gate wires, wherein
the printed wiring board includes an insulating substrate, a first source conductive pattern, and a first gate conductive pattern,
the insulating substrate includes a second principal surface facing the first principal surface and a third principal surface opposite from the second principal surface,
in a plan view of the third principal surface, the insulating substrate includes a first edge and a second edge opposite from the first edge,
the plurality of first self-arc-extinguishing semiconductor elements each include a first source electrode, a first gate electrode, and a first drain electrode,
the first drain electrodes of the plurality of first self-arc-extinguishing semiconductor elements are joined to the first conductive circuit pattern,
the first source electrodes of the plurality of first self-arc-extinguishing semiconductor elements are joined to the first source conductive pattern by means of the plurality of first conductive joining members,
the plurality of first conductive gate wires connect the first gate electrodes of the plurality of first self-arc-extinguishing semiconductor elements and the first gate conductive pattern, and
in the plan view of the third principal surface, a first longitudinal direction of the first gate conductive pattern coincides with a first array direction of the plurality of first self-arc-extinguishing semiconductor elements.

2-17. (canceled)

18. A power semiconductor module comprising:
an insulating circuit board including an insulating plate including a first principal surface and a first conductive circuit pattern provided on the first principal surface;
a plurality of first self-arc-extinguishing semiconductor elements;
a printed wiring board disposed to face the first principal surface;
a plurality of first conductive joining members; and
a plurality of first conductive gate wires, wherein
the printed wiring board includes an insulating substrate, a first source conductive pattern, and a first gate conductive pattern,
the insulating substrate includes a second principal surface facing the first principal surface and a third principal surface opposite from the second principal surface,
in a plan view of the third principal surface, the insulating substrate includes a first edge and a second edge opposite from the first edge,
the plurality of first self-arc-extinguishing semiconductor elements each include a first source electrode, a first gate electrode, and a first drain electrode,
the first drain electrodes of the plurality of first self-arc-extinguishing semiconductor elements are joined to the first conductive circuit pattern,
the first source electrodes of the plurality of first self-arc-extinguishing semiconductor elements are joined to the first source conductive pattern by means of the plurality of first conductive joining members, the first source conductive pattern being provided on the second principal surface,
the plurality of first conductive gate wires connect the first gate electrodes of the plurality of first self-arc-extinguishing semiconductor elements and the first gate conductive pattern, the first gate conductive pattern being provided on the third principal surface, and
in the plan view of the third principal surface, a first longitudinal direction of the first gate conductive pattern coincides with a first array direction of the plurality of first self-arc-extinguishing semiconductor elements.

19. The power semiconductor module according to claim 1, wherein a first length of the first gate conductive pattern in the first longitudinal direction of the first gate conductive pattern is greater than or equal to a second length of the plurality of first self-arc-extinguishing semiconductor elements in the first array direction of the plurality of first self-arc-extinguishing semiconductor elements.

20. The power semiconductor module according to claim 1, wherein
in the plan view of the third principal surface, the first gate conductive pattern is disposed along the first edge of the insulating substrate, and
the plurality of first self-arc-extinguishing semiconductor elements are disposed along the first edge of the insulating substrate.

21. The power semiconductor module according to claim 1, wherein
the first gate conductive pattern is disposed along an edge of the first source conductive pattern in the plan view of the third principal surface.

22. The power semiconductor module according to claim 1, wherein
a first width of a first gate conductive pattern portion of the first gate conductive pattern, the first gate conductive pattern portion corresponding to the plurality of first self-arc-extinguishing semiconductor elements in the first longitudinal direction of the first gate conductive pattern in the plan view of the third principal surface, is less than a second width of a first source conductive pattern portion of the first source conductive pattern, the first source conductive pattern portion corresponding to the plurality of first self-arc-extinguishing semiconductor elements in the first longitudinal direction of the first gate conductive pattern in the plan view of the third principal surface,
the first width of the first gate conductive pattern portion coincides with a length of the first gate conductive pattern portion in a first lateral direction of the first gate conductive pattern orthogonal to the first longitudinal direction, and
the second width of the first source conductive pattern portion coincides with a length of the first source conductive pattern portion in the first lateral direction of the first gate conductive pattern.

23. The power semiconductor module according to claim 1, wherein at least one of the plurality of first conductive gate wires extends in a direction oblique to the first longitudinal direction of the first gate conductive pattern in the plan view of the third principal surface.

24. The power semiconductor module according to claim 23, wherein
the at least one of the plurality of first conductive gate wires includes a first end bonded to the first gate electrode of at least one of the plurality of first self-arc-extinguishing semiconductor elements and a second end bonded to the first gate conductive pattern, and
an interval between the first end and the second end in the first longitudinal direction of the first gate conductive pattern is less than or equal to a width of the at least one of the plurality of first self-arc-extinguishing semiconductor elements in the first longitudinal direction of the first gate conductive pattern.

25. The power semiconductor module according to claim 1, further comprising:
a first electrode terminal; and
a second electrode terminal, wherein
the first electrode terminal is a first path end, in the power semiconductor module, of a first path of a first main current flowing between the first source electrodes and the first drain electrodes,
the second electrode terminal is a second path end, in the power semiconductor module, of the first path of the first main current,
the first electrode terminal is electrically connected to the first source electrodes via the first source conductive pattern without a conductive wire, and
the second electrode terminal is electrically connected to the first drain electrodes via the first conductive circuit pattern without a conductive wire.

26. The power semiconductor module according to claim 1, further comprising:
a plurality of second self-arc-extinguishing semiconductor elements;
a plurality of second conductive joining members; and
a plurality of second conductive gate wires, wherein
the printed wiring board further includes a second gate conductive pattern electrically connected to the first gate conductive pattern,
the plurality of second self-arc-extinguishing semiconductor elements each include a second source electrode, a second gate electrode, and a second drain electrode,
the second drain electrodes of the plurality of second self-arc-extinguishing semiconductor elements are joined to the first conductive circuit pattern,
the second source electrodes of the plurality of second self-arc-extinguishing semiconductor elements are joined to the first source conductive pattern by means of the plurality of second conductive joining members,
the plurality of second conductive gate wires connect the second gate electrodes of the plurality of second self-arc-extinguishing semiconductor elements and the second gate conductive pattern, and
in the plan view of the third principal surface, a second longitudinal direction of the second gate conductive pattern coincides with a second array direction of the plurality of second self-arc-extinguishing semiconductor elements.

27. The power semiconductor module according to claim 26, wherein
a third width of a second gate conductive pattern portion of the second gate conductive pattern, the second gate conductive pattern portion corresponding to the plurality of second self-arc-extinguishing semiconductor elements in the second longitudinal direction of the second gate conductive pattern in the plan view of the third principal surface, is less than a fourth width of a second source conductive pattern portion of the first source conductive pattern, the second source conductive pattern portion corresponding to the plurality of second self-arc-extinguishing semiconductor elements in the second longitudinal direction of the second gate conductive pattern in the plan view of the third principal surface,
the third width of the second gate conductive pattern portion coincides with a length of the second gate conductive pattern portion in a second lateral direction of the second gate conductive pattern orthogonal to the second longitudinal direction, and
the fourth width of the second source conductive pattern portion coincides with a length of the second source conductive pattern portion in the second lateral direction of the second gate conductive pattern.

28. The power semiconductor module according to claim 1, further comprising:
a plurality of second self-arc-extinguishing semiconductor elements;
a plurality of second conductive joining members; and
a plurality of second conductive gate wires, wherein
the insulating circuit board further includes a second conductive circuit pattern provided on the first principal surface and electrically insulated from the first conductive circuit pattern,
the printed wiring board further includes a second source conductive pattern electrically insulated from the first source conductive pattern, and a second gate conductive pattern electrically insulated from the first gate conductive pattern,
the plurality of second self-arc-extinguishing semiconductor elements each include a second source electrode, a second gate electrode, and a second drain electrode,
the second drain electrodes of the plurality of second self-arc-extinguishing semiconductor elements are joined to the second conductive circuit pattern,
the second source electrodes of the plurality of second self-arc-extinguishing semiconductor elements are joined to the second source conductive pattern by means of the plurality of second conductive joining members,
the plurality of second conductive gate wires connect the second gate electrodes of the plurality of second self-arc-extinguishing semiconductor elements and the second gate conductive pattern, and
in the plan view of the third principal surface, a second longitudinal direction of the second gate conductive pattern coincides with a second array direction of the plurality of second self-arc-extinguishing semiconductor elements.

29. The power semiconductor module according to claim 28, wherein
in the plan view of the third principal surface, a third width of a second gate conductive pattern portion of the second gate conductive pattern in a second lateral direction of the second gate conductive pattern, the second gate conductive pattern portion corresponding to the plurality of second self-arc-extinguishing semiconductor elements, is less than a fourth width of a second source conductive pattern portion of the second source conductive pattern in the second lateral direction, the second source conductive pattern portion corresponding to the plurality of second self-arc-extinguishing semiconductor elements and
the second lateral direction of the second gate conductive pattern is orthogonal to the second longitudinal direction of the second gate conductive pattern.

30. The power semiconductor module according to claim 26, wherein a third length of the second gate conductive pattern in the second longitudinal direction of the second gate conductive pattern is greater than or equal to a fourth length of the plurality of second self-arc-extinguishing semiconductor elements in the second array direction of the plurality of second self-arc-extinguishing semiconductor elements.

31. The power semiconductor module according to claim 26, wherein
in the plan view of the third principal surface, the second gate conductive pattern is disposed along the second edge of the insulating substrate, and
the plurality of second self-arc-extinguishing semiconductor elements are disposed along the second edge of the insulating substrate.

32. The power semiconductor module according to claim 28, wherein
in the plan view of the third principal surface, the second gate conductive pattern is disposed along the first edge of the insulating substrate, and
the plurality of second self-arc-extinguishing semiconductor elements are disposed along the first edge of the insulating substrate.

33. The power semiconductor module according to claim 28, further comprising:
a third electrode terminal; and
a fourth electrode terminal, wherein
the third electrode terminal is a third path end, in the power semiconductor module, of a second path of a second main current flowing between the second source electrodes and the second drain electrodes,
the fourth electrode terminal is a fourth path end, in the power semiconductor module, of the second path of the second main current,
the third electrode terminal is electrically connected to the second source electrodes via the second source conductive pattern without a conductive wire, and
the fourth electrode terminal is electrically connected to the second drain electrodes via the second conductive circuit pattern without a conductive wire.

34. A power conversion apparatus comprising:
a main conversion circuit including the power semiconductor module according to claim 1, the main conversion circuit to convert and output input power; and
a control circuit to output, to the main conversion circuit, a control signal to control the main conversion circuit.
